(19) United States
(12) Patent Application Publication
(10) Pub. No.: US 2023/0101023 A1
(43) Pub. Date: Mar. 30, 2023

(54) AI-BASED HYPERPARAMETER TUNING IN SIMULATION-BASED OPTIMIZATION

(71) Applicant: C3.ai, Inc., Redwood City, CA (US)

(72) Inventors: Zhaoyang Jin, Redwood City, CA (US); Mehdi Maasoumy Haghighi, Redwood City, CA (US); Zeshi Zheng, Redwood City, CA (US)

(21) Appl. No.: 17/932,862

(22) Filed: Sep. 16, 2022

Related U.S. Application Data
(60) Provisional application No. 63/245,728, filed on Sep. 17, 2021.

(51) Int. Cl. G06Q 10/08; G06F 30/27; G06Q 30/02

(52) U.S. Cl. CPC G06Q 10/087; G06F 30/27; G06Q 30/0202

(57) ABSTRACT

A method includes identifying, using at least one processor, uncertainty distributions for multiple variables. The method also includes identifying, using the at least one processor, one or more hyperparameters. The method further includes performing, using the at least one processor, multiple simulations to simulate effects of future requests using the one or more hyperparameters and at least one of the uncertainty distributions. The simulations involve sampling of the at least one uncertainty distribution to simulate at least one uncertainty associated with at least one of the variables on the future requests. In addition, the method includes selecting, using the at least one processor, one or more of the simulated future requests.

### CROSS-REFERENCE TO RELATED APPLICATION AND PRIORITY CLAIM

This application claims priority under 35 U.S.C. § 119(e) to U.S. Provisional Patent Application No. 63/245,728 filed on Sep. 17, 2021. This provisional application is hereby incorporated by reference in its entirety.

### TECHNICAL FIELD

This disclosure relates generally to machine learning systems. More specifically, this disclosure relates to artificial intelligence (AI)-based hyperparameter tuning in simulation-based optimization.

### BACKGROUND

Uncertainty is an intrinsic and dynamic property of modern complex planning systems, such as supply chains, air-logistic systems, etc. Uncertainty continually challenges planning decisions, which may consider balancing of capital investment constraints, order customizations, and service-level goals. As a result of uncertainty in inventory variables, for example, software for inventory management and planning may encounter challenges in accurately forecasting and predicting optimal inventory levels. In order to stay competitive in a dynamic market, businesses often need to constantly reconfigure planning and supply chains and to manage the various types of uncertainties that are continually being introduced (such as from both the demand-side and the supply-side). However, the data that is required to make informed decisions for managing these uncertainties in logistics (such as inventory, supply chain, transportation, etc.) is often stored in multiple disparate source systems (such as on-site or in a remote location like a cloud network) or not tracked historically. Such systems, which may have been built and implemented years or decades ago, may be rules-based systems that are rigid (not adaptive to changes in supply and demand) and thus incapable of handling large volumes of dynamic data distributed across various source systems.

### SUMMARY

This disclosure provides artificial intelligence (AI)-based hyperparameter tuning in simulation-based optimization.

In a first embodiment, a method includes identifying, using at least one processor, uncertainty distributions for multiple variables. The method also includes identifying, using the at least one processor, one or more hyperparameters. The method further includes performing, using the at least one processor, multiple simulations to simulate effects of future requests using the one or more hyperparameters and at least one of the uncertainty distributions. The simulations involve sampling of the at least one uncertainty distribution to simulate at least one uncertainty associated with at least one of the variables on the future requests. In addition, the method includes selecting, using the at least one processor, one or more of the simulated future requests.

In a second embodiment, an apparatus includes at least one processor configured to identify uncertainty distributions for multiple variables and identify one or more hyperparameters. The at least one processor is also configured to perform multiple simulations to simulate effects of future requests using the one or more hyperparameters and at least one of the uncertainty distributions. The simulations involve sampling of the at least one uncertainty distribution to simulate at least one uncertainty associated with at least one of the variables on the future requests. The at least one processor is further configured to select one or more of the simulated future requests.

In a third embodiment, a non-transitory computer readable medium contains instructions that when executed cause at least one processor to identify uncertainty distributions for multiple variables and identify one or more hyperparameters. The non-transitory computer readable medium also contains instructions that when executed cause the at least one processor to perform multiple simulations to simulate effects of future requests using the one or more hyperparameters and at least one of the uncertainty distributions. The simulations involve sampling of the at least one uncertainty distribution to simulate at least one uncertainty associated with at least one of the variables on the future requests. The non-transitory computer readable medium further contains instructions that when executed cause the at least one processor to select one or more of the simulated future requests.

Other technical features may be readily apparent to one skilled in the art from the following figures, descriptions, and claims.

### BRIEF DESCRIPTION OF THE DRAWINGS

For a more complete understanding of this disclosure and its features, reference is now made to the following description, taken in conjunction with the accompanying drawings, in which:

FIG. 1 illustrates common problems that may occur in manufacturing supply chains.

FIG. 2 illustrates an example material requirements planning (MRP) process that follows deterministic logic to place orders based on demand forecasts, current day inventories, planning calendars, order parameters, and previously-scheduled arrivals.

FIG. 3 illustrates an example stochastic inventory optimization (SIO) algorithm workflow in accordance with this disclosure.

FIG. 4 illustrates an example comparison of high versus low service level threshold percentiles in accordance with this disclosure.

FIG. 5 illustrates an example distribution where a safety time percentile may be used to account for supplier time uncertainty in accordance with this disclosure.

FIG. 6 illustrates an example grid search of hyperparameters in accordance with this disclosure.

FIG. 7 illustrates an example selection and consumption of hyperparameters in accordance with this disclosure.

FIG. 8 illustrates an example where a k-iteration algorithm is used as an interpretation algorithm to determine an inventory deficit in accordance with this disclosure.

FIG. 9 illustrates an example where an interpretation algorithm may be used to respond to realized uncertainty by elevating a safety stock value (SSV) in accordance with this disclosure.

FIG. 10 illustrates example SSV and safety time (ST) recommendations with different optimization frequencies in accordance with this disclosure.

FIG. 11 illustrates example simulated inventory levels with different optimization frequencies in accordance with this disclosure.

FIG. 12 illustrates example simulation results for a first product involving simulated and actual inventories, demand forecast and actual consumption, planned and actual arrivals for simulated and actual inventories, and simulated and actual SSV recommendations in accordance with this disclosure.

FIG. 13 illustrates example sampled uncertainties within an uncertainty sampling window (USW) for the first product including demand forecast uncertainty, movement uncertainty, supplier time uncertainty, and supplier quantity uncertainty in accordance with this disclosure.

FIG. 14 illustrates example forward-looking simulation results in the first iteration of a k-iteration algorithm for the first product in accordance with this disclosure.

FIG. 15 illustrates example simulation results for a second product involving simulated and actual inventories, demand forecast and actual consumption, planned and actual arrivals for simulated and actual inventories, and simulated and actual SSV recommendations in accordance with this disclosure.

FIG. 16 illustrates example sampled uncertainties within a USW for the second product including demand forecast uncertainty, movement uncertainty, supplier time uncertainty, and supplier quantity uncertainty in accordance with this disclosure.

FIG. 17 illustrates example forward-looking simulation results in the final iteration of a k-iteration algorithm for the second product in accordance with this disclosure.

FIG. 18 illustrates example results of a sensitivity study on a clipping multiplier for raw demand forecast data in accordance with this disclosure.

FIG. 19 illustrates example results of a sensitivity study on a clipping multiplier for demand forecast uncertainty and movement uncertainty in accordance with this disclosure.

FIG. 20 illustrates example results of a sensitivity study on a candidate list for service level percentile (SLP) in accordance with this disclosure.

FIG. 21 illustrates example results of a sensitivity study on a buffer for USW size in accordance with this disclosure.

FIG. 22 illustrates example results of a convergence study on a number of uncertainty realizations in a forward-looking simulation procedure in accordance with this disclosure.

FIG. 23 illustrates an example computer system that is programmed or otherwise configured to implement various techniques for hyperparameter inventory optimization using artificial intelligence in accordance with this disclosure.

FIG. 24 illustrates an example method for artificial intelligence (AI)-based hyperparameter tuning in simulation-based optimization in accordance with this disclosure.

FIG. 25 illustrates an example method for hyperparameter inventory optimization using artificial intelligence in accordance with this disclosure.

### DETAILED DESCRIPTION

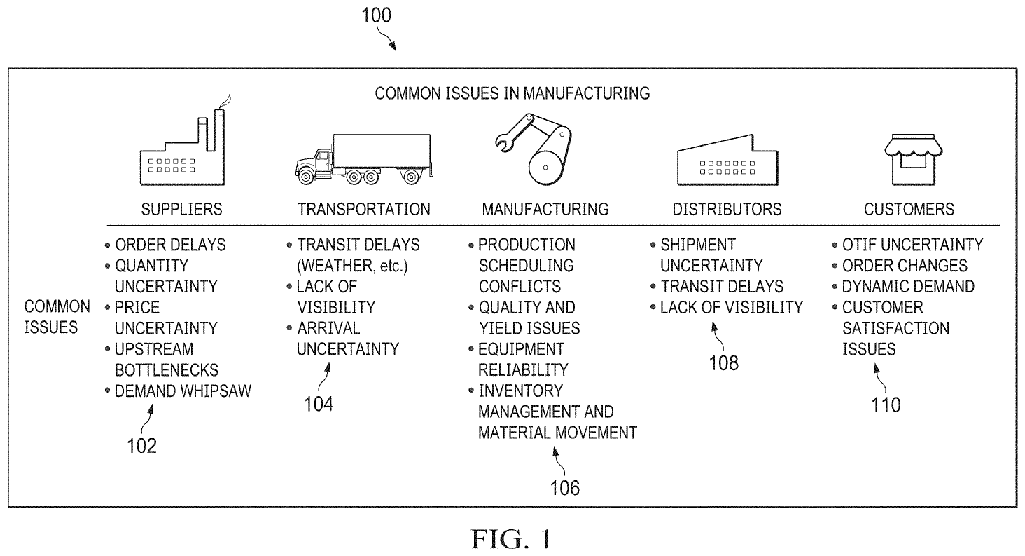

FIGS. 1 through 25, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system. Moreover, the drawings and description are to be regarded as illustrative in nature, and not as restrictive.

In the following discussion, various acronyms are used. The following is a partial list of the acronyms used below.

BOM—Bill of materials

EA—Expected expedited arrival

ELT—Expedited lead time

ERP—Enterprise resource planning

FLS—Forward-looking simulation

KIA—The k-iteration algorithm

LT—Lead time

MO—Minimum order quantity

MRP—Material requirements planning

PTF—Planning time fence

RV—Rounding value

SA—Expected standard arrival

SIO—Stochastic inventory optimization

SKU—Stock keeping unit

SL—Service level

SLP—Service level percentile

SSV—Safety stock value

ST—Safety time

STP—Safety time percentile

USW—Uncertainty sampling window

As noted above, uncertainty is an intrinsic and dynamic property of modern complex planning systems, such as supply chains. Uncertainty continually challenges inventory decisions, which may consider balancing of capital investment constraints and service-level goals. As a result of uncertainty in inventory variables, for example, software for inventory management and planning may encounter challenges in accurately forecasting and predicting optimal inventory levels. In order to stay competitive in a dynamic market, businesses often need to constantly reconfigure supply chains and to manage the various types of uncertainties that are continually being introduced (such as from both the demand-side and the supply-side). However, the data that is required to make informed decisions for managing these uncertainties in inventory is often stored in multiple disparate source systems (such as on-site or in a remote location like a cloud network) or not tracked historically. Such systems, which may have been built and implemented years or decades ago, may be rules-based systems that are rigid (not adaptive to changes in supply and demand) and thus incapable of handling large volumes of dynamic data distributed across various source systems.

The COVID-19 pandemic has had a significant impact on the world and magnified the issue of stochastic supply chain uncertainties. Global supply chains were subject to a supply shock from China as the pandemic first emerged from mainland China and disrupted global supply. Over the ensuing months, global shutdowns and stay-at-home orders triggered a second shock, this time to global demand. These two waves of unprecedented disruptions to global supply chains exposed the inherent volatility of such supply chains networks. Subsequently, manufacturers had to increase their domestic production and re-strategize to better leverage lean manufacturing concepts that included minimizing the amount of inventory held in their global supply chains.

Example aspects of this disclosure include systems and methods for technical analysis with hyperparameters used to improve machine learning processes and applications involving logistical uncertainty. In an example implementation, hyperparameter tuning can be applied to effectively and dynamically manage uncertainty by performing simulations to simulate uncertainty associated with variables on future orders or other requests. The simulations can sample different uncertainty distributions to analyze variable effects of future requests. Based on the simulations using the hyperparameter tuning, systems and methods can improve logistical planning and optimize for particular parameters. For example, an inventory planning system can optimize for inventory realizations generated by the simulations that meet a minimum target service level and a reorder quantity percentile representing a percentage of inventory realizations generated by the simulations that minimize an overall cost of holding the inventory. In some implementations, the realizations from the simulations using the hyperparameter tuning can control logistical planning systems. In an inventory optimization example, an MRP system can be controlled or instructed to change safety stock, safety time, or other parameter(s) that satisfy contractual requirements based on simulations using hyperparameter tuning that generate realizations to promote potentially significant cost savings compared to unchanged safety stock, safety time, or other parameter(s). Other examples can employ the realizations or output from the simulations using the hyperparameter tuning to automatically adjust resource planning, scheduling, ordering, routing, restocking, etc.

FIG. 1 illustrates common problems 100 that may occur in manufacturing supply chains. Current practice in today's supply chains suffer from numerous uncertainty issues stemming from every piece of the supply chain. This may include, for instance, problems 102 associated with suppliers, problems 104 associated with transportation, problems 106 associated with manufacturing, problems 108 associated with distribution, and/or problems 110 associated with customers. The problems 102 associated with suppliers may include issues such as delays in orders being fulfilled, uncertainties associated with order quantities, uncertainties associated with order prices, bottlenecks upstream of the suppliers, and demand whipsaw (large rapid changes in demand). The problems 104 associated with transportation may include issues such as transit delays due to factors like weather, lack of visibility into transportation issues, and uncertainties associated with arrival times. The problems 106 associated with manufacturing may include issues such as production scheduling conflicts involving multiple items to be manufactured, quality and yield issues affecting items being manufactured, manufacturing equipment reliability issues, and inventory management and material movement issues affecting raw or intermediate products used during manufacturing. The problems 108 associated with distribution may include issues such as uncertainties associated with manufactured product shipments, transit delays due to factors like weather, and lack of visibility into distribution issues. The problems 110 associated with customers may include issues such as uncertainties associated with on-time in-full (OTIF) orders, changes in customer orders, dynamic demands of customers, and issues affecting customer satisfaction.

Perturbations in each of the above processes are unlikely to be specific to that process alone. The network aspect of the supply chain often makes any issue in each of these processes propagate (upstream, downstream, or both) through the network. For example, in one direction, dynamic demand and order changes can impact production schedules and inventory management at manufacturing sites and distribution centers. On the other hand, available inventory and production requirements often inform supplier orders. Equipment reliability, product quality issues, and shipment uncertainties can impact part order logistics. In the other direction, supplier uncertainties and delays can affect production schedules, while order delays and quality issues may risk customer satisfaction. Furthermore, material movement delays can strain the entire supply chain. Lack of end-to-end operational visibility can lead to delays across supply chains, excess inventory levels, quality issues, poor OTIF, and low customer satisfaction.

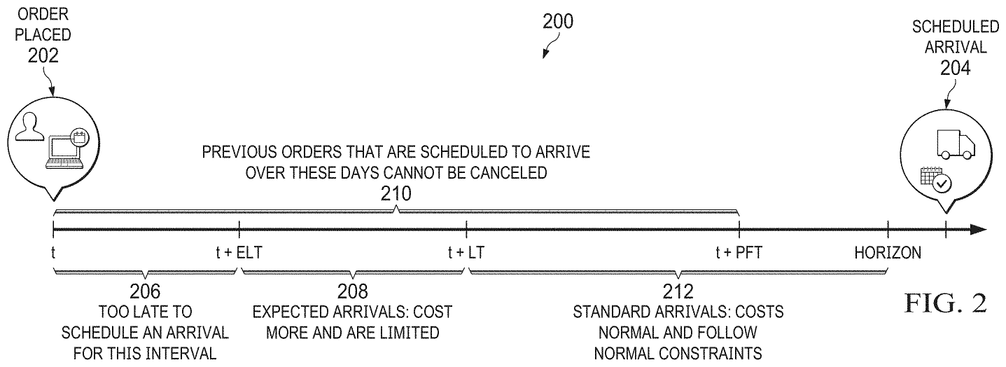

Material requirements planning (MRP) is at the heart of the processes in today's supply chain systems. FIG. 2 illustrates an example MRP process 200 that follows deterministic logic to place orders based on demand forecasts, current day inventories, planning calendars, order parameters, and previously-scheduled arrivals. More specifically, the MRP process 200 can use deterministic logic that calculates times and quantities of orders that need to be placed based on net material requirements, re-order parameters, current inventories, demand forecasts, and/or other inputs. Among other things, the MRP process 200 can identify a time 202 when an order should be placed and a time 204 when the order should be delivered. A time interval 206 may represent a period where delivery cannot occur due to manufacturing, transportation, or other constraints. A time interval 208 may represent a period where one or more deliveries are already expected to occur, so there are limited options that cost more in order to place an additional order. A time interval 210 may represent a period in which one or more previous orders are scheduled for delivery and cannot be cancelled. A time interval 212 may represent a period where standard delivery may occur and is associated with typical costs and constraints.

An MRP system may determine material requirements based on a demand forecast and may schedule arrivals (deliveries) as close as possible to the times that materials will be consumed. Re-order parameters, such as safety stock values (SSVs) and safety time (STs) for a safety stock MRP system or re-order points (RoPs) for a re-order point MRP system, are used as inputs to the MRP system in order to address uncertainties in both supply and demand by providing buffers in the system. In some cases, an MRP system receives as input (i) a bill of materials (BOM), which is a list of the materials, components, and subassemblies required to make each product, (ii) one or more end products, which are also called independent demand or level “0” on the BOM, (iii) a quantity of each end product that is required at a given time, (iv) a time at which each quantity is required to meet demand, (v) one or more inventory status records, each of which is a record of net materials available for use already in stock and materials on order from suppliers, and (vi) planning data, which includes the restraints and directions to produce such items like routing, labor and machine standards, quality and testing standards, lot sizing techniques (such as fixed lot size, lot-for-lot, economic order quantity, etc.), scrap percentages, and other inputs. A demand forecast reflects an independent demand, which is the demand for an end product like computers or bicycles. Dependent demand, on the other hand, is demand for component parts or sub-assemblies, such as the demand for microchips in the computers or wheels on the bicycles. Quantities for dependent demand are derived from independent demand using the bill(s) of material. A planning system may need to consider not only the quantities of each of the component parts needed but also the lead times needed to produce and receive the dependent demand items.

MRP can often be expressed as an optimal control problem, and the resulting optimal control problem can be solved by dynamic programming. However, dynamic programming techniques (such as dynamic lot-sizing) were perceived to be too complex. A few approximate heuristics have been developed for optimal control problems, but such heuristics used in MRP systems to date rely on gross simplifications. For example, the Silver-Meal heuristic is a forward-looking technique that requires determining an average cost per period as a function of the number of periods that a current order is to span and stopping the computation when this function first increases. Well-known techniques used to find order quantities may be dynamic lot-sizing, a Silver-Meal heuristic, and/or a least-unit-cost heuristic. As a result of such simplifying heuristics, MRP techniques determined using existing software are not optimal. Thus, currently-available MRP techniques typically suffer from three major drawbacks. First, dynamic programming techniques to the optimal control formulation of MRP algorithms were perceived to be too complex, and legacy MRP systems rely on grossly-simplified approximate heuristic solutions to the problem that cause non-optimal formulations and fail to offer effective MRP techniques. Second, these approaches rely on input parameters to account for uncertainties associated with supply and demand functions that are set by end users in an ad-hoc fashion without rigorous analysis of uncertainty associated with historical supply and demand. Third, approximate techniques to MRP do not learn from nor adapt to the uncertainties and the time-varying and customer- or supplier-dependent operational constraints surrounding a manufacturing process. These limitations, along with disparate and siloed data across multiple enterprise resource planning (ERP) systems resulting in stale and limited insights for planners, have led to overly-conservative inventory estimates due to hard-to-quantify uncertainties.

A lack of end-to-end visibility and a lack of system-level optimal decision-making makes today's supply chains suffer from several issues. For example, delayed arrivals of purchase parts by suppliers cause production delays for downstream components, and delays in the production of components result in production delays for top-level products. Therefore, purchase part delays lead to overall trapped inventories and increased inventory holding costs. Also, most manufacturing processes suffer from poor forecasts. Demand forecasts often end up being (i) under-forecasts, which lead to stock-outs and poor OTIF, or (ii) over-forecasts, which lead to excess inventory and large amounts (possibly hundreds of millions of dollars or more) of capital locked up in unused inventory.

In view of these challenges in inventory management systems, a “big data” artificial intelligence platform (also called a machine learning platform) may be used to aggregate data from multiple disparate source systems (such as enterprise systems, Internet of Things or “IoT” sensors, and third-party data providers) and apply artificial intelligence-based techniques that continually incorporate and learn from new or updated datasets. For example, the types of data useful for optimizing inventory may include demand forecasts, supplier orders, production orders, (time-varying) bills of material, change histories of re-order parameters, and inventory movement data. Recognizing the need for improved inventory management and optimization, this disclosure provides for hyperparameter inventory optimization using artificial intelligence. As described in more detail below, systems and methods for improved hyperparameter tuning in simulations for management and planning optimization using machine learning techniques are provided. These systems and methods may be applied to improve inventory management in real-time, substantially real-time, just-in-time, or periodically in hours, days, weeks, months, or other time periods. This can be accomplished by more accurately determining optimal inventory levels, which are robust to sudden unexpected changes or volatilities in the levels of uncertainty during the operation of the systems and methods. Among other things, these systems and methods may advantageously apply machine learning to accurately manage and predict inventory variables with future uncertainties, which can be used to improve inventory management by more accurately determining optimal inventory levels. Such systems and methods may allow accurate predictions of future uncertainties in inventory variables based on aggregated data from multiple disparate data source systems, determination of optimal inventory levels, and identification of actionable recommendations to users or systems.

By implementing improved inventory management and optimization, companies across a broad range of industries, such as manufacturing, automotive, and retail, may achieve significance reductions in inventory. In some cases, inventory reductions of 20% to 25% or more may be achieved through optimization, thereby decreasing costs by about 2% to 5% or more of revenues. Such companies, which may typically lock up a significant part of their working capital in inventory (such as an average inventory ranging from 10% to 20% of revenue) can reinvest the cost savings into the company's business in order to increase shareholder value. For example, a company with $10 billion in annual revenue can potentially free up $200 million to $500 million in working capital by optimizing their inventory using the systems and methods provided here.

In order to effectively apply artificial intelligence-based techniques to inventory management and optimization systems, data may be aggregated from various disparate source systems, such as one or more enterprise resource planning (ERP) systems, one or more asset management (AM) systems, one or more supplier management (SM) systems, and one or more inventory planning (IP) systems. In some cases, enterprises may engage third-party service providers to perform data integration, which may be costly. Alternatively or additionally, enterprises may attempt to perform data integration in-house using open-source technologies, but such approaches often encounter significant complexities and monetary and time costs with uncertain success. Using the systems and methods of this disclosure, enterprises can apply artificial intelligence-based hyperparameter tuning in simulations for management and planning optimization algorithms on platforms that enable seamless, scalable, and reliable integration of data sets from multiple disparate source systems. Once data aggregation and integration have been performed, artificial intelligence-based hyperparameter tuning in simulation techniques can be used to effectively and dynamically manage uncertainty and systematically improve real-world logistics, such as reducing inventory levels across various (possibly all) locations while minimizing the probability of stock-outs. As a particular example, systems and methods of this disclosure can apply key elements of artificial intelligence-based hyperparameter tuning techniques, including statistical modeling, machine learning, and optimization, to significantly improve inventory optimization.

In some aspects, this disclosure provides a computer-implemented method for inventory management and optimization. The method for inventory management and optimization may include obtaining an inventory dataset having a plurality of inventory variables, where the inventory variables include variables having future uncertainties. The method may also include applying a trained algorithm to the inventory dataset in order to generate predictions of the variables having the future uncertainties. The method may further include applying an optimization algorithm to the inventory dataset in order to optimize the inventory variables, thereby generating an optimized inventory dataset. Results of the artificial intelligence-based hyperparameter tuning can be used to control, instruct, message, etc. one or more logistics systems, such as ERP, AM, SM, and IP systems.

Example embodiments of the hyperparameter tuning systems and methods disclosed herein can be used with logistics optimization applications. In some example implementations, hyperparameter tuning as part of a logistics optimization application can be used with a model-driven architecture that includes a type system. A model-driven architecture is a term for a software design approach that provides models as a set of guidelines for structuring specifications. An example model-driven architecture may include a type system that may be used as a domain-specific language (DSL) within a platform used to access data, interact with data, and/or perform processing or analytics based on one or more type or function definitions within the type system. By using an abstraction layer provided by a type system, the complexity of a logistics optimization application problem can be reduced by orders of magnitude, such as to the order of a few thousand types, for any given logistics optimization application that a programmer manipulates using JAVASCRIPT or other language to achieve a desired result. Thus, all of the complexity of the underlying foundation (with an order of M×S×T×A×U using structured programming paradigms) is abstracted and simplified for the programmer. Here, M represents the number of process modules (APACHE Open Source modules are examples of process modules), S represents the number of disparate enterprise and extraprise data sources, T represents the number of unique sensored devices, A represents the number of programmatic APIs, and U represents the number of user presentations or interfaces. Example technologies that can be included in one or more embodiments may include nearly-free and unlimited compute capacity and storage in scale-out cloud environments, such as AMAZON Web Services (AWS); big data and real-time streaming; smart connected devices; mobile computing; and data science including big-data analytics and machine learning to process the volume, velocity, and variety of big-data streams.

The type system of the model-driven architecture may include types as data objects and at least one of: associated methods, associated logic, and associated machine learning classifiers. One or more of the data objects may be associated with at least one of: one or more customers, one or more companies, one or more accounts, one or more products, one or more employees, one or more suppliers, one or more opportunities, one or more contracts, one or more locations, and one or more digital portals. Type definitions may include properties or characteristics of an implemented software construct.

Employing the type system of the model-driven architecture may include performing data modeling to translate raw source data formats into target types. Sources of data may be associated with at least one of: accounts, products, employees, suppliers, opportunities, contracts, locations, digital portals, geolocation manufacturers, supervisory control and data acquisition (SCADA) information, open manufacturing system (OMS) information, inventories, supply chains, bills of materials, transportation services, maintenance logs, and service logs. Among other things, the type system can be employed to perform data modeling in order to translate raw source data formats into target types. Sources of data for which data modeling and translation can be performed may include accounts, products, employees, suppliers, opportunities, contracts, locations, digital portals, geolocation manufacturers, SCADA information, OMS information, inventories, supply chains, bills of materials, transportation services, maintenance logs, or service logs.

The model-driven architecture enables capabilities and applications including precise predictive analytics, massively parallel computing at the edge of a network, and fully-connected sensor networks at the core of a business value chain. The model-driven architecture can serve as the nerve center that connects and enables collaboration among previously-separate business functions, including product development, marketing, sales, service support, manufacturing, inventory, finance, shipping, order management, human capital management, etc. Some embodiments may include a product cloud that includes software running on a hosted elastic cloud technology infrastructure that stores or processes product data, customer data, enterprise data, and Internet data. The product cloud may provide one or more of: a platform for building and processing software applications; massive data storage capacity; a data abstraction layer that implements a type system; a rules engine and analytics platform; a machine learning engine; smart product applications; and social human-computer interaction models. One or more of the layers or services may depend on the data abstraction layer for accessing stored or managed data, communicating data between layers or applications, or otherwise storing, accessing, or communicating data.

An example logistics optimization application on the model-driven architecture can include functions and modules to improve machine learning processes and performance with logistical uncertainty, such as an inventory module, a prediction module, a simulation module, a tuning module, an optimization module, an aggregation module, an automation module, a control module, etc.

An example model-driven architecture for integrating, processing, and abstracting data related to an enterprise logistics optimization application development platform can include tools for machine learning, application development and deployment, data visualization, automated control and instruction, other tools (such as an integration component, a data services component, a modular services component, and an application that may be located on or behind an application layer), etc. The model-driven architecture may operate as a comprehensive design, development, provisioning, and operating platform for industrial-scale applications in various industries, such as energy industries, health or wearable technology industries, sales and advertising industries, transportation industries, communication industries, scientific and geological study industries, military and defense industries, financial services industries, healthcare industries, manufacturing industries, retail, government organizations, and/or the like. The system may enable integration and processing of large and highly dynamic data sets from enormous networks and large-scale information systems.

An integration component, data services component, and modular services component may store, transform, communicate, and process data based on the type system. In some embodiments, the data sources and/or the applications may also operate based on the type system. In an example embodiment, the applications may be configured to operate or interface with the components based on the type system. For example, the applications may include business logic written in code and/or accessing types defined by a type system to leverage services provided by the system.

In some embodiments, the model-driven architecture uses a type system that provides type-relational mapping based on a plurality of defined types. For example, the type system may define types for use in the applications, such as a type for a customer, organization, device, or the like. During development of an application, an application developer may write code that accesses the type system to read or write data to the system, perform processing or business logic using defined functions, or otherwise access data or functions within defined types. In some embodiments, the model-driven architecture enforces validation of data or type structure using annotations/keywords. The types in the type system may include defined view configuration types used for rendering type data on a screen in a graphical, text, or other format. In some embodiments, a server, such as a server that implements at least a portion of the system, may implement mapping between data stored in one or more databases and a type in the type system, such as data that corresponds to a specific customer type or other type.

One example of a type system is given by way of the following non-limiting example, which may be used in various embodiments and in combination with any other teachings of this disclosure. In some embodiments, the fundamental concept in the type system is a “type,” which is similar to a “class” in object-oriented programming languages. At least one difference between “class” in some languages and “type” in some embodiments of the type system disclosed here is that the type system is not tied to any particular programming language. As discussed here, at least some embodiments disclosed here include a model-driven architecture, where types are the models. Not only are types interfaces across different underlying technologies, they are also interfaces across different programming languages. In fact, the type system can be considered self-describing, so below is presented an overview of the types that may define the type system itself.

A type is the definition of a potentially-complex object that the system understands. Types may be the primary interface for all platform services and the primary way that application logic is organized. Some types are defined by and built into the platform itself. These types provide a uniform model across a variety of underlying technologies. Platform types also provide convenient functionality and build up higher-level services on top of low-level technologies. Other types are defined by the developers using the platform. Once installed in the environment, they can be used in the same ways as the platform types. There is no sharp distinction between types provided by the platform and types developed using the platform.

The logistics optimization application can be used with various enterprise functions, such as messaging, reporting, alerting, etc. processes to update systems based on triggers, detecting anomalies, real-time data streams, etc. In example enterprise environments, the logistics optimization application can control or instruct manufacturing or resource planning systems. In an example implementation when volatility is predicted or detected in supply chains networks, simulations using hyperparameters and uncertainty distributions can be employed to automatically realize instructions or commands that can re-strategize to better leverage manufacturing, such as minimizing the amount of inventory held in a supply chain.

Statistical Modeling of Uncertainty

In some embodiments, an inventory module (such as a hardware module or a software routine) may be programmed or configured to obtain an inventory dataset. The inventory dataset may include multiple inventory variables, such as inventory variables having future uncertainties. As examples, uncertainty may pertain to a difference between an actual consumption versus a forecasted consumption (demand forecast), a difference between an ordered quantity versus a delivered quantity, a difference between a promised delivery date versus an actual delivery date, etc. As particular examples, variables having future uncertainties (such as stochasticity) may include inventory levels, supply factors, supplier orders, demand factors, demand forecasts, material consumptions, transit times, lead times, material requirements planning (MRP), inventory holding costs, and shipping costs.

For a given enterprise, the distribution of a variable's uncertainty (such as of an inventory variable) may be modeled using historical data. For example, the transit or lead time (such as of goods or materials) from a supplier to a manufacturing facility is often stochastic and not deterministic and may depend on one or more external factors, such as network congestion, weather, and geo-political events. As a particular example, if a simple Gaussian distribution is assumed for the transit time, such a Gaussian distribution can be fitted to a set of observed historical data to estimate a mean and a variance of the transit time. However, in practice, the actual distribution of transit time is often asymmetric, and the Gamma distribution may be used where the shape and the scale parameters can be estimated from historical data. Statistical modeling of uncertainty in lead time by fitting a Gamma distribution to observed lead time data may be employed. This distribution may be calculated over a lead time of, for instance, no more than about 5 days, no more than about 10 days, no more than about 15 days, no more than about 20 days, no more than about 25 days, no more than about 30 days, no more than about 35 days, no more than about 40 days, no more than about 45 days, no more than about 50 days, no more than about 55 days, no more than about 60 days, no more than about 70 days, no more than about 80 days, or no more than about 90 days.

Inventory or other variables may include one or more time series to represent time-varying data, such as historical inventory data and/or current inventory data. Historical inventory or other historical variable data may be provided by one or more files, external data streams, input interfaces, etc. or calculated in a system by leveraging material movement data or other data. For example, historical inventory data can include different types of movements related to inventory management and optimization, such as arrival movements, consumption movements, blocked movements, and miscellaneous movements (such as inter-factory movements).

In some embodiments, an aggregation module (such as a hardware module or a software routine) may be programmed or configured to obtain and aggregate datasets from a plurality of disparate sources. For example, the datasets can include internal datasets and external datasets. Examples of disparate sources may include smart devices, sensors, enterprise systems, extraprise systems, and Internet data sources. Such datasets may be persisted across one or more data stores.

Random variables associated with different sources of uncertainties within a supply chain network can be divided into independent and dependent random variables. Independent uncertainty sources can be modeled. Dependent uncertainty sources, however, may be derived mainly from the independent sources and how the independent sources affect the dependent sources. This dependency structure is commonly encoded using probabilistic graphical models (PGMs), such as Bayes or Markov networks depending on the dependency assumptions. The PGM structure is affected by the graph-based representation of the supply network. Having modeled the independent sources of uncertainty, PGM-based inference techniques can be used to predict distributions or statistical properties of the dependent sources of uncertainty.

Modeling and Prediction of Stochastic Variables with Future Uncertainty

Uncertainty is an intrinsic property of modern, complex supply chains. There may be a number of sources of uncertainty in a supply chain network. Examples of three major sources of uncertainty include (i) supplier-related uncertainties, (ii) facility-related uncertainties, and (iii) demand uncertainties. Supplier-related uncertainties may include uncertainties in the quantity, quality, or price of source materials. Supplier-related uncertainties may also include uncertainties of when such source materials will be available or how long such source materials will take to ship. Facility-related uncertainties may include uncertainties in the availability of production resources, such as laborers, machines, time, etc. Demand uncertainties may include uncertainties in the demand for final products. Demand may change over time and by geography. There may be other sources of uncertainties in complex supply chains, such as shipping uncertainties. Some examples of particular uncertain variables in supply chains are inventory levels, supply factors, supplier orders, demand factors, demand forecasts, material consumptions, transit times, seasonality, lead times, material requirements planning (MRP), inventory holding costs, and shipping costs.

An uncertainty module (such as a hardware module or a software routine) may model one or more of the above-mentioned uncertainties and/or any other type(s) of uncertainties that may be associated with at least one complex supply chain. More specifically, the uncertainty module can implement machine learning models or other types of models that are programmed or configured to predict distributions of variables (such as inventory variables) that have future uncertainties. In some cases, the models can be trained using historical values of the inventory variables.

One example of a stochastic inventory variable is transit time, which may depend on one or more external factors like network congestion, weather, and geo-political events. If transit time has or is assumed to have a Gaussian distribution, the systems and methods described here can fit a Gaussian distribution to a set of historical transit times in order to estimate a mean and a variance of future transit times. If transit time instead has or is assumed to have an asymmetric distribution, the systems and methods described here can fit, for example, a Gamma distribution to the historical transit time in order to estimate these parameters. More generally, the models described here can represent any suitable machine learning models or other models like parametric models (such as linear regression models, logistic regression models, quantile regression models, support vectors machines or “SVMs,” random forest models, boosted tree models, etc.) that can be used to predict parameters (such as median, mean, mode, variance, standard deviation, quantile, measure of central tendency, measure of variance, range, minimum, maximum, interquartile range, percentile, or combination thereof) of the inventory variables. As one particular example, regression models may be trained from historical data to learn how these distributions vary over time based on features such as season of the year, etc. The trained regression models may be used to predict the prior and conditional distributions of the random variables. Each node in a supply chain may estimate the distribution of the random variables locally and share this information with other nodes in the supply chain, such as by using belief propagation techniques. The nodes can continue to propagate their beliefs to other nodes in the system until convergence occurs. Once the beliefs converge, suitable actions can occur, such as by estimating a recommended safety stock at each node locally using the conditional distribution of the inventory variable.

In other embodiments, the models may be non-parametric models, such as Gaussian processes, Dirichlet processes, or other Bayesian sampling-based techniques. A Gaussian process is a stochastic model defined by a collection of random variables indexed by time. Each finite collection of the random variables has a multivariate normal distribution. That is, each finite collection of the random variables is normally distributed. The distribution of a Gaussian process is the joint distribution of all of the random variables and, as such, is a distribution over functions with a continuous domain. A Dirichlet process is a stochastic model whose range itself is a set of probability distributions.

The distribution of uncertainty of inventory variables often tends to change over time. For example, the variance in the transit time of a source material or product may increase during the winter season. As such, the models described above may be used to predict distributions of inventory variables over future durations of time, where the future durations of time may correspond to planning horizons for the inventory variables being optimized. The planning horizons may vary depending on the customer, supplier, and/or the material. As particular examples, the planning horizons may be about 1 day, about 3 days, about 5 days, about 1 week, about 2 weeks, about 3 weeks, about 1 month, about 2 months, about 3 months, about 4 months, about 5 months, about 6 months, about 7 months, about 8 months, about 9 months, about 10 months, about 11 months, about 12 months, about 14 months, about 16 months, about 18 months, about 20 months, about 22 months, about 24 months, or more. In some cases, the planning horizons may dynamically change as new data is incorporated into the models. In cases where one or more models show deterioration of performance, the one or more models can be re-trained automatically and leverage the most recent data available.

In some embodiments, a statistical modeling of uncertainty in lead time may fit a Gamma distribution to observed lead time data. As particular examples, the distribution may be calculated over a lead time of no more than about 5 days, no more than about 10 days, no more than about 15 days, no more than about 20 days, no more than about 25 days, no more than about 30 days, no more than about 35 days, no more than about 40 days, no more than about 45 days, no more than about 50 days, no more than about 55 days, no more than about 60 days, no more than about 70 days, no more than about 80 days, or no more than about 90 days. In other cases, the distribution may be calculated over a lead time of less than 5 days. Historical trends in lead time over a period of time (such as about 28 months) may be used to train a machine learning algorithm to predict future uncertainty in lead time.

Prediction of Stochastic Variables and Simulation of Effects on Inventory Management

Tools that may leverage the models described above and related new models can proactively, rather than reactively, make operational decisions in supply chain management. For example, tools may be used to perform “what-if” simulations. A simulation module (such as a hardware module or a software routine) may conduct “what-if” simulations, which may simulate what would have happened in a particular time period if a different action had been taken in the past during the inventory management process, such as if a different safety stock had been used. The simulations can use historical data and/or modeled uncertainty distributions to simulate stochasticity. To provide a concrete example, one way to implement such a simulation framework is as follows.

The simulation module can obtain data related to historical replenishment outcomes. Such data can provide valuable insights into how inventory for different parts have been managed at a facility. Such data may include (i) material movements, such as how or when a part has been consumed or moved from or to available inventory, (ii) demand forecasts, such as daily, weekly, or monthly forecasts (like on a product or part level), and (iii) arrival patterns, such as how suppliers have honored their obligations. The simulation module can use an MRP algorithm to process this data and simulate the effects of changing different parameters in the inventory management process.

As one example, the simulation module can investigate the effect of changing the safety stock of an item while fixing all other parameters. Starting with some initial inventory at the beginning of a simulation period and knowing the demand forecast through the period, the simulation module may simulate the inventory management process during that period by running the MRP algorithm based on one or more new choices of safety stock. This way, knowing the material movement history, the simulation module may evaluate the robustness and cost effectiveness of the new choice(s) of safety stock. Because the simulation module may change some of the parameters, it can schedule new arrivals during a period that may be different from what was observed in the historical data. However, there may be uncertainty related to supplier behaviors. Therefore, in order to make the what-if analysis more realistic, the simulation module may also simulate the effect of supplier uncertainty on the new scheduled arrivals. To do so, one or more parametric and/or non-parametric models described above may be incorporated into the simulation.

In some cases, analysis can be done by extracting the uncertainties associated with the historical quantity and timing of arrivals. These uncertainties may be represented using empirical distributions or through fitting suitable parametric or non-parametric distributions to these populations. The simulation module can simulate the uncertainty associated with each newly-scheduled arrival by sampling from these distributions. For example, the scheduled arrival of 50 units of a part for a day can be t+5. The simulation module can simulate uncertainties pertaining to the quantity and timing of this arrival by sampling from their corresponding distributions. In this example, the samples from the quantity and time uncertainties can be ten and two, respectively. The simulation module can simulate that the scheduled arrival has actually arrived on day t+7 with a quantity of 40. Notice that the information concerning the perturbation is not known to the replenishment process until it is realized at time t+5. In other words, the arrival that will be delayed is known at time t+5 but not by how much. Once at time t+7, the arrival expected at time t+5 arrives, but only 40 units are received instead of 50.

Implementations of the framework disclosed herein may be modular and can incorporate different replenishment approaches and different ways for simulating supplier or uncertain movement effects. Moreover, the disclosed approach is one approach for simulating uncertainty and conducting a what-if simulation that looks backward in time. The approach can also be conducted forward in time. For the forward-looking case, the simulation module may rely on predictive models of uncertainties to simulate the uncertainties (rather than relying on known uncertainties). Thus, the simulation module can be used to predict what may happen in the future. For example, the simulation module can simulate what would happen in the future considering particular uncertainties in inventory variables. For this, the simulation module can use the uncertainty models described above to simulate uncertainties and inject such uncertainties into the inventory management process.

To run an MRP simulation for a time horizon in the future, given all other re-order parameters, one approach that informs upon the inventory management process relies on studying the effect of future uncertainties on the future/forward-projected inventory profile. For instance, the simulation module can run the MRP with a given choice of re-order parameters, and the MRP can schedule arrivals in the future to keep up with the demand forecast and based on other re-order parameters. In the case where there are no uncertainties, the inventory may not go below zero. If there are uncertainties, the simulation module can sample, for example, a sequence of time and quantity uncertainties from their corresponding predictive distributions generated by one or more parametric and/or non-parametric models described above. Time uncertainty sequences can be used for perturbing the scheduled arrivals by the MRP, and quantity uncertainty sequences can be used for perturbing the demand forecast (consumption in the future) and available inventory. Each combination of uncertainty sequences may result in a perturbed inventory profile. Repeating this process for several of such uncertainty sequence combinations may generate several perturbed profiles for different uncertainty pairs. This provides an empirical joint distribution of the forward-projected inventory profile. This empirical distribution can be used, for example, to provide an estimate of obtained future service level given the considered management practices.

The presented simulation approaches enable estimation of different stochastic variables over a horizon into the future, which includes inventory and service levels. These simulation tools may enable systems to evaluate changes to management practices, adjust expectations for what is to come in the future, and make more informed decisions. The simulation module may additionally quantify the uncertainties associated with placed orders with suppliers (such as orders that have not reached their due dates) and uncertainties associated with customer orders received by a facility. This can benefit from the models discussed above or may use additional models that are developed. These enable operators to manage their inventory in a more proactive rather than reactive fashion.

Similar to a single facility case, a simulation module (such as a hardware module or a software routine) can conduct what-if simulations on a supply chain network having multiple facilities. In order to conduct a simulation in a coherent fashion, the structure of a graph (such as a directed graph) that represents the supply chain network can be followed. As one example, the replenishment processes or MRPs used at each facility in the supply chain are treated as known or determinable. Starting from customer-facing facilities and based on the demand forecast at those facilities (independent demand), the simulation module can produce “dependent” demands from these facilities to their supplying facilities/nodes. This propagates through the network until reaching facilities/nodes that are only receiving supplies from facilities external to the supply network. This mimics a backward pass through the network, where facilities create demand for their supplying facilities given their dependent and independent demands. The simulation module can also conduct a forward pass through the network to simulate supply processes in the network. During the forward pass, the simulation module can simulate uncertainties in the network associated with supply edges in the network and to facilities and their associated independent demands. Repeating this process for every timestep in the simulation period allows full simulation of the behavior of the supply chain. Because this process is performed for a period in the past, exact realizations of certain sources of uncertainties or the uncertainty model outputs can be used for simulating uncertainties in the supply chain.

This process can also be replicated forward in time in a similar fashion, where the uncertainty models are relied upon for simulating the effects of the uncertainties. To be more specific, an example of such a simulation approach can follow the following procedure. The simulation module can conduct a backward pass of the supply chain network as described above. In the case where there are no uncertainties, all facilities will be able to supply their customer facilities, and no facility will face stock-outs. In the case of uncertainties, the simulation module can sample sequences of time and quantity uncertainties from their corresponding predictive distributions. This may involve running multiple forward passes through the supply chain network and using models for independent uncertainty sources. Specifically conducting forward passes may amount to sampling from the stochastic processes (as defined by the PGMs as described above). Each forward pass results in a perturbed inventory profile, which in turn provides an empirical joint distribution of the forward-projected inventory profile. This empirical distribution can be used, for instance, to provide an estimate of obtained future service level given the considered management practices.

The simulation module can also enable computation of forward projections that might happen into the future. That is, in the case of knowledge of replenishment processes or MRPs used at each facility in the supply chain, the simulation module can simulate what would happen in the future in the presence of uncertainties and study the effectiveness of choices of re-order parameters at each time step. Similarly, the simulation module can quantify the uncertainties associated with placed orders with suppliers (such as orders that have not reached their due dates) and uncertainties associated with customer orders received by each facility. This could benefit from the models discussed above or may involve developing additional models for each connected facility pair. These enable operators at each facility to manage the inventories in a more proactive (rather than reactive) fashion while having information that also incorporates the structure of the supply chain.

Inventory Management and Optimization

Inventory management and optimization may concern optimizing three different categories of variables: (i) variables set by a manufacturer that provide robustness with respect to sources of uncertainty, (ii) variables concerning interaction with suppliers, such as order timing and quantity and other parameters governing the supplier interactions that are set through negotiations with the suppliers (like lead time, minimum order quantity, etc.), and (iii) variables defining production planning, such as production plans and schedules for satisfying customer orders.

Regarding variables set by a manufacturer that provide robustness with respect to sources of uncertainty, in order to optimize variables that provide robustness, an optimization module (such as a hardware module or a software routine) can leverage the simulation methodologies discussed above. As a particular example, the optimization module can evaluate the performance of different combinations of values of the variables under consideration. For instance, the optimization module can perform what-if simulations for periods in the past. For every combination of values, the optimization module may run a series of simulations to evaluate the performance of the combination. The performance criteria may be operational costs and obtained service levels. In order to pick what combinations to evaluate, binary searches, grid searches, random searches, or Bayesian optimization may be used in some embodiments.

The optimization module can alternatively or additionally perform forward-looking what-if simulations for periods in the future. For every combination of values, the optimization module may run a series of simulations to evaluate the performance of the combination. The performance criteria may be operational costs and obtained service levels. In some cases, the optimization module may use binary searches, grid searches, random searches, or Bayesian optimization to pick what combinations to evaluate.

The optimization module can alternatively or additionally project future stochastic inventory variables. For every combination of values, a series of forward-projections may be run to evaluate the performance of the combination. The performance criteria may be operational costs and obtained service levels. The optimization module may use binary searches, grid searches, random searches, Markov Chain Monte Carlo (MCMC) optimization, or Bayesian optimization to pick what combinations to evaluate in some embodiments. In this example, the optimization module may not need to evaluate different combinations and may be able to derive suitable combinations from the obtained distributions of forward-projected stochastic variables.

The variables in the different categories mentioned above (those set by a manufacturer, those concerning interaction with suppliers, and those defining production planning) may be selected in a number of different ways. For example, the optimization module can use different combinations of selection rules or policies for selecting the variables under consideration. These rules may be static, be parametrized by certain parameters (such as order-up-to-policy), or be based on quantile models discussed above. As one example, the optimization module may optimize safety stock and safety time, and the optimization module may use a combination of different quantile models to quantify uncertainties and different models for time uncertainties for tuning safety stock and safety time, respectively. Safety stock levels may correspond to excess inventory that is to be held to provide robustness with respect to quantity uncertainties. Safety time may correspond to a time buffer that is used for alleviating possible delays from suppliers or to accommodate changed timelines by customers with minimal adverse effects. For evaluating different combinations of selection rules/policies, backward-looking simulations, forward-looking what-if simulations, and forward projections of stochastic variables as described above may be used.

The optimization module can also use optimization algorithms that do not rely on simulation approaches. For example, the optimization module can parametrize a mathematical optimization problem with parameters that include the variables under consideration. This may lead to stochastic mixed-integer linear programming (MILP), which can leverage outputs from uncertainty models to form stochastic terms of an objective function of an optimization problem or stochastic constraints associated with it, such as chance constraints. In some cases, MILP may utilize an MCMC algorithm to sample the uncertainties of variables. The cost to optimize may be an inventory holding cost, ordering cost, production or operational cost, sales lost, achieved profits, etc. The constraints may include inventory evolution or operational constraints within a facility, such as encoding BOM, replenishment process constraints, and demand satisfaction or management constraints.

For inventory management and optimization operations that involve the category of variables concerning interaction with suppliers (such as order amounts and timing), the optimization module can use a direct mathematical optimization approach. This optimization is commonly conducted in the case of legacy MRP frameworks that lack the necessary sophistication to handle complexities of interacting with suppliers and hence are replaced by this optimization framework. This commonly leads to stochastic MILPs, which can leverage the outputs from the models for uncertainty to form stochastic terms of the objective function of the optimization problem or stochastic constraints associated with it, such as chance constraints. The cost to optimize may be inventory holding cost, ordering cost, production or operational cost, sales lost, achieved profits, etc. The constraints may be or include inventory evolution, operational constraints within a facility, replenishment process constraints (such as any replenishment constraints that are not the target of optimization), and demand satisfaction or management constraints. The constraints and terms in the objective function that concern interactions with suppliers may encode costs associated with different interaction approaches with different suppliers and rules associated with these interactions (which are commonly conditional and time-varying constraints), such as (i) time-varying multi-column pricing and (ii) timing and permissions associated with cancelling or adding to existing outstanding orders. This optimization formulation may have the necessary flexibility to jointly optimize these variables and those concerning robustness. In the event that this problem is prohibitively costly to solve, the optimization module may take other actions, such as decomposing the problem and using distributed algorithms for solving the problem or simultaneously solving relaxations (which commonly result in stochastic linear problems) and restrictions (projection techniques) of these problems. This can enable the system to provide approximate solutions to the problem but also quantify the level suboptimality of the approximate solutions.

For inventory management and optimization operations that involve the category of variables concerning production planning, the optimization module can also use a direct optimization approach to optimize variables concerning production planning and/or variables related to determining how to satisfy sales orders. This also commonly leads to stochastic MILPs, which can leverage the outputs from the uncertainty models described above to form stochastic terms of the objective function of the optimization problem or stochastic constraints associated with it, such as chance constraints. The cost to optimize may be inventory holding cost, ordering cost, production or operational cost, sales lost, achieved profits, etc. The constraints may be or include inventory evolution, operational constraints within a facility, constraints that clearly encode a replenishment process framework, and demand satisfaction or management constraints based on contractual obligations. Such obligations may also be included in the cost function. The constraints and terms in the objective function that concern interactions with customers can clearly encode costs associated with different interaction approaches with different customers and their associated contractual obligations, which may include hard-coded rules associated with these interactions (which are commonly conditional and time-varying constraints), such as time-varying penalties for missed orders or constraints concerning latest possible delivery dates. The constraints may also encode interactions among equipment involved in the production process, which may not be simply represented using BOM. The optimization formulation has the necessary flexibility to jointly optimize these variables and those concerning robustness and/or the ones concerning replenishment process.

As noted above, the distribution of uncertainty often tends to change over time, such as when the variance in transit time may increase during the winter season. As a result, in addition to estimating the distribution of transit time based on past data, effective inventory management and optimization methods and systems can predict this distribution over the planning horizon. Machine learning can be applied to model stochastic variables with future uncertainty by learning past trends in uncertainty distributions and predict the future uncertainties of such stochastic variables. In some embodiments, a prediction module (such as a hardware module or a software routine) may be programmed or configured to apply a trained algorithm to an inventory dataset in order to generate a prediction of stochastic variables having future uncertainties. In some cases, the trained uncertainty model algorithm may include a machine learning algorithm, such as a support vector machine (SVM), a naïve Bayes classification, a linear regression, a quantile regression, a logistic regression, a random forest, a neural network, or a combination thereof. As a particular example, a prediction may be generated by processing the inventory dataset to fit a statistical distribution to a plurality of inventory variables. The statistical distribution may be fitted by estimating one or more statistical parameters using the historical inventory data. For example, the statistical distribution may be a parametric distribution, such as a Gaussian distribution, a Gamma distribution, or a Poisson distribution. The statistical parameters may include, for example, a median, mean, mode, variance, standard deviation, quantile, measure of central tendency, measure of variance, range, minimum, maximum, interquartile range, percentile, or combination thereof.

The inventory management and optimization systems and methods here may further use the statistical distributions to generate the predictions of the stochastic variables having future uncertainties. The predictions may include a distribution of the stochastic variables having future uncertainties. For example, the distribution of the stochastic variables having future uncertainties may include a distribution over a future duration of time. The future duration of time may correspond to a planning horizon for the material or item being optimized. The planning horizon may vary depending on the customer, supplier, and the material. For example, the future duration time may be about 1 day, about 3 days, about 5 days, about 1 week, about 2 weeks, about 3 weeks, about 1 month, about 2 months, about 3 months, about 4 months, about 5 months, about 6 months, about 7 month, about 8 months, about 9 months, about 10 months, about 11 months, about 12 months, about 14 months, about 16 months, about 18 months, about 20 months, about 22 months, about 24 months, or more than about 24 months. Observation of historical trends in lead time over a period of time (such as about 28 months), may be used to train a machine learning algorithm to predict future uncertainty in lead time.

Stochastic Optimization of Inventory Level

Manufacturers typically use rules-based systems to determine the timing and sizes of orders that need to be placed with suppliers. However, the static rules may not account for any variability, which may yield sub-optimal inventory levels. Using artificial intelligence-based (such as machine learning-based) approaches, inventory management and optimization can be formulated as a constrained optimization problem, where a goal is to minimize a cost function (such as an inventory holding cost) under one or several constraints (such as a confidence level of availability of stock).

In some embodiments, stochastic optimization of inventory level of an item over a period of time (such as about 6 months) may be employed. For example, an original inventory level over a duration of time may be configured to have a high probability or confidence of maintaining an inventory level that is at least an original safety stock level. As another example, the optimized inventory level over a duration of time may be configured to have a high probability or confidence of maintaining an inventory level that is at least an optimized safety stock level. Since the optimized safety stock level may be less than the original (non-optimized) safety stock level, the enterprise may realize potentially significant cost savings by maintaining inventory at the optimized safety stock level, rather than the original safety stock level, while still meeting contractual requirements of their customers.

In some embodiments, an optimization module (such as a hardware module or a software routine) may be programmed or configured to apply an optimization algorithm to an inventory dataset in order to optimize inventory variables and generate an optimized inventory dataset. For example, the optimization algorithm may support the use of a constrained optimization problem. Such a constrained optimization problem may minimize a cost function and may include constraints pertaining to a material ordering mechanism or MRP algorithm, such as an inventory constraint, a service level constraint, an arrival window constraint (like days of the week when orders can arrive), an order size constraint (like a minimum order size and rounding value), an ordering window constraint (like inactive or dead periods during which new orders cannot be placed), or a combination thereof. The set of constraints for the constrained optimization problem may help determine allowed times and amounts for which orders can be placed. In some cases, the service level constraint includes a confidence level that an inventory meets a demand requirement (such as when a stock-out event is not experienced). For example, the service level constraint may be about 90%, about 95%, about 98%, or about 99%. The service level constraint may correspond to the service level that is desired by a customer. The desired service level may be a configurable parameter and may vary for each customer and for each material. In some embodiments, the minimized cost function can represent a cost such as an inventory holding cost, a shipping cost, a backorder (such as production delay) cost, or a combination thereof. The cost function may be configurable and can vary with each customer.

The constrained optimization problem may be a stochastic constrained optimization problem. For example, in instances where an enterprise is bound to using currently-implemented legacy MRP approaches, the current MRP algorithm may be treated as a black-box, and the constrained optimization problem may be solved using a black-box optimization algorithm. The optimization algorithm may use any suitable technique for solving the optimization problem, such as a grid search, a random search, a Bayesian optimization search, or a combination thereof. In other embodiments, such as instances where an enterprise is not bound to using legacy MRP approaches, the stochastic constrained optimization problem can be formulated as an MILP problem. The MILP problem may model the variables having future uncertainties using one or more linear chance constraints. The MILP problem may be solved, for example, by jointly optimizing for the inventory and the MRP (such as orders placed).

After the inventory dataset has been optimized, the optimized inventory dataset may be stored in a database. In some cases, the storing may be performed through a cloud-based network (such as in a database located on one or more cloud-based servers). Also, in some cases, the optimized inventory dataset may be generated in real-time, substantially real-time, just-in-time, or periodically in hours, days, weeks, months, or more and/or stored in the database in real-time, substantially real-time, just-in-time, or periodically in hours, days, weeks, months, or more.

The systems and methods for inventory management and optimization may further involve the generation of one or more recommended inventory management decisions based on the optimized inventory dataset. For example, a difference may be determined between the optimized inventory dataset and a reference inventory dataset, and the recommended inventory management decisions may be generated based on the determined difference between the optimized inventory dataset and the reference inventory dataset. In some cases, after the inventory dataset has been optimized, one or more alerts of disruption risks and/or delay risks may be generated based at least in part on the optimized inventory dataset.

Optimization of Daily Inventory Level, Demand, and MRP

In some embodiments, the methods and systems for inventory management and optimization may perform optimization of a daily inventory level. Manufacturing systems typically maintain a log of inventory movements, such as arrivals from suppliers, consumption in a production line, and any other intra- and inter-facility shipments (miscellaneous movements). The movement data can be used to calculate the historical inventory levels for each item, where arrivals have a positive contribution to the inventory level, consumption has a negative contribution to the inventory level, and all other miscellaneous movements can result in either a positive or negative contribution to the inventory level. For example, the inventory at a given time t can be expressed as the inventory at a prior time (t−1), plus the arrivals at time t, minus the consumption at time t, and plus miscellaneous movements at time t as given by the equation below.

Inventoryₜ=Inventoryₜ₋₁+Arrivalsₜ−Consumptionₜ+Miscellaneousₜ (1)

In some cases, observations of historical inventory movements (including arrival movements, consumption movements, and miscellaneous movements) and total inventory over a period of time (such as about 6 months) may be employed.

Also, in some embodiments, the methods and systems for inventory management and optimization may perform optimization of a demand forecast. In the case of manufacturers, a demand forecast (or planned consumption) for each item over a planning horizon can be determined using the forecasted demand for finished products, product configurations, and one or more BOMs. Each BOM may represent a dynamic (time-varying) hierarchical graph that provides a list of the items and intermediate assemblies required to manufacture a finished product, along with their quantities. A traversed BOM may be displayed to a user. For example, the BOM may be traversed and displayed to the user in real-time.

Further, in some embodiments, the methods and systems for inventory management and optimization may perform optimization of MRP. MRP is often based on several constraints that determine the timing and quantity of orders that need to be placed with suppliers. For example, such constraints may be defined using re-order parameters. In some cases, re-order parameters may be categorized into three groups: (i) parameters determined by the manufacturer (such as safety stock, lot size, breakage, warranty replacement, or safety time), (ii) parameters determined by the supplier (such as minimum order size, lead time, etc.), and (iii) parameters determined by the customer (such as cancellations and returns).

In addition, in some embodiments, the methods and systems may formulate inventory management and optimization as a stochastic constrained optimization problem that solves for the optimal values of re-order parameters (such as safety stock) that minimize the total landed cost (such as inventory holding and shipping costs, accounting for variability in the price of the inventory items) while maintaining a level of confidence (a) on the availability of items in stock (such as a service level constraint). The service level constraint may be adjustable for each item (such as with a 90%, 95%, 96%, 97%, 98%, or 99% confidence), thereby providing the manufacturer a level of control based on several factors, such as cost of stock-outs and service level agreements with their customers.

By solving the stochastic constrained optimization problem, a set of stochastic variables may be simulated or predicted, and the predictions can be incorporated into the optimization problem. For example, variables corresponding to stochastic components of a supply chain (such as stochasticity associated with supply for each facility in the supply chain) can be modeled. In some cases, this can be done by conducting a forward pass through the supply chain. As a particular example, the forward pass can begin with facilities i without children. For these facilities, it is known what arrivals will actually arrive at time t and what arrivals are scheduled to arrive at the facility. For the latter, the stochasticity (uncertainty) in quantity and time can be simulated to predict what portion of one or more arrivals will be realized that day, and the result can partly define the end-of-day inventory of that facility for that day.

Moreover, each of these facilities (having run their MRPs at time t) may select or decide how much of the dependent and independent demand is to be satisfied or optimized against. Each facility, given its available inventory of the day and knowledge about the set of material movements that have occurred in each facility, may or may not have enough material to satisfy the demand it wants to satisfy. In cases where the facility does not have enough material, an assumption can be made that the facility starts satisfying the demands for parties with the highest penalties until the facility runs out of inventory. The remainder of the demand can be moved to the next time point for satisfaction. At this point, knowledge about what actually will arrive on that day and what remains in the inventory can enable computation of the end-of-day inventory for that facility. Furthermore, knowledge about how much material will be shipped from every such facility i to its parents can be incorporated. In the case where the uncertainty associated with every edge (I,j) is known or treated as known or knowable for all such parent facilities j of facility i, the uncertainty associated with arrival at facility j can be simulated based on the shipment at time t. At this point, every node for which all of its children have concluded the above outlined computations can conduct its own set of simulations and predictions. This process may continue until nodes without parents are reached, at which point the simulation of the behavior of the supply network at time t is concluded.

Hyperparameter Optimization

In some embodiments, optimization of a stochastic constrained uncertainty problem may be accomplished by calculation of one or more hyperparameters, where the one or more hyperparameters provide an uncertainty model of a multiparametric optimization problem. The parameters of this model may include any of the inventory parameters described in this document (such as SL, ST, PTF, SL, SSV, SA, MO, ELT, EA, data from a BOM, RV, USW, parameters associated with particular target SKUs, holding cost, ordering and transport cost, etc. or combinations of one or more thereof). Parameters of the hyperparameter may be constrained or configured by a file, external command stream, input interface, etc. or determined automatically.

Also, in some embodiments, a risk tolerance level may be selected or configured by a file, external command stream, input interface, etc. In other embodiments, a risk tolerance level may be automatically determined from data about the user. In some cases, data about the user may include aggregated risk data from a market sector of the particular user or may be empirical data gathered during a training period by the system concerning the realized risk during the training period.

Moreover, in some embodiments, a trade-off preference may be used to configure one or more hyperparameter uncertainty models. The trade-off preference may be determined at least partially by prioritization of multiple business objectives. Business objectives may include a maximum tolerable risk level, one or more costs associated with inventory, or other business considerations and combinations of one or more thereof. In some cases, computation of a hyperparameter uncertainty model may be performed exclusively during a training phase. The hyperparameter uncertainty model may provide a forward-looking simulation, and computation exclusively during the training phase may improve efficiency and allow for more frequent evaluation of inventory parameters.

Further, in some embodiments, a hyperparameter uncertainty model may account for a majority of possible risk outcomes for a given acceptable risk level or risk profile. Recalculation of the hyperparameter uncertainty model may only be required when the risk profile or acceptable risk level changes. Accounting for a majority of risk outcomes may allow a machine learning system to apply realized inventory levels to the hyperparameter uncertainty model in order to determine inventory re-order parameters during a production phase without needing to recalculate the uncertainty model. Because of this, in some embodiments, the systems and methods may be robust to and tolerant of large changes in the realized risk profile (such as the large increase in supply chain uncertainty during COVID-19). Robustness may be achieved due to the dependence of the uncertainty model only on the tolerable risk level. In some cases, re-order parameters are automatically adjusted by application of realized risks to the uncertainty model, such as to raise inventory level into the constraints of the model, so that the desired risk tolerance level is achieved even when large supply chain interruptions are experienced.

Beyond that, in some embodiments, the process of applying a hyperparameter uncertainty model to realized inventory data may be performed by an interpretation algorithm. In some cases, the interpretation algorithm may be iterative. In other cases, the interpretation algorithm may be non-iterative. In many embodiments, the interpretation algorithm may be customized to a given inventory system or business.

In addition, in some embodiments the interpretation algorithm may be a k-iteration algorithm. In some cases, the k-iteration algorithm may apply the model to the data in real-time. Also, in some cases, the k-iteration algorithm may adjust inventory parameters to bring realized inventory levels back into the constraints of the model. Further, in some cases, the adjustments may ensure that realized risk falls within the acceptable risk tolerance of a hyperparameter uncertainty model. In addition, in some cases, the k-iteration algorithm may adjust inventory parameters to ensure that an unexpected and substantial supply chain interruption does not impact service level or cause realized inventory to fall below a safety level.

The systems and methods for inventory management and optimization may be applied to a wide variety of enterprises, such as global manufacturers with footprints across multiple countries or continents. For example, such manufacturers may operate hundreds of factories globally, manufacture highly complex equipment, and hold average inventory levels worth hundreds of millions or even billions of dollars. As a particular example, based on standard industry practice among manufacturers of expensive and sophisticated equipment (such as industrial equipment), manufacturers may allow their customers to configure products with dozens or hundreds of individual options, leading to products having hundreds or thousands of permutations. In such cases, the customized nature of the manufacturer's products may drive significant complexity in managing inventory levels during the manufacturing process. For instance, since the final configuration of a product is often not known until close to submission of the order for that product, the manufacturer may routinely hold significant excess inventory on hand to fulfill orders on time.

Using the systems and methods for inventory management and optimization disclosed herein, manufacturers may achieve significant reductions in average inventory levels. Depending on the enterprise and the implementation of the described systems and methods, the reduction in average inventory levels may be less than about 5%, about 5%, about 10%, about 15%, about 20%, about 25%, about 30%, about 35%, about 40%, about 45%, about 50%, about 55%, about 60%, about 65%, about 70%, about 75%, about 80%, about 85%, about 90%, or greater than about 90%. Such significant reductions in average inventory levels may confer additional benefits, such as savings in shipping costs (due to fewer parts being ordered) and increased productivity of inventory analysts by helping them focus on higher value-added tasks instead of tracking, managing, and auditing available inventory. In addition, using the systems and methods for inventory management and optimization disclosed herein, key insights may be uncovered, which may prove useful during negotiations with suppliers (such as the effect of supplier planning time fence on inventory levels).

Multi-Echelon Inventory Optimization (MEIO)

The systems and methods for inventory management and optimization may be applied toward multi-echelon inventory optimization (MEIO), which generally refers to a problem of optimizing inventory across all nodes in a supply chain. MEIO approaches may optimize the inventories across the network holistically, such as by leveraging the relationships between nodes in the network. For example, the inventory dataset may include inventory variables for either a single-echelon inventory (such as corresponding to a single node or facility) or, in the case of MEIO approaches, a multi-echelon inventory (such as corresponding to a supply chain with a plurality of nodes or facilities). MEIO may use approaches similar to those described above with certain modifications. These modifications mainly concern describing the connectivity and interactions among facilities in a supply chain.

Inventory management and optimization in a multi-echelon setting also concerns the three different categories of variables discussed above for a single facility (variables set by a manufacturer that provide robustness with respect to sources of uncertainty, variables concerning interaction with suppliers, and variables defining production planning). In order to optimize the variables related to robustness, an optimization module (such as a hardware module or a software routine) can leverage the simulation techniques discussed above. For example, the optimization module can evaluate the performance of different combinations of values of the variables under consideration. The optimization module can cause the simulation module to run what-if simulations for a period in the past, forward-looking what-if simulations for periods in the future, and forward projections of stochastic variables. This may be facilitated through inference techniques provided by the theory of probabilistic graphical models.

In some embodiments, the MEIO problem may be formulated as a probabilistic graphical model. A probabilistic graphical model may contain a graph with nodes representing facilities and directed edges (i,j) representing that facility i can supply facility j. For example, the probabilistic graphical model can be used to determine optimal scheduled arrivals at any given time t into the future for such a supply chain network or to determine an optimal safety stock and safety time for each facility in the network. The probabilistic graphical model can be combined with a data-driven machine learning-based training system. In this example, a machine learning system may be used to train models to learn how distributions of random variables change over time and predict the distributions in the future. The probabilistic graphical model can be used to propagate information across nodes in the supply chain and to learn the inter-relationships across the nodes in the supply chain. Selecting the variables under consideration at different facilities can be similar to the process described above for single-facility analyses.

The optimization module can also use optimization algorithms that do not rely on simulation approaches, such as by parametrizing a mathematical optimization problem with parameters that include the variables under consideration, leading to stochastic MILPs as described above. Given the directed nature of the graph describing the supply chain, the optimization module may also employ approximate dynamic programming to provide approximate solutions to the MILP.

In order to optimize variables concerning interactions among facilities in the supply chain (including orders amounts and timing), the optimization module can use a direct mathematical optimization approach. By solving this optimization, the optimization module can set the interactions among facilities with a full view of the supply chain. This may lead to stochastic MILPs, which can leverage the outputs from the models for uncertainty to form stochastic terms of an objective function of an optimization problem or stochastic constraints associated with it, such as chance constraints. The cost to optimize may be or include inventory holding cost, ordering cost, production or operational cost, sales lost, achieved profits, etc. for the whole supply network. The constraints may be or include inventory evolution at each facility, operational constraints within each facility, replenishment process constraints (such as any replenishment constraints that are not the target of optimization) between facilities, and demand satisfaction or management constraints for each facility. The constraints and terms in the objective function that concern interactions among facilities may clearly encode costs associated with different interaction approaches between nodes and the rules associated with these interactions (which are commonly conditional and time-varying constraints), such as (i) time-varying multi-column pricing and (ii) timing and permissions associated with cancelling or adding to existing outstanding orders. The optimization formulation may have the necessary flexibility to jointly optimize these variables and those concerning robustness.

The optimization module can also use a direct optimization approach to optimize variables relating to production planning and/or variables related to determining how to satisfy sales orders. The cost to optimize may be inventory holding cost, ordering cost, production or operational cost, sales lost, achieved profits, etc. over the whole supply chain. The constraints may be or include inventory evolution at each facility, operational constraints within each facility, constraints that clearly encode a replenishment process framework between facilities, and demand satisfaction or management constraints based on contractual obligations between nodes and with external customers. Such obligations may also be included in the cost function. The constraints and terms in the objective function that concern interactions with customers can clearly encode costs associated with different interaction approaches with different customers and their associated contractual obligations, which may include hard-coded rules associated with these interactions (which are commonly conditional and time-varying constraints), such as time-varying penalties for missed orders or constraints concerning latest possible delivery dates. The constraints may also encode interactions among equipment involved in the production process at each facility, which may not be simply represented using BOM at each facility. The optimization formulation has the necessary flexibility to jointly optimize these variables and those concerning robustness and/or the ones concerning replenishment process.

In the event that any of these optimization problems is prohibitively costly to solve, the optimization algorithm may take other actions, such as decomposing the problem and using distributed algorithms for solving the problem or simultaneously solving relaxations (which commonly result in stochastic linear problems) and restrictions (projection techniques) of these problems. This can enable the system to provide approximate solutions to the problem but also quantify the level suboptimality of the approximate solution. Given the directed nature of the graph describing the supply chain, the optimization module may also employ approximate dynamic programming to provide approximate solutions to the MILP.

In the MEIO problem, the underlying supply chain network may define the global graphical structure. The local structure of the graphical model may be defined by the relationships among various random (such as stochastic) variables in the optimization problem, such as inventory, demand forecasts, material movements, supplier orders, etc. Such random variables may have stochastic distributions, which may be typically time-varying. Regression models may be trained from historical data to learn how these distributions vary over time based on features such as season of the year, etc. The trained regression models may be used to predict the prior and conditional distributions of the random variables. Each node in the supply chain may estimate the distributions of the random variables locally and share this information with other nodes in the supply chain, such as by using belief propagation techniques. The nodes can continue to propagate their beliefs to other nodes in the system until convergence occurs. Once the beliefs converge, suitable actions can occur, such as by estimating a recommended safety stock at each node locally using the conditional distribution of the inventory variable.

Note that multi-echelon inventory optimization can be performed by applying an inventory optimization approach designed for a single facility to every facility in the supply chain network. For example, every facility (having observed its historical suppliers' behaviors), uncertainties over its demand forecasts, and other miscellaneous behaviors at the facility, can optimize its safety stock and safety time in isolation from other facilities in the network.

In some embodiments, the MEIO problem may include modeling the supply chain network and optimizing the inventory variables using Bayesian optimization. For example, optimal safety stock and safety time values may be determined for each facility by jointly optimizing quantity and time uncertainties for all facilities in the network. Safety stock may be an additional quantity of an item held by a company in inventory in order to reduce the risk that the item will be out of stock. Safety time may be a time buffer for covering product requirements in cases of future late deliveries. In some cases, a grid of possible order parameter values can be created across the nodes in the supply chain, and the supply chain can be simulated with each combination to determine the cost and service level. The supply chain can be optimized to obtain an optimal combination of parameters, such as by performing an exhaustive grid search or a random search. It should be noted, however, that such approaches can be computationally expensive without optimization. As an example, if each node in a supply chain network with N nodes takes ten possible values for its order parameters, the total number of possible combinations to search over is 10^{N}. The list of total combinations can quickly get prohibitively large to evaluate and find the optimal combination.

Bayesian optimization may be used to obtain the optimal combination of parameters with decreased computational complexity. Bayesian optimization may refer to a sequential technique that suggests the next best combination to evaluate given the prior combinations evaluated. Applying Bayesian optimization may enable computation of optimal combinations by visiting only a subset of the grid points of parameter values. Such an approach may be advantageous and enable benefits such as using Gaussian process models as the underlying models, using probabilistically meaningful acquisition functions that provide probabilistic guarantees concerning quality of the output, using the evaluated data points from the previous optimization run for the current time by modifying the used kernel appropriately, and setting a computational time or resources budget for the optimization and interrupting safely if the computational time or resources budget is surpassed. The computational complexity of the Bayesian optimization approach can be expected, in the very worst case, to be exponential with respect to the number of facilities in the network.

The following describes example approaches for implementing the various techniques described above. In the discussion below, the following are variables that may be used and their associated meanings.
Θ—a set of stochastic variables
δ—a level set function
γₚ—an aggregation function that takes the p^{th} percentile of an uncertainty distribution
a—a stochastic expected order arrival for one day (scalar)
A^{τ:H}—a one-dimensional array of stochastic expected order arrivals for a period of time starting at timestamp t (inclusive) and ending at timestamp t+H (exclusive)
x—a stochastic inventory level for one day (scalar)
X^{:τ}—a one-dimensional array of stochastic inventory levels for a period of time starting at timestamp t (inclusive) and ending at timestamp t+τ (exclusive)
πₕ—an inventory holding cost
π_{o,t}—an inventory ordering and transportation cost
ψ—a function that calculates a service level
Ã^{:H}—a one-dimensional array of stochastic expected order arrivals for the current predictive horizon (predicted at a prior sampling time i) starting at timestamp t (inclusive) and ending at timestamp t+H (exclusive)
b^{USW}—a buffer for a length of an uncertainty sampling window
c_{α}^{τ}—an actual consumption at timestamp τ
C_{DF,2D}—a two-dimensional demand forecast matrix within an uncertainty sampling window
C_{DF,1D}—a demand forecast aggregated to one dimension (from off-diagonal elements in the two-dimensional matrix) within an uncertainty sampling window
C_{DF}^{τ}—a demand forecast (one-dimensional array) made at a date τ for a length of a predictive horizon H
c_{DF}^{t}^{ₒ}^{,t}^{_{f}}—a demand forecast made at a date tₒ for a date t_{f} (scalar)
H—a predictive horizon
Lₘᵢₙ^{USW}—a minimum length of an uncertainty sampling window
Nᵣ—a number of uncertainty realizations in a forward-looking simulation procedure
Nₒₛ—a number of uncertainty realizations in an order simulation step
p_{SL}—a service level percentile (SLP)
r—one or more re-order parameters for one day
R^{:τ}—a one-dimensional array of re-order parameters for a period of time starting at timestamp t (inclusive) and ending at timestamp t+τ (exclusive)
U_{DF}—a one-dimensional array representing a demand forecast uncertainty within an uncertainty sampling window
U_{MM}—a one-dimensional array representing a material movement uncertainty within an uncertainty sampling window U_{SQ}—a one-dimensional representing a supplier quantity uncertainty within an uncertainty sampling window
U_{ST}—a one-dimensional array representing a supplier time uncertainty within an uncertainty sampling window.

Constrained Stochastic Inventory Optimization

An example problem that may be solved by the systems and methods disclosed herein is a stochastic constrained optimization problem of re-order parameters that minimizes inventory levels subject to a given service level constraint. An objective function in this optimization problem may include costs associated with holding inventory, ordering, and transportation. These costs can be optimized with respect to operational constraints. The operational constraints may include a planning calendar, planning time fence, (expedited) lead time, rounding values, minimum order quantity, customer-dependent operational constraints, and complex material pricing (such as volume-based pricing). Another constraint is often the service level constraint, which is defined as the expected probability of not hitting a stock-out during the next replenishment cycle.

The stochasticities or uncertainties in the constrained optimization problem come partly from the fact that there are often unexpected delays and shortages on arriving orders. Also, miscellaneous and blocked material movements cannot be anticipated ahead of time and are also categorized as uncertainties. In addition, the optimization result may need to be frequently adjusted based on the latest estimation of the future demand, which is subject to change from one day to the next and is often different from the actual demand (leading to another source of uncertainty). To address the constraints and the uncertainties in this example, the problem may be formulated in a model predictive control (MPC) setting. At each timestamp t (also referred to as a sampling time), an example problem can be formulated as the following optimization problem.

$$\begin{matrix}\text{?} & {γ}_{p} [ {\sum }_{i = 0}^{H - 1} \text{?} ]\end{matrix} \\ \begin{matrix}s . t . & ψ ( {X}^{: H} ) - {SL}_{min} \geq 0 \\ & \text{?} \\ & ∀ i ∈ [ 0 , … , H - 1 ] \\ & {A}^{i + 1 : H} = MRP ( \text{?} ) \\ & ∀ i ∈ [ 0 , … , H - 1 ] \\ & \text{?} \\ & \text{?}\end{matrix} \qquad ( 2 )$$

$$\text{?} \text{indicates text missing or illegible when filed}$$

Here, H represents the length of the prediction horizon, which limits the length of the inventory simulation that can be performed at sampling time t. The superscript represents the timestamp, and the notation “t+i|t” in the superscript represents a value at timestamp t+i predicted at timestamp t. Also, x∈ [symbol] ¹ represents the stochastic inventory level, and a∈ [symbol] ¹ represents the stochastic expected order arrival quantity. Note that the expected order arrival quantity can be further split into the expected standard arrival (SA) and the expected expedited arrival (EA). Further, πₕ represents the inventory holding cost, and π_{0,t} represents ordering and transportation costs. Note that the objective function can take different forms depending on, among other things, the business setting of the customer. The notation γₚ(⋅) in the objective function of Equation (2) represents an aggregation function that takes the specific percentile of a given uncertainty distribution, where p represents the percentile of the uncertainty distribution (such as, if p=50%, γₚ returns the median of the uncertainty distribution). Aggregation using the function γₚ(⋅) may offer more flexibility than aggregation with the expectation ( [symbol] [⋅]), although the latter is more often used as the aggregation function for stochastic optimization problems.

In many large-scale operational settings, the re-ordering of materials is done via legacy MRP systems. In order to respect that constraint and to ease customer adaptation, the re-order parameters may be optimized, which are inputs of the MRP system. Therefore, the decision variables in this formulation may be denoted by R^{:H}, which represents the re-order parameters of the MRP system up to timestamp t+H. For example, R: may be expressed as follows.

R^{:H}=[r^{l|t},r^{t+1|t}, . . . ,r^{t+H-1|t}]∈R^{H×2} (3)

Here, r at a given timestamp represents a single pair of re-order parameters for the MRP system. Note that this formulation can work for MRP systems with a variety of replenishment strategies. However, for this example, the scope of discussion is limited within a safety stock MRP system. In that setting, the re-order parameters may include the safety stock value (SSV) and the safety time (ST), and r^{I+l|t} can be expressed as follows.

r^{t+i|t}=[SSV^{t+i|t},ST^{t+i|t}]∈ [symbol] ² (4)

Note that X^{:H} in the first constraint of Equation (2) represents the vector of stochastic inventory levels in the prediction horizon H and may be defined as follows.

X^{:H}=[x^{t|t},x^{t+1|t}, . . . ,x^{t+H-1|t}]∈ [symbol] ^{H} (5)

Here, the bold lower-case notation x∈ [symbol] ¹ with superscripts represents the stochastic inventory level for a specific date as predicted at time t, and SLₘᵢₙ represents the minimum target service level. The function ψ(⋅) calculates the service level within the prediction horizon and may be expressed as follows.

$$ψ ( {X}^{: H} ) = {γ}_{{p}_{SL}} [ \frac{{\sum }_{i = 1}^{H} δ ( {x}^{t + i \vert t} )}{H} ] ∈ {1}^{} \qquad ( 6 )$$

The notation δ(⋅) is a level set function, which may be defined as follows.

$$δ ( x ) = \{ \begin{matrix}1 , & x \geq 0 \\ 0 , & otherwise\end{matrix} \qquad ( 7 )$$

Note that, in this example, the service level is computed as the percentage of days on which the inventory level is not negative. Other definitions of the service level, such as fill rate, may also be supported by this formulation. Also note that the aggregation functions γₚ in Equation (2) and γ_{pSL} in Equation (6) may be identical, but p and p_{SL} can take different values depending on the risk profile of the customer. Distinct notation is employed here for flexibility.

The second constraint in Equation (2) represents simple inventory updating logic, where c_{DF}^{t,t+i}∈ [symbol] ¹ denotes the demand forecast for timestamp t+i made at timestamp t. Here, Θ denotes a collection of stochastic variables representing various sources of uncertainties, such as movement uncertainty UMM, supplier quantity uncertainty USQ, supplier time uncertainty UST, and demand forecast uncertainty UDF.

The function notation MRP(⋅) in the third constraint in Equation (2) represents the constraints imposed by the legacy MRP system. This function takes the inventory level up to the current timestamp x^{t+l|t}, the demand forecasts at the current timestamp C_{DF}^{t+i}, the re-order parameters at the current timestamp r^{t+i|t}, and the expected order arrivals starting at the current timestamp A^{r:H} as inputs. This function updates (overwrites) the expected order arrivals starting at the next timestamp to the end of the predictive horizon (A^{i+1:H}) Here, C_{DF}^{t+i}∈ [symbol] ^{H} represents the demand forecast made at timestamp t+i and can be expressed as follows.

C_{DF}^{t+i}=[c_{DF}^{t+i,l+i}, . . . ,c_{DF}^{t+i,t+i+H-1}]∈ [symbol] ^{H} (8)

The notation A^{τ:H} represents the stochastic expected order arrivals (including both standard arrivals and expedited arrivals) starting at timestamp t+τ(∀τ∈[0, . . . , H−1]) to the end of the predictive horizon (timestamp t+H). This can be expressed as follows.

A^{τ:H}=[a^{t+τ|t}, . . . ,a^{t+H-1|t}]∈ [symbol] ^{H-τ} (9)

Note that the initial value for A^{t:H} in Equation (2) while i=0 (denoted as Ã^{:H}) comes from the output of Equation (2) during the previous sampling time \tilde{t}. This may be explicitly written as follows.

Ã^{:H}=[a^{t|\tilde{t}}, . . . ,a^{t+H-1|\tilde{t}}]∈ [symbol] ^{H} (10)

More details regarding this MRP constraint can be found in Algorithm 1 discussed below.

The fourth constraint in Equation (2) represents the limitations of the current MRP system, where only a single value can be specified for each SSV and ST throughout the entire prediction horizon. Note that the re-order parameters are not required to be identical when the sampling time t evolves. For example, r^{t+i|t} is not necessarily equal to r^{t+i|t+j} for j>0 and i>j. The fifth constraint in Equation (2) indicates that the re-order parameters may always be non-negative.

The formulation presented in Equation (2) can be solved iteratively for different sampling times t. The re-order parameters recommended at a sampling time t can be preserved until updated at the next sampling time t+j. Note that the sampling time increment j (also referred to as the optimization frequency) is not required to be one. Also note that non-zero results from decision variable optimizations are expected due to uncertainties (represented by Θ). Should the uncertainties in the formulation be completely removed, the decision variables may be all zero since legacy MRP systems are capable of handling deterministic inventory planning without any buffer specified.

### Overview of Example Algorithm

Once a suitable objective function and its constraints are configured (such as when the hyperparameters including γₚ in Equation (6) are determined), Equation (2) can be solved for each sampling time. In an example implementation, the system may assist in configuring the hyperparameters to best fit business or other interests. In addition, MRP systems can be highly customized depending on the customer. There are pieces of logic, such as order cancellation and order merging (like flush windows), that may be difficult to formulate as simple linear constraints for the optimization problem.

An AI stochastic inventory optimization (SIO) algorithm (“algorithm”) as disclosed herein enables hyperparameter tuning with systems for automated improvements to address such situations. The simulations using hyperparameters and uncertainty distributions are used to predict impacts of changes of variables on future orders or other requests. In an example, the algorithm learns a material plant's historical uncertainties in material movements (supply, demand, and other) over a historical time period (referred to as a “training period” or “training phase”) to select optimal hyperparameters determined feasible. The algorithm can perturb these learned material movement uncertainties into material planning simulations in the future (such as during a validation period and during live production). Based on these simulations and uncertainty realizations in the future and with the help of the selected hyperparameters, the algorithm recommends optimized re-order parameters (such as SSV and ST values for a safety stock MRP system) that minimize inventory costs while meeting any target service level constraints.

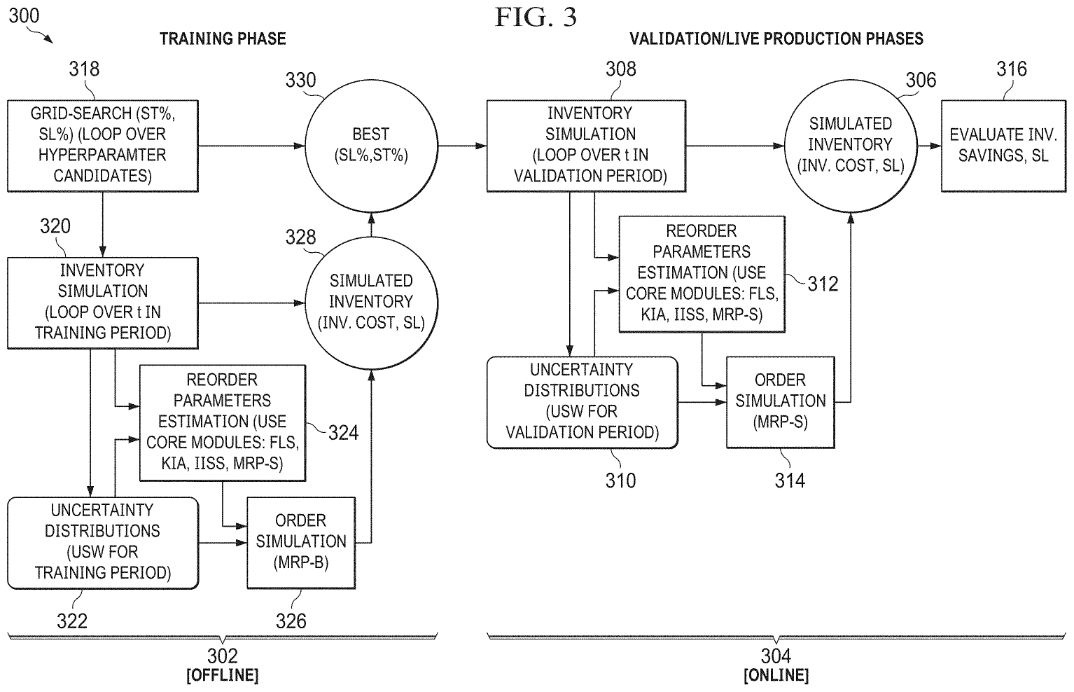

FIG. 3 illustrates an example stochastic inventory optimization (SIO) algorithm workflow 300 in accordance with this disclosure. As shown in FIG. 3, the algorithm workflow 300 generally has two phases: a training (offline) phase 302 and a validation or live production (online) phase 304. The training phase 302 typically occurs during a period of time further in history, while the validation phase 304 occurs during a more recent time period. The phrase “simulation period” refers to the timestamps (such as in days) either during the training phrase 302 or the validation phase 304, depending on the context. Live production can be considered a special case of a validation phase where optimization is performed “today” (the last date with data available). Therefore, in some cases, the re-order parameters may only be optimized for one timestamp in the live production phase.

During the validation phase 304, the optimization problem formulated in Equation (2) is solved repeatedly at each sampling time t to generate a final simulated inventory 306 for the validation period. An inventory simulation 308 of the validation phase 304 includes three general components or steps: (i) an uncertainty distribution step 310, (ii) a re-order parameters estimation step 312, and (iii) an order simulation step 314. During the uncertainty distribution step 310, the uncertainties of a model's inputs are collected within an uncertainty sampling window (USW). Those uncertainties are saved for the sampling procedure that occurs in the re-order parameters estimation step 312. In the re-order parameters estimation step 312, MRP simulations are performed repeatedly, starting at each sampling time t, to infer one or more optimal or best re-order parameters. The inference of the re-order parameters may be accomplished using a “k-iteration” inventory simulation process (with the hyperparameters determined by the training phase 302). The re-order parameters can be retained until they are overwritten by the inference made at the next sampling time. The algorithm is designed with this overwriting process to effectively incorporate new information that becomes available at each sampling time t. Subsequently, in the order simulation step 314, future order placements can be generated based on a series of re-order parameters. Finally, the algorithm workflow 300 incorporates the uncertainty distributions again to generate multiple realizations of the simulated inventory 306, and the inventory cost of each realization can be computed accordingly. Inventory savings 316 can be computed by comparing the actual cost of the inventory with the median (or any other aggregation approach configurable by a file, external command stream, input interface, etc.) of the realizations during the validation period. The live production (or operation) phase is similar to the validation phase described above. The primary distinction is that there is only one timestamp (such as a day) for re-order parameter recommendation in the live production. Also, since the actual data (such as actual inventory, actual arrivals, actual consumptions, etc.) may not be present for the live production, there is no need to compare the simulated results with the actual inventory.

The purpose of the training phase 302 is to determine the hyperparameters, which helps the inferring of the re-order parameters at each sampling time t in the validation phase 304. In this example, the training phase 302 is essentially a grid search process 318 that repeats the validation procedure multiple times in the training period, each time with a different combination of hyperparameters. Thus, the training phase 302 can repeatedly perform inventory simulations 320, including an uncertainty distribution step 322, a re-order parameters estimation step 324, and an order simulation step 326, using different combinations of hyperparameters. This results in various simulated inventories 328. A set of one or more best hyperparameters 330 can be determined based on the inventory savings and service level achieved by each combination. Note that the grid search approach is chosen in this example among all optimization options to ensure the stability of the algorithm, although other search approaches may be used.

To summarize, the deployment of the algorithm can include three general operations. First, a model is trained to learn from material movements and associated uncertainties over a historical training period and optimizes the hyperparameters. Second, the trained model (with the optimized hyperparameters) is validated in a production-like operation over a period of recent history to evaluate real performance (such as to predict inventory cost and service level). Third, the model is run during live production, simulating uncertainties into the future in order to provide recommendations on optimal re-order parameters. The model's performance can be monitored over time, and the model may be automatically or manually retrained as needed.

It should be noted that the functions shown in or described with respect to FIG. 3 can be implemented in at least one electronic device (such as a computer system described below) in any suitable manner. For example, in some embodiments, at least some of the functions shown in or described with respect to FIG. 3 can be implemented or supported using one or more software applications or other software instructions that are executed by one or more processors of at least one electronic device. In other embodiments, at least some of the functions shown in or described with respect to FIG. 3 can be implemented or supported using dedicated hardware components. In general, the functions shown in or described with respect to FIG. 3 can be performed using any suitable hardware or any suitable combination of hardware and software/firmware instructions.

In the following sections of this document, various aspects of the systems and methods are described in greater detail. These aspects of the systems and methods include the MRP simulation, the modeling of uncertainties, the optimization of the hyperparameters, the forward-looking simulation, the “k-iteration” algorithm, and other algorithm treatments.

Inventory Simulation with MRP

In some embodiments, an MRP system may sit at the core of an algorithm described here. The MRP system may be a re-order point MRP (where re-order parameters may include re-order point and re-order quantity) or may be a min-max MRP system (where re-order parameters may include minimum and maximum inventory levels). For any given sampling time t, the MRP system may take re-order parameters along with other inputs, such as a demand forecast C_{DF}^{t+i}, a lead time (LT), an expedited lead time (ELT), a planning calendar (PC), an item volume pricing (IVP), etc. within a horizon (corresponding to the predictive horizon H in Equation (2)) and output the order placement in that horizon. The optimization framework disclosed herein can support MRP systems with a variety of replenishment strategies. However, the scope of discussion in this example is limited to a safety stock MRP system, where the re-order parameters may include SSV and ST.

A safety stock MRP system places orders for a window in the future based on the current inventory position, existing orders, and demand forecasts. For example, the MRP may project the inventory position for every day in this future window, and orders are placed to arrive when the projected inventory drops below a predefined safety stock value subject to re-order constraints such as lead time, factory calendar, planning calendar, minimum order quantity, rounding values, etc. Algorithm 1 below provides a simplified view of the safety stock MRP system, where various pieces of logic are described in detail. However, some auxiliary pieces of logic (such as item volume pricing, lot size in days, planning calendar, and order flushing or merging) are intentionally omitted to improve the readability of the algorithm.

```
Algorithm 1 Simplified Safety Stock MRP
  Input: starting inventory x^{t}, demand forecast C_{DF}^{t}, expected standard
order arrivals SA^{t+i}, expected expedited order arrivals EA^{t+i}, where i =
0 . . . H, and H is the planning time horizon, lead time LT, expedited
lead time ELT, safety stock value SSV, minimum order quantity
MO, rounding value RV
  Output: updated expected arrivals of standard orders SA^{t+i} and
expedited orders EA^{t+i}, i = 0 . . . H
```

| | |
|---|---|
| 1: | Apply order cancellation on expected standard order arrivals (SA) |
| | based on Algorithm 2 |
| 2: | \hat{x}^{t} = x^{t} |
| 3: | |
| 4: | for i = 0, . . . , ELT − 1 do |
| 5: | \hat{x}^{t+i+1} = \hat{x}^{t+i} + SA^{t+i} + EA^{t+i} − c_{DF}^{t,t+i} |
| 6: | end for |
| 7: | |
| 8: | for i = ELT, . . . , LT − 1 do |
| 9: | \tilde{x}^{t+i+1} = \hat{x}^{t+i} + SA^{t+i} + EA^{t+i} − c_{DF}^{t,t+i} |
| 10: | if \tilde{x}^{t+i+1} < 0 then |
| 11: | EA^{t+i} += −\tilde{x}^{t+i+1} |
| 12: | end if |
| 13: | \hat{x}^{t+i+1} = \hat{x}^{t+i} + SA^{t+i} + EA^{t+i} − c_{DF}^{t,t+i} |
| 14: | end for |
| 15: | |
| 16: | for i = LT, . . . , H − 1 do |
| 17: | \hat{x}^{t+i+1} = \hat{x}^{t+i} + SA^{t+i} + EA^{t+i} − c_{DF}^{t,t+i} |
| 18: | if \tilde{x}^{t+i+1} < SSV then |
| 19: | Δx = SSV − \tilde{x}^{t+i+1} |
| 20: | ${SA}^{t + i} += max ( ⌈ \frac{{Δ}_{x} - MO}{RV} ⌉ , 0 ) \times RV + MO$ |
| 21: | end if |
| 22: | \hat{x}^{t+i+1} = \hat{x}^{t+i} + SA^{t+i} + EA^{t+i} − c_{DF}^{t,t+i} |
| 23: | end for |
| 24: | |
| 25: | return SA^{t+i}, EA^{t+i} i = 0 . . . H |

Input data to Algorithm 1 includes starting inventory x^{t}, demand forecast C_{DF}^{t}, and expected arrivals of existing standard orders SA^{t+i} and existing expedited orders EA^{t+i} (where i=0, . . . , H and where H is the horizon). The algorithm simulates inventory for the horizon \hat{x}^{t+i}, where i=0, . . . , H. Notice that the hat accent is used to denote inventory position within the MRP. When ELT≤i<LT (where ELT and LT are expedited lead time and lead time, respectively), the algorithm can place one or more new expedited orders if the projected inventory \tilde{x}^{t} is about to go below zero. When LT≤i<H, the algorithm can place one or more new standard orders if the projected inventory is about to go below the safety stock value SSV. The quantity of the one or more new standard orders can be modified to comply with minimum order quantity (MO) and rounding value (RV).

Note that logic can be introduced here to extend the functionality of the algorithm to an arbitrary business function. One such function is order cancellation. Other examples may include order flushing or other inventory management parameters. Similar functions may be designed to extend functionality of the hyperparameter uncertainty modeling platform to any desired or required inventory-related parameter. Orders sent to vendors can often be cancelled based on a cancellation window (such as 30 days prior to arrival). Often times, an order can be cancelled when the order's expected arrival date is later than the planning-time-fence (PTF) day, which counts from the current day. In an MRP system, orders may be cancelled when the PTF is greater than the lead time (LT). However, in the case that the PTF is smaller than the lead time, the MRP does not cancel orders that will be arriving in between [PTF, LT] if more quantity is ordered than needed.

Algorithm 2 below represents a pre-processing algorithm for an MRP to handle the cancellation of excessive orders. Algorithm 2 modifies orders that were previously placed but that are expected to arrive in between [PTF, LT]. Rather than iterating incrementally from PTF to LT, Algorithm 2 iterates in a backward order from LT to PTF in order to make sure that a cancelled order does not impact future inventory levels. Within each iterated date, Algorithm 2 computes a surplus of inventory, which is denoted as \tilde{x}^{t+k}. If the surplus is greater than zero, the expected arrivals for that date can be reduced to offset the surplus.

Algorithm 2 The order cancellation logic

| | Input: inventory x^{t} of the day t, expected standard |
|---|---|
| order arrivals SA^{t+i}, expedited order arrivals EA^{t+i} and | |
| demand forecast c_{DF}^{t, t+i} where i = 0...H, and H is the plan- | |
| ning time horizon for a single round of MRP simulation, | |
| lead time LT, planning time fence PTF, and safety stock | |
| value SSV | |
| | Output: modified expected order arrivals SA^{t+i} where |
| i = 0...H | |
| 1: | Set k = LT |
| 2: | while k > PTF do |
| 3: | \tilde{x}^{t+k} = x^{t} + Σᵢ₌₀^{i=k} SA^{t+i} + Σᵢ₌₀^{i=k} EA^{t+i} − |
| | Σᵢ₌₀^{i=k} c_{DF}^{t, t+i} − SSV |
| 4: | if \tilde{x}^{t+k} ≤ 0 then |
| 5: | k = k − 1 |
| 6: | continue to next iteration |
| 7: | end if |
| 8: | if \tilde{x}^{t+k} > SA^{t+k} then |
| 9: | Set SA^{t+k} := 0 |
| 10: | else |
| 11: | Set SA^{t+k} := SA^{t+k} − \tilde{x}^{t+k} |
| 12: | end if |
| 13: | k = k − 1 |
| 14: | end while |
| 15: | return SA |

Modeling of Uncertainties

In an example algorithm (such as the one represented in FIG. 3), four sources of uncertainties may be considered and modeled during the uncertainty distribution step 310. These sources of uncertainties can include demand forecast uncertainty, material movement uncertainty, supplier quantity uncertainty, and supplier time uncertainty. With respect to the first source of uncertainty, depending on the accuracy of a demand forecast model, predicted demand can be quite different from actual demand/consumption. Demand forecast uncertainty models the distribution of the differences between demand forecasts and actual consumptions.

With respect to the second source of uncertainty, there may be two types of material movements, namely miscellaneous movements and blocked movements. These are typically not considered in traditional MRP systems and are not part of the amount represented in a demand forecast. Miscellaneous movements happen due to movements between facilities or customer returns. Blocked movements happen when parts arrived but cannot be consumed (such as due to a quality issue). As these material movements are generally unpredictable, they are treated as sources of uncertainties. Material movement uncertainty models the distribution of the sum of miscellaneous movements and blocked movements, such as for a given SKU.

With respect to the third and fourth sources of uncertainty, supplier quantity uncertainty models the distribution of the differences between planned quantities in purchase orders and actual quantities received, such as for a given SKU. Supplier time uncertainty models the distribution of time differences of planned delivery dates and actual delivery dates of orders, such as for a given SKU. In reality, different suppliers can have different behaviors, such as when one supplier may be more likely to delay and reduce quantity than another supplier. However, sufficient data points to accurately model the behavior of each supplier may not be available. Therefore, different behaviors of all suppliers may be averaged, such as for a given SKU, into one distribution.

In some embodiments, the distribution of each source of uncertainty may be estimated using an empirical distribution. Each empirical distribution can be represented by a list of historical data points. Historical data points may be assumed to be equally likely so that the empirical distribution may be sampled from the list of historical data points. In some cases, the list of historical data points can be retrieved from relevant quantities within a certain uncertainty sampling window (USW). During training, the USW may represent the entire training period. During validation/live production, the USW may represent a growing window with a fixed start date, where the initial length of the USW L_{USW}⁰ may be determined as follows.

L₀^{USW}=max(Lₘᵢₙ^{USW},LT+b^{USW}) (11)

Here, LT represents the lead time, b^{USW} represents the buffer or offset of the USW length, and Lₘᵢₙ^{USW} represents the minimum initial length of the USW.

The empirical distribution for material movement uncertainty can be represented by Um, which may include a list of data points in the uncertainty sampling window where each data point is the sum of miscellaneous and blocked movements at that time step. In some cases, this can be expressed as follows.

U_{MM}=[ . . . ,c_{MIM}^{τ}+c_{BM}^{τ}, . . . ]∈ [symbol] ^{L}^{^{USW}},∀τ∈USW (12)

Here, L^{USW} represents the length of the uncertainty sampling window, and C_{MIM}^{τ}∈ [symbol] ¹ and C_{BM}^{τ}∈ [symbol] ¹ represent the values of consumption due to miscellaneous movements and blocked movements at time τ, respectively. The values of C_{MIM}^{τ} and C_{BM}^{τ} can be positive when materials move in and negative when materials move out.

The empirical distribution for supplier quantity uncertainty can be represented by U_{SQ}, which may include a list of historical data points that represent differences between planned quantities and actual received quantities of orders delivered in the uncertainty sampling window. In some cases, this can be expressed as follows.

U_{SQ}=[ . . . ,min(s_{A}^{o}−sₚ⁰,0), . . . ]∈ [symbol] ^{USW} (13)
∀o∈Orders planned to arrive in USW
   Here, S_{A}^{o}∈ [symbol] ¹ and S_{P}^{o}∈ [symbol] ¹ represent an actual quantity and a planned supplied quantity for order o, respectively. To make the example algorithm conservative in nature, when the actual supplied quantity S_{A}^{o} is larger than the planned supplied quantity Sₚ^{o}, this favorable condition may not be considered when quantifying the uncertainty. Therefore, the positive number may be replaced with a zero in the empirical distribution.

The empirical distribution for supplier time uncertainty can be represented by U_{ST}, which may include a list of historical data points that represent the differences (such as in number of days) between planned delivery dates and actual delivery dates of orders delivered in the uncertainty sampling window. In some cases, this can be expressed as follows.

U_{ST}=[| . . . ,max(t_{A}^{o}−t_{P}^{o},0), . . . ]∈R^{L}^{^{USW}} (14)
∀o∈Orders planned to delivered in USW
   Here, T_{A}^{o}∈ [symbol] ¹ and T_{P}^{o}∈ [symbol] ¹ represent an actual delivery time and a planned delivery time for order o, respectively. When the actual delivery date TA is earlier than the planned delivery date T_{P}^{o}, this is a favorable condition that may not be taken into consideration. Therefore, a value of zero may be substituted in the empirical distribution.

The empirical distribution for demand forecast uncertainty can be represented by U_{DF}. In some cases, a two-dimensional demand forecast can be constructed as follows.

C_{DF,2D}=[| . . . ,C_{DF}^{τ}, . . . ]∈ [symbol] ^{L}^{^{USW}}^{×H},∀τ∈USW (15)

To construct the demand forecast uncertainty U_{DF}, the two-dimensional demand forecast of Equation (15) can be compressed into a one-dimensional array before subtracting it by the actual consumption. As a particular example, following Equation (8), let c_{DF}^{t}^{ₒ}^{,t}^{_{f}}∈ [symbol] ¹ represent the demand forecast (planned consumption) for time t_{f} made at time tₒ. For each time in the uncertainty sampling window, the demand forecast value made for time τ at time τ−LT−ST can be extracted to obtain a one-dimensional representation of the demand forecast uncertainty, where LT and ST stand for lead time and safety time, respectively. In this example, the one-dimensional representation can be expressed as follows.

C_{DF, 1D}=[ . . . ,c_{DF}^{τ-LT-ST,τ}, . . . ] [symbol] ^{L}^{^{USW}},∀τ∈USW (16)

Here, the demand forecast made (lead time plus safety time) days before may be used to most accurately reflect the actual demand forecast uncertainty. Note that C_{DF, 1D} effectively comes from off-diagonal terms of the matrix C_{DF, 2D}. In practice, demand forecasts may come in on a weekly basis, monthly basis, or other basis. To convert the demand forecast into a daily forecast so that it is comparable to the actual consumption, a convolution step on C_{DF, 1D} may be applied that acts as a moving average smoother. For example, when a demand forecast comes in once every day d, C_{DF, 1D} may be convolved with a d-dimensional constant vector

$$a = [ \frac{1}{d} , … , \frac{1}{d} ]$$

to obtain the smoothed one-dimensional demand forecast C*_{DF, 1D}.

$${C}_{DF , 1 D}^{i , *} = \frac{1}{d} {{\sum }^{i + d / 2}}_{j = i - d / 2} {C}_{DF , 1 D}^{j} \qquad ( 17 )$$

Here, C^{j}_{DF, 1D} represents the j^{th} element in C_{DF, 1D} as defined in Equation (16), and C_{DF,1D}^{i,}* represents the i^{th} element in the smoothed one-dimensional demand forecast C_{DF,1D}*. Let:

C_{A}=[ . . . ,c_{A}^{τ}, . . . ]∈ [symbol] ^{L}^{^{USW}},∀τ∈USW (18)

represent the list of actual consumption in the uncertainty sampling window. The demand forecast uncertainty may then be determined as follows.

U_{DF}=C_{DF, 1D}*−C_{A}∈ [symbol] ^{L}^{^{USW}} (19)

Note that, in practice, outliers in C_{DF} are likely to occur, so one or more pre-processing operations may be performed before computing U_{DF} or consuming C_{DF} in the algorithm.

Optimization of the Hyperparameters

The system can assist in determining or recommending a risk profile that fits a particular business or other interest. The risk profile can be quantified by hyperparameters, such as p_{SL} for γₚ_{_{SL}} in Equation (6). This hyperparameter is also referred to as a service level percentile or SLP. As discussed later, in the context of a safety stock MRP system, the SLP can directly affect the choice of SSV in the example algorithm but may not have an impact on the choice of ST. To help with quantifying a customer's risk profile on the time delay and recommending an ST, another hyperparameter referred to as a safety time percentile (STP) may be used. Although these two variables are called “hyperparameters,” they can be analogous to “parameters” in a regular machine learning model, which is optimized during the training process and directly used in the model for the test period. They are referred to as “hyperparameters” in the example algorithm to distinguish them from other model parameters that are not optimized during the training process.

To distinguish SLP from the service level (SL), note that SL describes the performance of a single simulated inventory curve. However, SLP describes the performance of multiple simulated inventory curves, and it is not a replacement but a complement of SL. SLP describes the percentage of inventory realizations that meets the minimum target service level (such as SLₘᵢₙ in Equation (6)). For example, if the minimum target service level is 96% and the total number of uncertainty realizations of simulated inventory is 100, this means there will be 100 simulated inventory curves, and a service level percentile of 50% means that 50 realizations out of the total 100 realizations will have a service level above 96%.

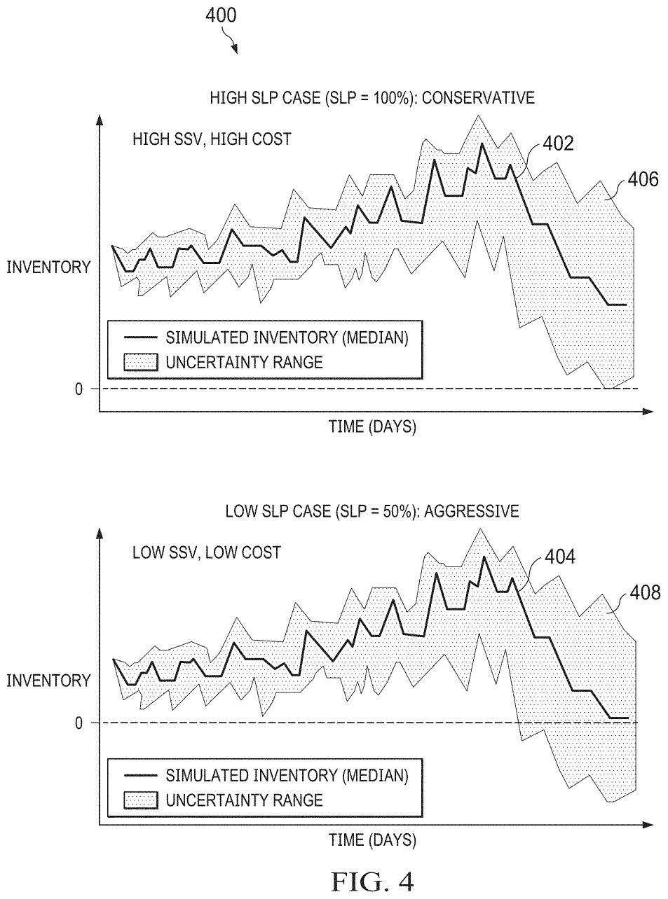

SLP can be used by the algorithm to recommend SSV at each sampling time during the “k-iteration” process, where SLP decides how conservative or aggressive the SSV choice will be. FIG. 4 illustrates an example comparison 400 of high versus low service level threshold percentiles in accordance with this disclosure. In particular, FIG. 4 provides a visual illustration on the discrepancies between a high SLP and a low SLP, where curves 402-404 represent median values of simulated inventories and regions 406-408 represent uncertainty ranges of the simulated inventories. Note that a minimum target service level of 100% is used, for example, while discussing SLP in FIG. 4.

A high SLP (such as 100% as is shown on the left of FIG. 4) puts the entire uncertainty range of the simulated inventory above zero (such as for 100 out of 100 uncertainty realizations, each of the realization has a service level of 100%). A low SLP (such as 50% as is shown on the right side of FIG. 4) only puts the median curve above zero. The low SLP is a more aggressive strategy, which means the inventory will have a higher chance of going below the minimum target service level (a higher risk for stock-out) but the inventory cost will be much lower (higher return for inventory savings). For now, the SLP may be selected in the training based on the inventory cost of the median realizations, which means p=50% for γₚ in Equation (2), but it may also be configured by a file, data stream, input interface, etc.

STP, on the other hand, describes the percentile in the supplier time uncertainty distribution. One strategy used in the safety stock MRP system to de-risk the supplier delay may be to place a purchase order earlier. The safety time is the variable that determines how early the order should be placed compared to the default order placement date in the MRP output. Therefore, the choice of the most suitable safety time depends on the supplier time uncertainty profile, which can vary over the simulation period. A fixed choice of STP can map to different safety times while the supplier time uncertainty profile changes over time.

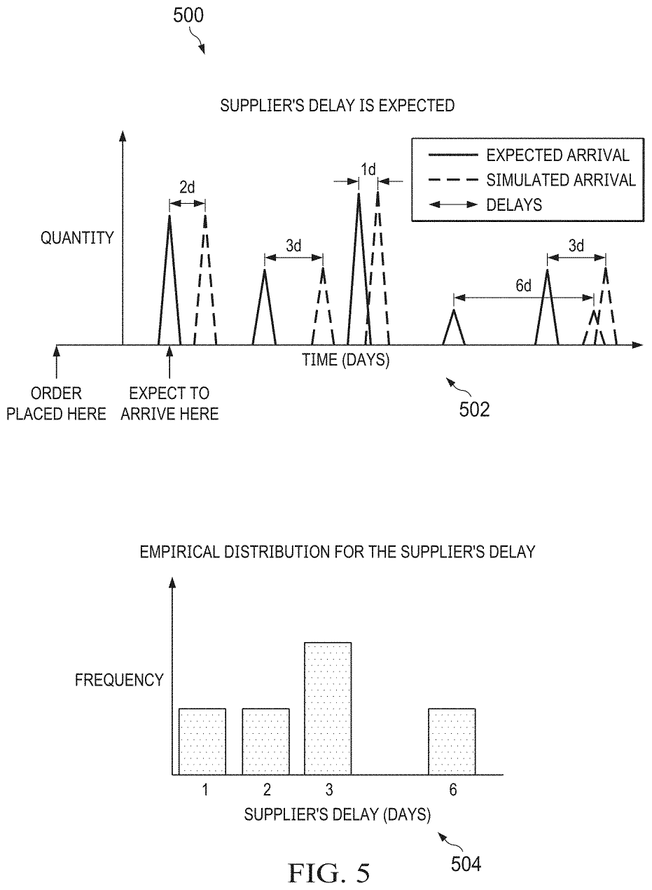

FIG. 5 illustrates an example distribution 500 where a safety time percentile may be used to account for supplier time uncertainty in accordance with this disclosure. More specifically, FIG. 5 demonstrates a distribution that may be employed in deciding the safety time percentile. A plot 502 in FIG. 5 shows the delay of each arriving order in the USW, such as where the delays are represented by differences between the peaks in expected arrival times and peaks in simulated arrival times. Those delays are translated into an empirical distribution of supplier time uncertainty as is shown in a plot 504. Safety time can be determined based on the STP and the empirical distribution. For example, an STP of 50% would translate into a safety time of three days with the empirical distribution provided in the plot 504 of FIG. 5, since the 50th percentile of the empirical distribution is three days. An STP of 100% would translate into a safety time of six days. Similar to the choice of SLP, a high STP represents a conservative strategy, since it would make the MRP place all orders so early that even the longest delay would be prevented. This STP would result in a high service level, but the inventory level will be piling up due to the early placement of orders and the inventory cost will be high. On the other side, a low STP is an aggressive strategy, since it will result in a smaller safety time where the inventory is prone to stock-out but the inventory cost will be lower.

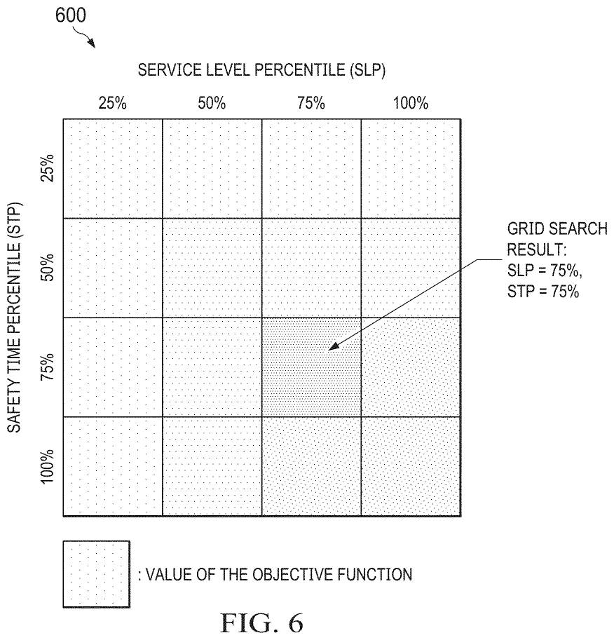

In the training phase 302 of FIG. 3, the best combination of SLP and STP values can be selected, such as based on the grid search approach. In some cases, the SLP and STP values are selected so that the median of the simulated inventory realizations would have the lowest inventory cost while its service level is above the target service level. FIG. 6 illustrates an example grid search 600 of hyperparameters in accordance with this disclosure, which may occur during the selection of the SLP and STP values. Note that the objective function applied and the constraint on the median of the realizations can be design choices, which may be configurable to fit the user's preferences.

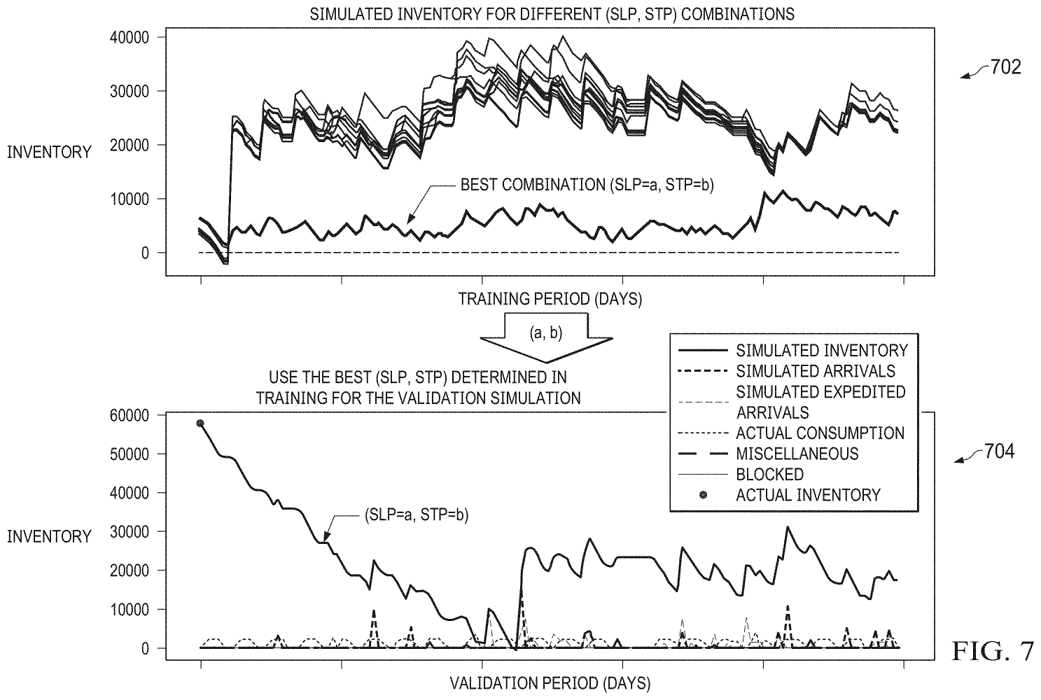

FIG. 7 illustrates an example selection and consumption of hyperparameters in accordance with this disclosure. More specifically, FIG. 7 provides a wholistic picture of how hyperparameters can be selected and consumed in the algorithm. During the training phase 302, the median realizations of the simulations for all combinations of SLP and STP values may be generated, as is shown in a top plot 702 in FIG. 7. Among all the combinations, one combination with SLP equal to a and STP equal to b gives the lowest inventory cost while satisfying the constraint on the service level. Therefore, this combination (a, b) is selected as the best hyperparameters. This hyperparameter pair is used in the validation phase 304, where the selected SLP and STP values are translated into SSV and ST recommendations at each timestamp of the simulation. The inventory is simulated based on those recommendations to generate a simulated inventory curve as shown in a bottom plot 704 in FIG. 7.

Forward-Looking Simulations

After selecting the hyperparameters, the re-order parameters estimation step 312 is performed. To find the optimal re-order parameters at a given sampling time t, the inventory is simulated within a forward-looking window from t to H, where H is the horizon. This simulation is done with the MRP system and can be repeated multiple times, incorporating different samples from the uncertainty distributions. This process is referred to as the forward-looking simulation, which generally includes two steps: (i) running an MRP simulation within the forward-looking window and (ii) generating multiple uncertainty realizations of the simulated inventory by perturbing the demand forecast, the delay, and the quantity shortage of the arriving orders.

In some embodiments, the inputs to the MRP simulation can include (i) the demand forecast made at the sampling time t for the forward-looking window C_{DF}^{t}∈ [symbol] ^{H}, (ii) the existing orders scheduled to arrive within a seeding window, (iii) the candidate SSV and ST values, and (iv) the initial inventory position x₀^{t} at the sampling time t. The existing orders scheduled to arrive within a seeding window may be determined as follows.

A_{seed}^{t}^{ₛ}=[a_{seed}^{t}, . . . ,a_{seed}^{t+t}^{ₛ}⁻¹]∈ [symbol] ^{t}^{ₛ} (20)

Here, tₛ represents the length of the seeding window, and a_{seed}, ∀τ∈[t, . . . , t+tₛ−1] represents the seeded arrival on timestamp r. Note that the size of the seeding window tₛ varies depending on the business logic associated with the customer, but oftentimes it can be set to the lead time (LT).

Given new orders scheduled by the MRP system, a total of Nᵣ realizations of inventory curves can be generated. In some cases, the inventory at time τ+1 for a realization r can be determined as follows.

x^{τ+1}(r)=x^{τ}(r)−c_{A}^{τ}(r)−c_{MM}^{τ}(r)+sₛ^{τ}(r)∈ [symbol] ¹

∀τ∈[t, . . . ,t+H−1] (21)

Here, x^{τ}(r) represents the inventory at time T for the r^{th} realization, c_{A}^{τ}(r) represents the sampled consumption at time τ, c_{MM}^{τ}(r) represents the sampled material movement at time τ, and sₛ^{τ}(r) represents sampled purchase order arrivals at time T. Note that the inventory level x here is no longer stochastic with specific samples. For instance, the sampled consumption at time τ can be expressed as follows.

c_{A}^{τ}(r)=C_{DF}^{t,τ}−u_{DF}(r)∈ [symbol] ¹ (22)

Here, c_{DF}^{t,τ} represents the demand forecast made at time t for time τ, and u_{DF}(r) represents the r^{th} sample from U_{DF} in Equation (19). The sampled material movement at time τ can be expressed as follows.

c_{MM}^{τ}(r)=u_{MM}(r)∈ [symbol] ¹ (23)

Here, u_{MM}(r) represents the r^{th} sample from U_{MM} in Equation (12). Let o₁, o₂, . . . , oₙ represent the set of orders that the MRP system placed, and let tₑ^{o}^{ⱼ} and sₑ^{o}^{ⱼ}, ∀j∈[1, . . . , n] represent the expected arrival time and expected quantity for order oⱼ. In some cases, the r^{th} sampled arrival time for order oⱼ, which can be denoted by tₛ^{o}^{ⱼ}(r), may be determined as follows.

tₛ^{o}^{ⱼ}(r)=tₑ^{o}^{ⱼ}+u_{ST}(r)∈ [symbol] ¹ (24)

Here, u_{ST}(r) is the r^{th} sample from U_{ST} in Equation (13). In some cases, the r^{th} sampled quantity for order oⱼ, which can be denoted by sₛ^{o}^{ⱼ}(r), may be determined as follows.

sₛ^{o}^{ⱼ}(r)=sₑ^{o}^{ⱼ}+u_{SQ}(r)∈ [symbol] ¹ (25)

Here, u_{SQ}(r) is the r^{th} sample from U_{SQ} in Equation (14). The sampled purchase order arrivals at time τ, which can be denoted by sₛ^{τ}(r), may be determined as follows.

$${s}_{s}^{τ} ( r ) = {\sum }_{{o}_{j}} {s}_{s}^{{o}_{j}} ( r ) ∈ {1}^{} , ∀ {t}_{s}^{{o}_{j}} ( r ) = τ \qquad ( 26 )$$

In some embodiments, inventory realizations generated by the forward-looking simulation can be expressed as follows.

X^{:H}(r)=[x^{t}(r), . . . ,x^{t+H-1}(r)]∈ [symbol] ^{H}

∀r∈[1, . . . ,N_{τ}] (27)

The realizations X^{:H}(r), ∀r∈[1, . . . , Nᵣ] can be used to represent the stochastic variable X^{:H} and can be consumed by the k-iteration algorithm to produce recommendations for the re-order parameters.

The k-Iteration Algorithm

The k-iteration algorithm (also included in the re-order parameters estimation step 312 shown in FIG. 3) is used to map the hyperparameters to the re-order parameter recommendations at each sampling time t. This algorithm can be triggered in both training and validation (live production) phases 302-304 of the algorithm workflow 300. The procedure of the k-iteration algorithm can be found in Algorithm 3 as shown below.

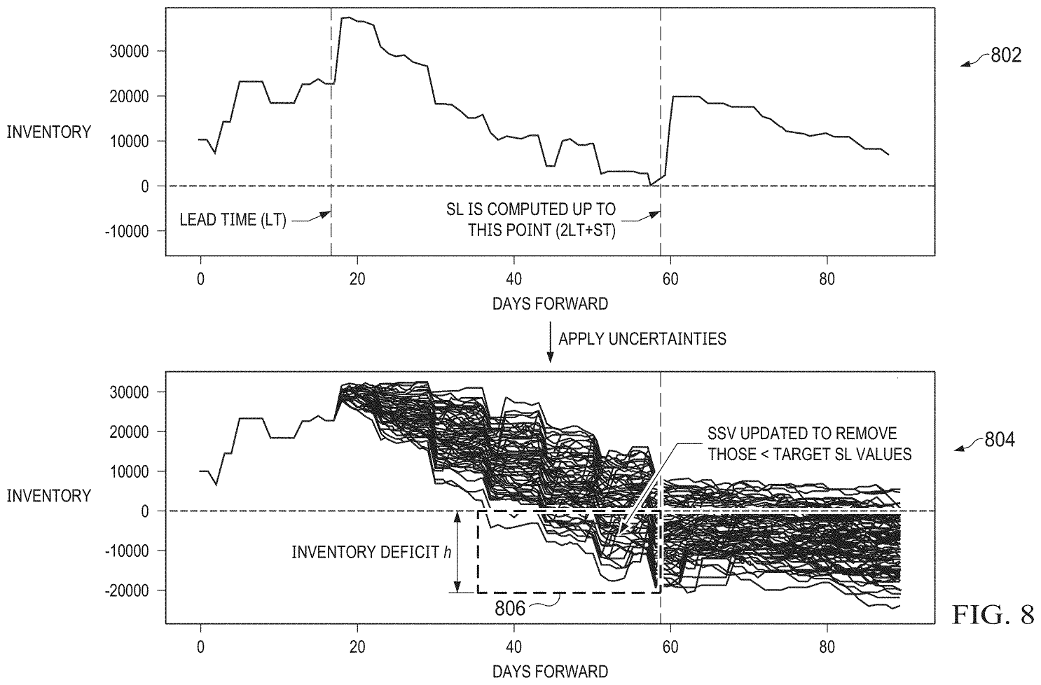

Algorithm 3 The k-iteration algorithm (for the Safety Stock
MRP)

| | |
|---|---|
| 1: | Set ST to the value corresponding to the STP (which is |
| | invariant of the k-th iteration) |
| 2: | Set SSV = 0, h > 0 |
| 3: | while k < max iteration AND h > 0 do |
| 4: | Get Nᵣ samples from each of the empirical uncer- |
| | tainty distribution (i.e., U_{ST}, U_{SQ}, U_{MM}, U_{DF}) |
| 5: | Apply the forward-looking simulation to get |
| | X^{:H} (r), ∀r ∈ [1,...,Nᵣ] |
| 6: | Calculate the inventory cost and the SL associated |
| | with each of the inventory realization r |
| 7: | if Eq. 27 does not hold then |
| 8: | Compute the inventory deficit h (Fig. 8) |
| 9: | else |
| 10: | Set h = 0 |
| 11: | end if |
| 12: | Update SSVₖ₊₁ = SSVₖ + h and add incremental |
| | counter k = k + 1 |
| 13: | end while |
| 14: | return (SSV, ST) |

At a sampling time t, the ST is determined by the STP and the empirical distribution of the supplier time uncertainty U_{ST} in the corresponding USW. For SSV, it is initialized to a value of zero. The loop is entered (such as during the k iteration) for increasing SSV incrementally until the SLₘᵢₙ constraint in Equation (3) is met. In each iteration of this loop, a total of Nᵣ realizations of the simulated inventory curves can be generated (such as X^{:H}(r), ∀r∈[1, . . . , Nᵣ]) using the forward-looking simulation procedure. The inventory cost and SL associated with each realization of the simulated inventory (such as X^{:H}(r)) can be determined, and an inventory deficit h can be calculated to quantify how much lift of the inventory is needed to make sure ψ(X^{:H}) is greater or equal to SLₘᵢₙ.

FIG. 8 illustrates an example where a k-iteration algorithm is used as an interpretation algorithm to determine an inventory deficit in accordance with this disclosure. As shown in FIG. 8, a plot 802 represents possible inventory over time, and a plot 804 represents the possible inventory over time after the uncertainties are applied. In FIG. 8, if the minimum target SL and the SLP are both assumed to be 100%, the inventory deficit h would be the height of the boxed area 806, since that is how much the inventory level needs to be lifted so that 100% (SLP) of the realization curves would satisfy a minimum target SL of 100%.

Note that, for the MRP simulations in the k-iteration algorithm, the arrivals in the time period of [0, LT) (where LT represents the lead time) can be seeded with the simulated arrivals from the MRP orders placed during the previous sampling time, since any order placed at the simulation of the current sampling time will not arrive until after the lead time. Here, the service level is computed in the time period of [LT, min(2LT+ST, H)] due to the fact that the service level in [0, LT) is not in any way affected by the choice of SSV at sampling time t and the service level for later than 2LT+ST is likely overwritten in the next sampling time.

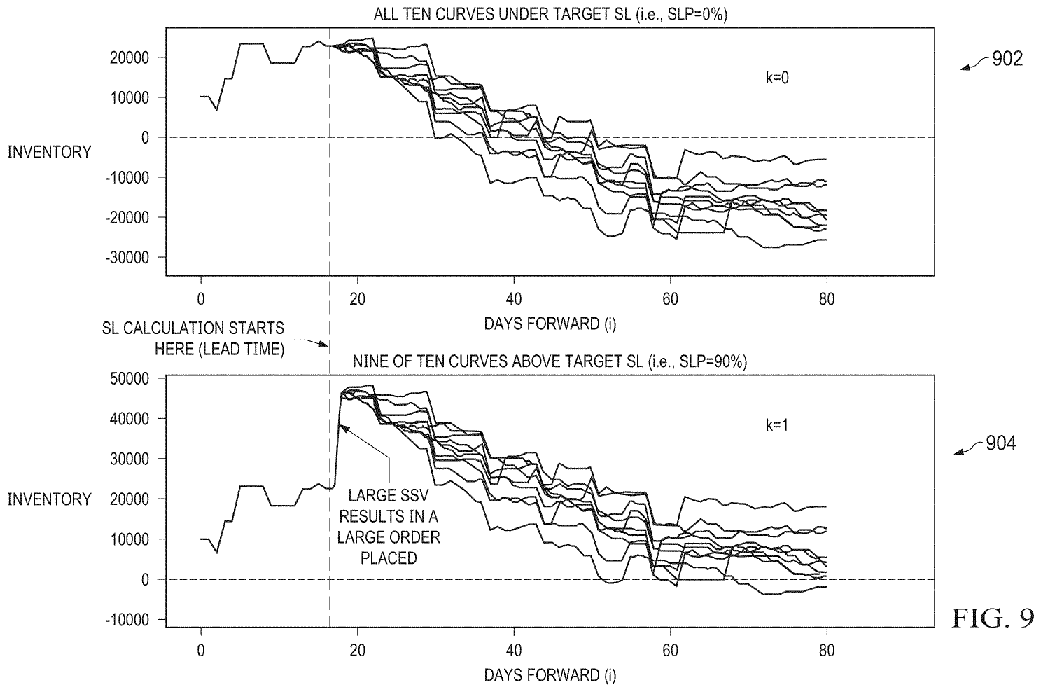

Once the inventory deficit h is determined, the SSV for the next iteration can be calculated by adding h to the current SSVₖ (where k denotes the iteration). The new SSVₖ₊₁ would be used to run the MRP simulation and determine the uncertainty realizations for the next iteration k+1. FIG. 9 illustrates an example where an interpretation algorithm may be used to respond to realized uncertainty by elevating an SSV in accordance with this disclosure. As shown in FIG. 9, a plot 902 represents a collection of simulation results associated with SL values under a target value, and a plot 904 represents the same collection of simulation results associated with SL values that are predominantly above a target value due to elevating (lifting) the SSV. As shown, the lifted SSV may typically be identical to the lift of inventory level, since it would result in a large order arrival right after the lead time to lift the overall inventory level and the SLP will increase as a result.

The iterations of the k-iteration algorithm can continue until one or more specified criteria are met, such as a maximum number of iterations being performed or a determination being made that there is no need to provide additional lift (h=0). In some cases, this latter condition can be expressed as follows for each sampling time t, which utilizes the notations developed in Equations (3) and (6).

$${γ}_{{p}_{SL}} [ \frac{{\sum }_{i = LT}^{min ( 2 LT + ST , H )} δ ( {x}^{t + i} )}{min ( L T + ST , H - L T )} ] - {SL}_{min} \geq 0 \qquad ( 28 )$$

Here, p_{SL} represents the SLP. Note that in the k-iteration procedure, the choice of the initial inventory may be configurable, such as by a file, an external command stream, input interface, etc.

Other Algorithm Treatments

There are several treatments of the algorithm workflow 300 that may have significant impact on the performance and outputs of the algorithm. These treatments may include batched uncertainty realizations with the MRP simulation, “steady-state” initial inventory of the k-iteration algorithm, optimization frequency, and demand forecast pre-processing. Each one of these treatments is described in order below.

With respect to batched uncertainty realizations with MRP, in the k-iteration algorithm described above, each uncertainty realization r does not trigger another MRP simulation. This means that, for Nᵣ simulated inventory curves, the MRP simulation may only be performed once. The remainder of the curves can be generated by simply perturbing the MRP result with the uncertainties sampled from the empirical distributions as a post-processing step. This process is referred to as batched uncertainty realizations with MRP simulation. One example benefit of such an approach is the reduction of computation time, since the uncertainty sampling can be done much quicker in comparison to the MRP simulation. However, those realizations are referred to as proxies, since there can be differences between the results of this approach and the results obtained if the uncertainty distributions are sampled during the MRP simulation processes (such as by performing sequential uncertainty realizations with MRP). The proxies of the simulated inventory may be considered to be sufficiently accurate for the realizations of the simulated inventories, since those realizations may only be used to determine how much SSV should be lifted (rather than accurately computing inventory cost and SL).

With respect to “steady-state” initial inventory, the initial inventory used for the k-iteration algorithm at sampling time t can intuitively be taken from the simulated inventory computed from the previous sampling time. In some cases, this can be expressed as follows.

x₀^{t}=xₛᵢₘ^{t} (29)

Here, x₀^{t} represents the initial inventory for the k-iteration algorithm starting at sampling time t, and xₛᵢₘ^{t} represents the inventory simulated at the previous sampling time. Note that at the beginning of the simulation period (for either training or validation), the simulated inventory can be seeded with the actual inventory. The initial inventory determined by Equation (29) can be sensitive to the simulation process. For instance, if the simulated inventory is high at sampling time t, the initial inventory of the k-iteration would be high. In some embodiments, the realizations in the forward-looking simulation would be far above zero (satisfying the SLₘᵢₙ constraint) even when SSV is set to zero. As a result, the algorithm can give a zero SSV recommendation as long as the current simulated inventory is high.

The SSV recommendations may be expected to be independent of the current inventory level. To achieve this goal, one approach that can be supported uses a “steady-state” inventory as the initial inventory from the k-iteration algorithm. In some cases, the initial inventory of the k^{th} iteration may be determined as follows.

$${x}_{0 , k}^{t} = S S {V}_{k} + {\sum }_{i = 0}^{LT - 1} ( {c}_{DF}^{t , t + i} - {c}_{A}^{t + i} ) \qquad ( 30 )$$

Here, x_{0,k}^{t} represents the initial inventory for the k^{th} iteration starting at sampling time t, SSVₖ represents the SSV candidate at the k^{th} iteration, LT represents the lead time, c_{DF}^{t,t+i}∈ [symbol] ¹ represents the demand forecast for timestamp t+i made at time t, and c_{A}^{t+i}∈ [symbol] ¹ represents the simulated arrivals at timestep t+i.

Note two things regarding the determination of the initial inventory with Equation (30). First, since the arrivals during the time period of [0, LT) may be seeded with the simulated arrivals, the inventory level at LT in the k-iteration procedure may be exactly at the level of the candidate SSV (such as SSVₖ) regardless of the simulated inventory level at the sampling time t. Second, Equation (30) does not enforce the initial inventory to be larger or equal to zero, which means negative inventories can occur in the time period of [0, LT) due to the choice of this initial inventory. However, since the inventory level will be brought back to positive at LT and the service level is only computed in [LT, 2LT+ST], the potential negative inventories in [0, LT) may not affect the SSV recommendations.

With respect to optimization frequency, the optimization frequency relates to the frequency at which the re-order parameters are recommended. This frequency also corresponds to the frequency at which Equation (3) is solved. Ideally, solving Equation (3) at every sampling time t would give an optimal result, since new information is usually provided on a daily basis. However, it may be challenging (if possible at all) for customers to adopt re-order parameter recommendations on a daily basis. Therefore, a feature may be included in the algorithm that allows the optimization frequency to be configurable by users.

If the optimization frequency in days is set to be a number j larger than one day (such as 30 days), the re-order parameter recommendations can be updated every j days. For days where those re-order parameters are not updated, they may default to the values determined at the previous sampling time. However, MRP simulations in the order simulation step 314 may still be performed on a daily basis. Since the optimization frequency adds another constraint on the optimization of the re-order parameters, the more frequent the re-order parameters are allowed to change, the more room there will be for the algorithm to improve the results.

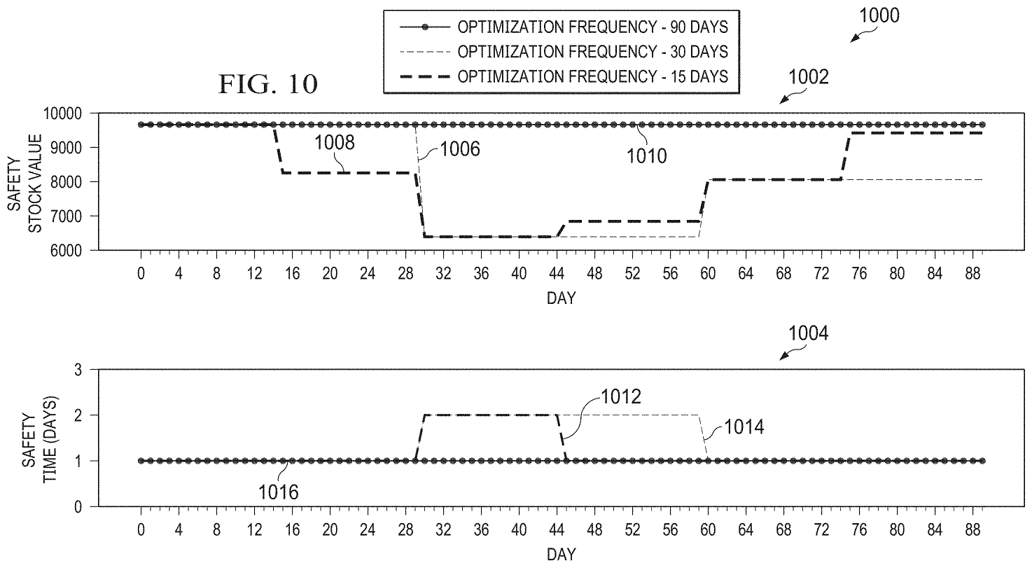

To rationalize this, experimental simulations were set up with various optimization frequencies for a total length of 90 days. FIG. 10 illustrates example SSV and ST recommendations 1000 with different optimization frequencies in accordance with this disclosure. More specifically, FIG. 10 shows SSV and ST recommendations with optimization frequencies of 90 days, 30 days, and 15 days. A plot 1002 shows the SSV recommendations, and a plot 1004 shows the ST recommendations. In the plot 1002, a curve 1006 is associated with SSV recommendations using a 15-day optimization frequency, a curve 1008 is associated with SSV recommendations using a 30-day optimization frequency, and a curve 1010 is associated with SSV recommendations using a 90-day optimization frequency. In the plot 1004, a curve 1012 is associated with ST recommendations using a 15-day optimization frequency, a curve 1014 is associated with ST recommendations using a 30-day optimization frequency, and a curve 1016 is associated with ST recommendations using a 90-day optimization frequency. The SSV and ST recommendations using the 90-day optimization frequency remain unchanged during the entire simulation period. The changes in the SSV and ST recommendations using the 15-day and 30-day optimization frequencies are clearly observed.

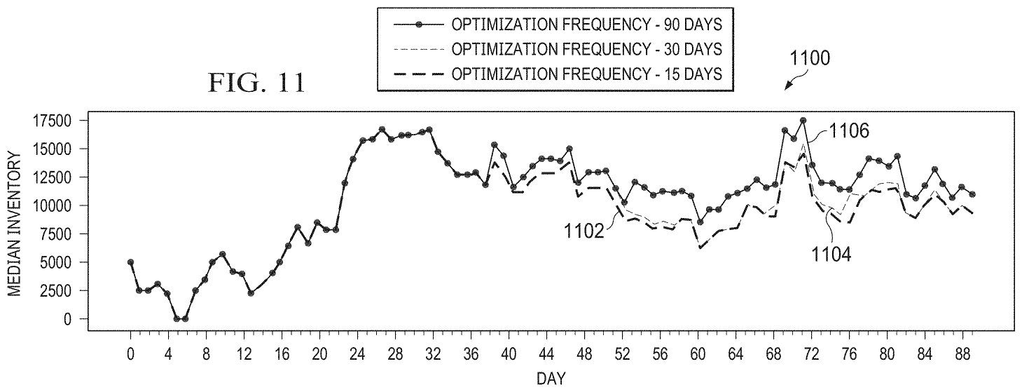

FIG. 11 illustrates example simulated inventory levels 1100 with different optimization frequencies in accordance with this disclosure. More specifically, FIG. 11 demonstrates the median of simulated inventory levels that correspond to each optimization frequency (15-day, 30-day, and 90-day) mentioned above. In FIG. 11, a curve 1102 is associated with the median inventory level using a 15-day optimization frequency, a curve 1104 is associated with the median inventory level using a 30-day optimization frequency, and a curve 1106 is associated with the median inventory level using a 90-day optimization frequency. In this example, the simulated inventory level corresponding to the 90-day optimization frequency is the highest, and the simulated inventory level corresponding to the 15-day optimization frequency is the lowest. Moreover, the simulated inventory levels corresponding to all three optimization frequencies remain above zero. This is generally true since, the more frequent the re-order parameters are allowed to change, the less constraints there will be for the optimization (and a better result would therefore be expected). To summarize, there can be a clear trade-off between the algorithm's performance and the adoption for the choice of optimization frequency. In reality, the decision made on this parameter can vary case-by-case.

With respect to the pre-processing of demand forecast data, a pre-provided demand forecast usually comes with outliers in the data. Those outliers may be due to various factors, such as input errors or inaccurate forecasts. The outliers often have values that are orders of magnitude larger than the regular data points, which can have large impact on the optimization results. To mitigate the impact of those outliers, a clipping step may be applied on the demand forecast data as a pre-processing operation. One example of the clipping may be expressed as follows.

$${\tilde{C}}_{DF , 1 D} = \{ \begin{matrix}{η}_{{C}_{DF}} + {n}_{c} \cdot {σ}_{{C}_{DF}} \\ if {C}_{DF , 1 D} > {η}_{{C}_{DF}} + {n}_{c} \cdot {σ}_{{C}_{DF}} \\ {C}_{DF , 1 D} , otherwise\end{matrix} \qquad ( 31 )$$

Here, \tilde{C}_{DF,1D} represents the clipped demand forecast, C_{DF, 1D} represents the raw demand forecast data computed as in Equation (16), and η_{C}_{_{DF}} and σ_{C}_{_{DF}} represent the median and the standard deviation of the demand forecast data, respectively. Also, n_{c} represents a multiplier that controls the strictness of the clipping, which can be a parameter that is configurable by a file, external command stream, input interface, etc. In some example use cases, for instance, the default may be 5.0. The clipped demand forecast \tilde{C}_{DF,1D} can be used to calculate the convolved demand forecast C*_{DF, 1D} mentioned in Equation (17).

The outliers in the raw demand forecast data can also result in over-estimation of the demand forecast uncertainty. As a result, the demand forecast uncertainty derived from the clipped demand forecast can go through another step of clipping to further reduce those impacts. In some cases, this additional clipping may be expressed as follows.

$${\tilde{U}}_{DF} = \{ \begin{matrix}{η}_{{C}_{DF}} + {n}_{u} \cdot {σ}_{{U}_{DF}} & if {U}_{DF} > {η}_{{U}_{DF}} + {n}_{u} \cdot {σ}_{{U}_{DF}} \\ {U}_{DF} & otherwise\end{matrix} \qquad ( 32 )$$

Here, U_{DF} represents the demand forecast uncertainty as defined in Equation (19) but with C*_{DF} derived from \tilde{C}_{DF} (instead of from C_{DF} directly). Also, η_{U}_{_{DF}} and σ_{U}_{_{DF}} represent the median and the standard deviation of the demand forecast uncertainty, respectively. Similar to that for \tilde{C}_{DF}, nᵤ represents a multiplier that controls the strictness of the clipping. In some example use cases, for instance, the default may be 1.0. Note that the movement uncertainty Umm can be treated in a similar manner to generate a clipped movement uncertainty Ũ_{MM}.

Inventory Optimization at Scale

The example stochastic inventory optimization algorithm described above may be leveraged to integrate various formats of datasets from different data sources such that the data can be easily consumed and input to the deployed inventory optimization framework. The computational intensity for the framework disclosed herein can be easily identified based on the nature of multiple simulation runs. Typically, customers from different industries have hundreds of thousands to millions of types of SKUs to optimize, leading to a necessity of effective large-scale optimization. One example of a model deployment framework that enables systems to scale-out up to millions of machine learning models within a single application through prepackaged automation including automatic scoring, compute resource auto-scaling, version management, alerting, hyperparameter optimization, and auto retraining. This helps to facilitate the performance of inventory optimization and simulation experiments across a large number (possibly millions) of SKUs at scale and in a distributed fashion. Within an example inventory optimization application, information associated with certain business modules in resource planning (such as inventory levels, material movement transactions, purchase orders, production orders, demand forecasts, etc.) may be considered.

Model Deployment

In order to deploy machine learning pipelines on large number of SKUs, machine learning segments can be created to support a model-to-SKUs relationships, and distributed jobs can be run to deploy the machine learning pipelines on a large number of SKUs or a group of SKUs that belong to one segment. Configuration of a champion and challenger model to make sure that the live model is always providing optimal results is also possible. Model operations and model governance can be useful or important in managing model recommendations and explaining model predictions.

Stochastic Inventory Optimization

The example stochastic inventory optimization (SIO) algorithm disclosed herein improves performance in a variety of verticals. The performance of the example SIO system with different levels of details was determined, and the inventory savings that can be achieved by applying the algorithm were demonstrated. As one example, information regarding two representative SKUs in the energy and manufacturing industries were analyzed. How the algorithm manages to recommend a lower SSV while keeping a satisfying service level was demonstrated in detail. The dataset was then expanded to use 54 representative SKUs in the same industries, and the impacts of some of the model parameters on the performance of the algorithm were determined. The generality of the algorithm (by showing its performance on customer data across a variety of verticals) was further demonstrated.

With respect to the optimization results for two sampled SKUs, the example SIO system was applied on two representative SKUs (referred to as SKU A and SKU B) from clients in the energy and manufacturing industries. The minimum target service levels for SKU A and SKU B were set to 91% and 96%, respectively. The data available for both SKUs ranged from Jun. 1, 2018 to Oct. 1, 2020. The training period for the example SIO system ranged from Jun. 1, 2018 to Mar. 1, 2020. The validation period ranged from Apr. 1, 2020 to Oct. 1, 2020. Since Oct. 1, 2020 is the last date with data available, the operation date (or live production date) was set to Oct. 1, 2020. The optimization frequency was set to 30 days, which means that this example algorithm was able to recommend new re-order parameters every 30 days.

According to client requirements, STP was held constant and always set at ST=0. Therefore, for the grid search in the training phase 302, the optimal SLP from the SLP candidate list may be exclusively selected. The SLP candidate list was set to a default value of [50, 70, 90, 92.5, 95] here. The default multiplier for clipping the demand forecast (n_{c} in Equation (31)) was set to 5.0, and the default multiplier for clipping the demand forecast uncertainty (nᵤ in Equation (32)) was set to 1.0. The default minimum length of the uncertainty sampling window Lₘᵢₙ^{USW} (Equation (11)) was 30 days, and the USW buffer b^{USW} (Equation (11)) was set to 14 days. The number of uncertainty realizations in a forward-looking simulation procedure (Nᵣ in Equation (27)) was set in this example to 100. These default values were altered later in a later portion of the example to evaluate their impacts on the performance of the algorithm.

Note that during the order simulation step 314 in the example SIO system's algorithm workflow 300, multiple realizations of the inventory (denoted as Nₒₛ here) can be generated and compared with the actual inventory associated with a customer. The value of Nₒₛ was set to ten in this case. Also, the client intended to focus on the savings for the inventory holding cost, so the value of π_{o,t} in Equation (3) was set to zero in this case.

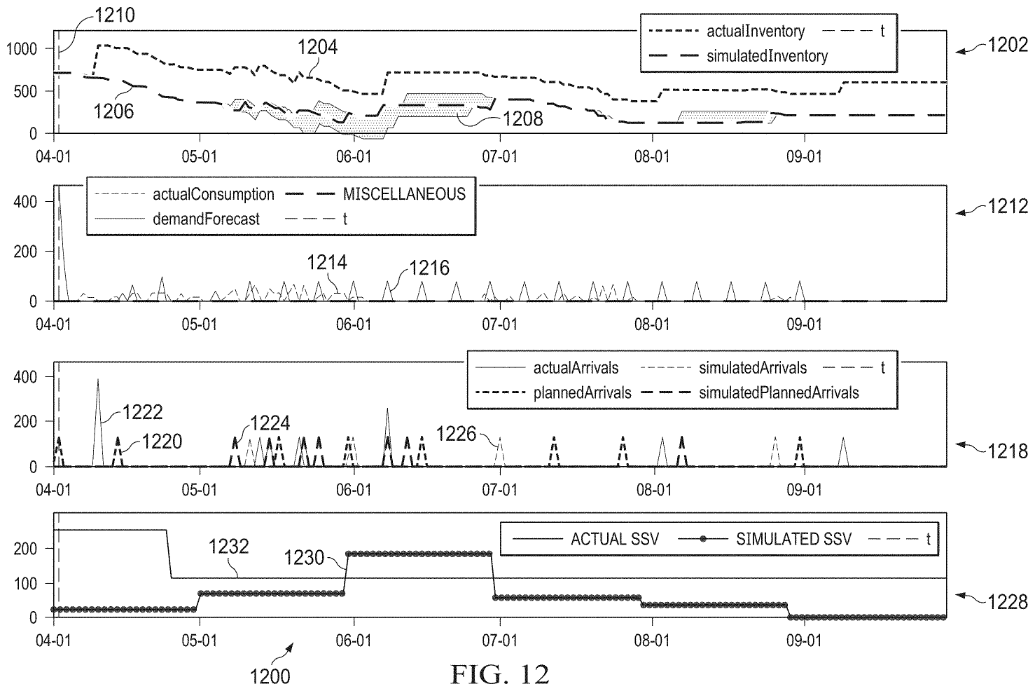

FIG. 12 illustrates example simulation results 1200 for a first product (SKU A) involving simulated and actual inventories, demand forecast and actual consumption, planned and actual arrivals for simulated and actual inventories, and simulated and actual SSV recommendations in accordance with this disclosure. As shown in FIG. 12, a plot 1202 shows a comparison between actual inventory (represented by a curve 1204) and the median of the simulated inventory realizations (represented by a curve 1206) over the validation period. Shading 1208 surrounding parts of the curve 1206 represent the uncertainty range generated from the ten uncertainty realizations. A line 1210 identifies a current sampling time t. In a plot 1212, actual consumption (represented by a curve 1214) is compared to the demand forecast (represented by a curve 1216). In this example, it is assumed that there are no miscellaneous movements, although that need not be the case. A plot 1218 compares planned arrivals (represented by a curve 1220) and actual arrivals (represented by a curve 1222) in reality and planned arrivals (represented by a curve 1224) and actual arrivals (represented by a curve 1226) determined during simulation. A plot 1228 compares simulated SSV recommendations (represented by a curve 1230) with actual SSV recommendations (represented by a curve 1232).

Looking at the plot 1202 in FIG. 12, it is obvious that the simulated inventory represented by the curve 1206 is at a lower level overall in comparison with the actual inventory represented by the curve 1204. The shaded area 1208 shows the uncertainty range for the simulated inventory with ten uncertainty realizations. A small portion of the shaded area 1208 drops below zero around Jun. 1, 2020, indicating a slight out-of-stock risk (potentially caused by some outliers in the uncertainties). However, the simulated inventory represented by the curve 1206 (which represents the median of all curves in the shaded area 1208) is far away from zero, which gives more confidence in the overall healthiness of the inventory level.

The curves 1214 and 1216 in the plot 1212 of FIG. 12 indicate that the demand forecast is significantly more than the actual consumption. This scenario is referred to as over-forecasting. Note that the plot 1212 only shows the demand forecast made on Apr. 1, 2020. Demand forecasts on other days in the validation period showed consistent over-forecasting.

The plot 1218 in FIG. 12 represents the arrival information for both simulated inventory and actual inventory. Actual arrivals are represented by the curve 1222, which corresponds to the increases of the curve 1204 in the plot 1202. Comparing the curves 1220 and 1222 in the plot 1218, a sense of supplier time uncertainty (how much the actual arrivals are late compared to the planned arrivals) and supplier quantity uncertainty (how many quantities the actual arrivals are less than the planned arrivals) can be gained for the actual inventory. Similarly, the curve 1226 in the plot 1218 corresponds to simulated arrivals, which corresponds to the increases of the curve 1206 in the plot 1202. Comparing the curves 1224 and 1226 indicates the supplier time and quantity uncertainties for the simulated inventory.

The plot 1228 in FIG. 12 shows the simulated SSV recommendations represented by the curve 1230 and the actual SSV recommendations represented by the curve 1232. The simulated SSV is overall much lower than the actual SSV, resulting in fewer orders placed in the validation period. This may be one primary reason why the overall simulated inventory level is lower than the actual inventory level in the plot 1202. Note that the curve 1230 here is stair-like because the optimization frequency was set to 30 days.

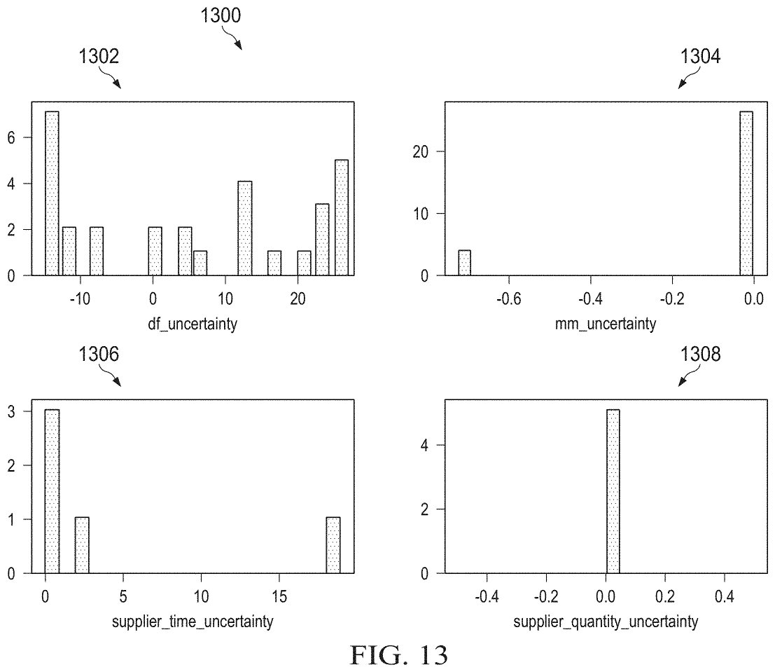

To identify the reason behind the low SSV recommendation shown in the plot 1228 of FIG. 12, the uncertainty sampling process and the k-iteration algorithm can be examined. FIG. 13 illustrates example sampled uncertainties 1300 within a USW for the first product (SKU A) including demand forecast uncertainty, movement uncertainty, supplier time uncertainty, and supplier quantity uncertainty in accordance with this disclosure. More specifically, FIG. 13 demonstrates the uncertainties sampled at the beginning of the validation period. Note that the lead time for this SKU is six days, the USW buffer b^{USW} is set to fourteen days, and the uncertainty sampling window ranges from Mar. 12, 2020 to Apr. 1, 2020. A plot 1302 shows a histogram of the demand forecast uncertainty. There are more positive samples than negative samples in the histogram, which is consistent with the over-forecasting observed in the plot 1212 of FIG. 12. Plots 1304-1308 respectively show histograms of the movement uncertainty, supplier time uncertainty, and supplier quantity uncertainty.

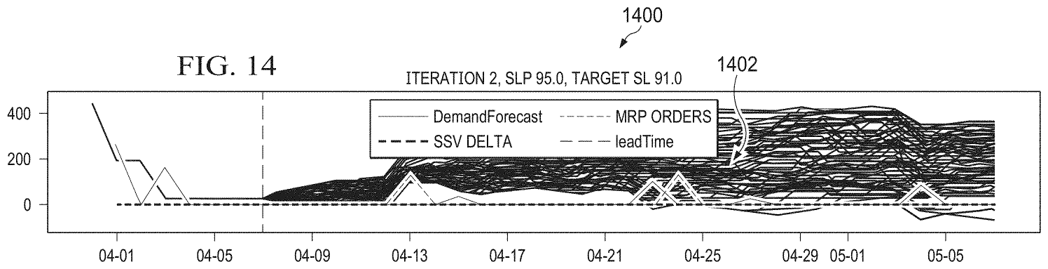

In the k-iteration algorithm, the demand forecast is used as the input for the MRP simulation, and the output of the MRP simulation is “corrected” to the actual consumption by sampling the demand forecast uncertainty. If more positive samples are present in the demand forecast uncertainty, it means that the actual consumption is more likely to be less than the demand forecast used as the input of the MRP. Therefore, the simulated inventory level is more likely to be pushed up in the uncertainty realizations. FIG. 14 illustrates example forward-looking simulation results 1400 in the first iteration of a k-iteration algorithm for the first product (SKU A) in accordance with this disclosure. More specifically, FIG. 14 shows the simulation with uncertainty realizations in the first iteration of the k-iteration procedure. Various curves 1402 in FIG. 14 represent the uncertainty realizations of the simulated inventory. Most of the uncertainty realizations are above zero due to the reasons discussed above. Therefore, the inventory deficit is small, and significant lifting of the SSV to satisfy the constraint on the service level is not required.

Demonstrated in this example, the example SIO system algorithm offered an objective view for potential risks involved every time a recommended SSV was generated. This view is obtained from MRP simulations with multiple uncertainty realizations in the k-iteration procedure. With SKU A, such a view helped to reduce the SSV significantly compared to the actual SSV used by the customer.

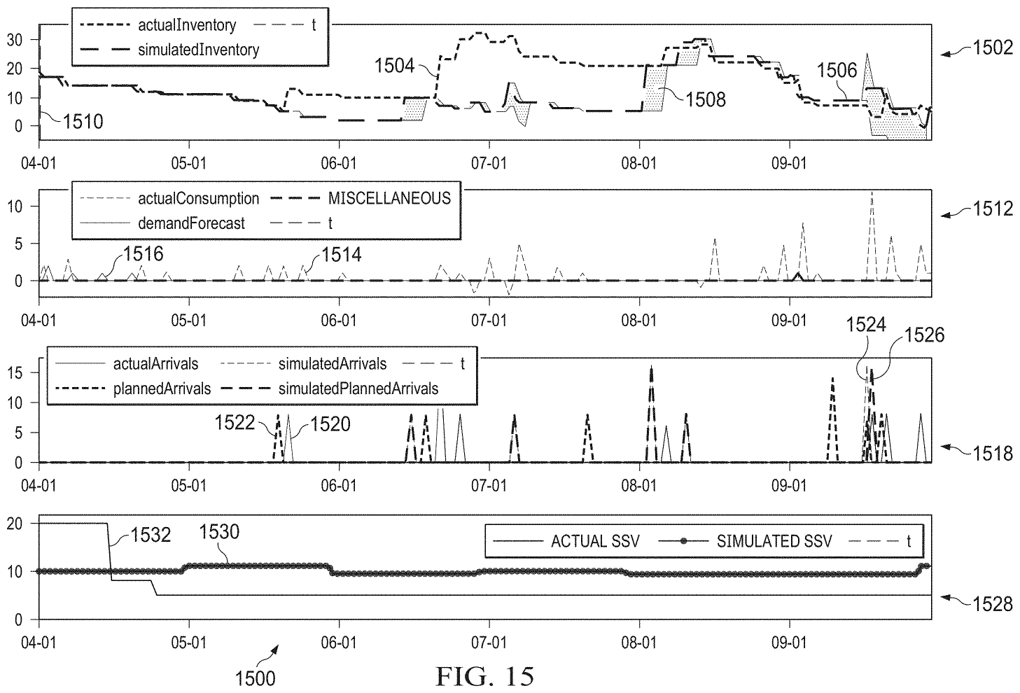

FIG. 15 illustrates example simulation results 1500 for a second product (SKU B) involving simulated and actual inventories, demand forecast and actual consumption, planned and actual arrivals for simulated and actual inventories, and simulated and actual SSV recommendations in accordance with this disclosure. The results in FIG. 15 contain the same types of plots as in FIG. 12. A plot 1502 shows a comparison between actual inventory (represented by a curve 1504) and the median of the simulated inventory realizations (represented by a curve 1506) over the validation period, where shading 1508 surrounding parts of the curve 1506 represents the uncertainty range generated from the ten uncertainty realizations and a line 1510 identifies a current sampling time t. A plot 1512 compares actual consumption (represented by a curve 1514) to the demand forecast (represented by a curve 1516). A plot 1518 compares planned arrivals (represented by a curve 1520) and actual arrivals (represented by a curve 1522) in reality and planned arrivals (represented by a curve 1524) and actual arrivals (represented by a curve 1526) determined during simulation. A plot 1528 compares simulated SSV recommendations (represented by a curve 1530) with actual SSV recommendations (represented by a curve 1532).

There is one significant difference between SKU B and SKU A regarding the demand forecast. Observed in the plot 1512 of FIG. 15, the curve 1516 is significantly less than the curve 1514, which indicates significant under-forecasting in the demand forecast. Note that the curve 1516 in the plot 1512 only shows the demand forecast made on Apr. 1, 2020. In fact, the demand forecast made on most of the days in the validation period are all zero. This is not a rare case in the customer's data. Significant under-forecasting or complete missing of demand forecasts is observed for the vast majority of the in-scope SKUs provided by the customer, due to the fact that the customer lacks the capability to predict consumption for the SKUs it holds. Nevertheless, the example SIO system algorithm is capable of maintaining the service level with SSV recommendations even when the demand forecast is very sparse or completely missing, as will be demonstrated using SKU B.

The plot 1528 in FIG. 15 indicates that the algorithm overall recommends a much higher SSV compared to the actual SSV used by the customer. Yet, the plot 1502 in FIG. 15 shows that the higher SSV recommendation ends up with an overall lower simulated inventory level compared to the actual inventory level while still satisfying the service level constraint. In some cases, the actual SSV is much lower than the simulated SSV, but the actual inventory ends up in a much higher position compared to the simulated inventory because the actual inventory may be managed or influenced by human operators who may not place orders exactly following the MRP output. In the case of SKU B, it is likely that a human operator placed more orders than what the MRP system recommended. In an example where the orders are placed exactly following the actual SSV, the actual inventory may have significant service level issues (such as serious stock-outs).

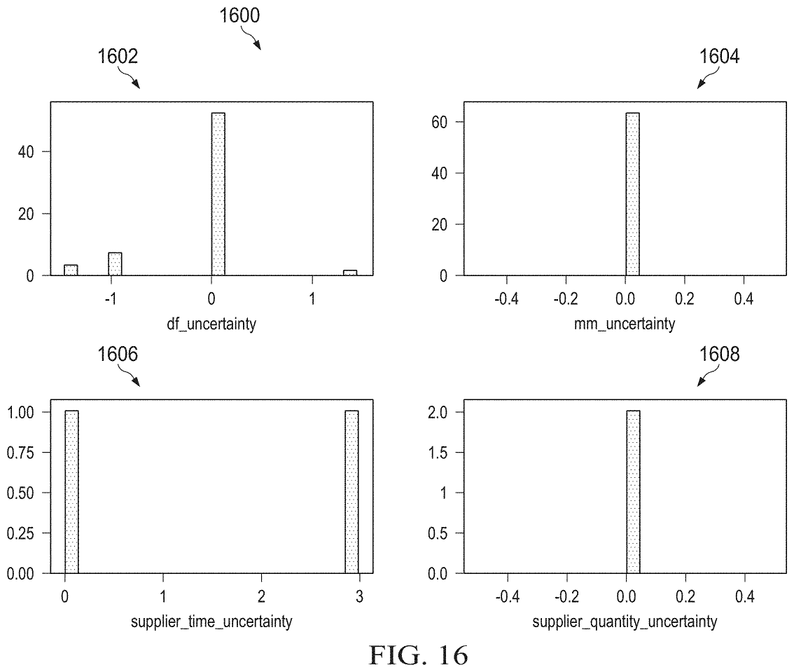

It is quite intuitive that when the demand forecast is missing, a high SSV level is maintained to account for unexpected consumption. FIG. 16 illustrates example sampled uncertainties 1600 within a USW for the second product (SKU B) including demand forecast uncertainty, movement uncertainty, supplier time uncertainty, and supplier quantity uncertainty in accordance with this disclosure. More specifically, FIG. 16 shows the uncertainties sampled at the beginning of the validation period. A plot 1602 shows a histogram of the demand forecast uncertainty. Here, the demand forecast uncertainty indicates an overall under-forecast, since most of the non-zero samples are negative. The negative samples in the demand forecast uncertainty would pull the inventory level lower in the uncertainty realizations of the k-iteration procedure, forcing a higher SSV to maintain the service level. Plots 1604-1608 respectively show histograms of the movement uncertainty, supplier time uncertainty, and supplier quantity uncertainty.

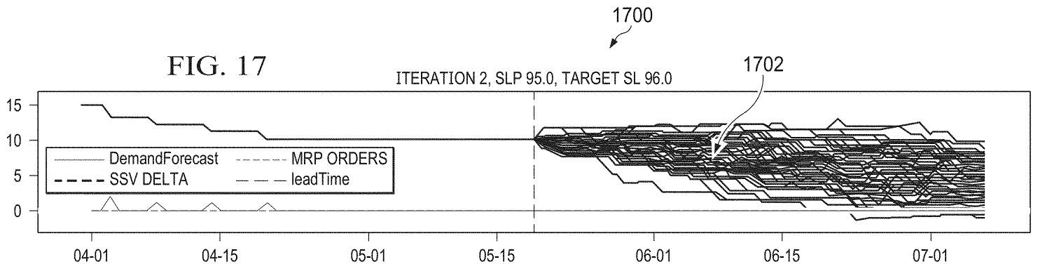

FIG. 17 illustrates example forward-looking simulation results 1700 in the final iteration of a k-iteration algorithm for the second product (SKU B) in accordance with this disclosure. More specifically, FIG. 17 shows the uncertainty realizations in the last iteration of the k-iteration procedure on Apr. 1, 2020. Various curves 1702 in FIG. 17 represent the uncertainty realizations of the simulated inventory. Note that the overall downward trend of the inventory is due to the negative samples of the demand forecast uncertainty. This indicates that the demand forecast fed to the MRP simulation is an under-forecast, so “corrections” are applied to pull the inventory level down. As a result, to meet the service level constraint, a higher SSV is recommended.

Other than the hyperparameters (which can specifically refer to SLP and STP), there are a few model parameters that can be critical or important to the performance of the example SIO system depending on the implementation. In some cases, those model parameters may include the multiplier for clipping the demand forecast (such as n_{c} in Equation (31)), the multiplier for clipping the demand forecast uncertainty (such as nᵤ in Equation (32)), the candidate list for SLP, the length of the offset (buffer) for the USW (such as b^{USW} in Equation (11)), and the number of uncertainty realizations (such as Nᵣ in Equation (27)). To evaluate the impact of these model parameters on the model performance, the experiment expanded to include an ensemble of 54 SKUs. Those 54 representative SKUs were hand-picked by the client's subject matter experts with an intention to cover various scenarios they encounter in their business operations.

For each of the studies, a few key performance metrics including the percentage of SKUs meeting the target service level (such as service level adherence rate denoted r_{AD}), inventory holding cost saving percentage averaged over the entire validation period (denoted s̅ᵢₙᵥ), safety stock holding cost saving percentage averaged over the entire validation period (denoted s̅ₛₛ), and safety stock holding cost saving percentage at the operation date (denoted s_{ss, op}) were compared. The service level adherence rate can be defined as follows.

$${r}_{A D} = \frac{{\sum }_{i = 1}^{{N}_{SKU}} δ ( S {L}_{i} - S {L}_{i , target} )}{{N}_{S K U}} \qquad ( 33 )$$

Here, N_{SKU} represents the total number of SKUs in the scope, which in this example means N_{SKU}=54. Also, the notation δ(⋅) represents the level set function as defined in Equation (7), and SLᵢ and SL_{i,target} respectively represent the service level from the example SIO system simulation and the target service level for SKU i. In some cases, the inventory holding cost saving percentage averaged over validation period can be defined as follows.

$${\overline{s}}_{inv} = \frac{{\sum }_{t = 1}^{{N}_{T}} ( {x}_{a}^{t} - {x}_{sim}^{t} ) {π}_{h}^{t}}{{\sum }_{t = 1}^{{N}_{T}} {x}_{a}^{t} {π}_{h}^{t}} \qquad ( 34 )$$

Here, t represents the timestep in the validation period, N_{T} represents the total number of days in the validation period, xₐ^{t} and xₛᵢₘ^{t} respectively represent the actual and simulated inventory levels at timestamp t, and πₕ represents the inventory holding cost. Similarly, the safety stock holding cost saving percentage averaged over validation period and the safety stock holding cost saving percentage at operation date may be defined as follows.

$${\overline{s}}_{ss} = \frac{{\sum }_{t = 1}^{{N}_{T}} ( SS {V}_{a}^{t} - S S {V}_{sim}^{t} ) {π}_{h}^{t}}{{\sum }_{t = 1}^{{N}_{T}} {x}_{a}^{t} {π}_{h}^{t}} \qquad ( 35 )$$

$${\overline{s}}_{ss , op} = \frac{{N}_{T} ( SS {V}_{a}^{op} - S S {V}_{sim}^{op} ) {π}_{h}^{op}}{{\sum }_{t = 1}^{{N}_{T}} {x}_{a}^{t} {π}_{h}^{t}} \qquad ( 36 )$$

Here, the notation SSV represents the safety stock value, and the superscript op represents the timestep at the operation date (which may typically be the date right after the validation period finishes). Note that in Equations (35) and (36), the denominator is the total inventory holding cost rather than the total safety stock holding cost over the validation period.

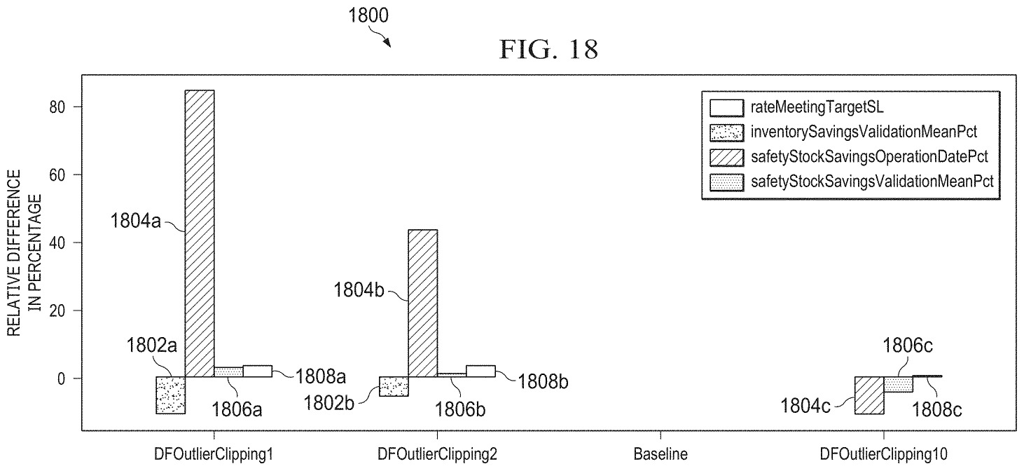

FIG. 18 illustrates example results 1800 of a sensitivity study on a clipping multiplier for raw demand forecast data in accordance with this disclosure. Here, the results 1800 relate to a sensitivity study for n_{c}, the multiplier for clipping the demand forecast. Setting n_{c}=5.0 as the baseline case for this example, n_{c} values larger and smaller than the baseline were evaluated. The x-axis in the results 1800 shows n_{c} values of 1.0, 2.0, 5.0, and 10.0, successively. Bars 1802a-1802b represent r_{AD}, meaning the rate of meeting the target SL value (note that no r_{AD} bar is provided for the n_{c} value of 10.0 since the target SL value is never satisfied there). Bars 1804a-1804c represent s̅ᵢₙᵥ, which represents the average percentage value of inventory savings during validation. Bars 1806a-1806c represent s_{ss, op}, which represents the safety stock holding cost saving percentage at the operation date. Bars 1808a-1808c represent s̅ₛₛ, which represents the average safety stock holding cost saving percentage during validation.

With n_{c} larger than the baseline, a clear drop of all saving metrics (such as s̅ᵢₙᵥ, s̅ₛₛ, and s_{ss, op}) with no improvement in r_{AD} was observed. On the other hand, making the clipping criteria stricter and setting n_{c} smaller than the baseline produced a clear improvement of the saving metrics, especially for the inventory holding cost savings (see bars 1804a-1804b). However, the service level adherence rate will be lower in these conditions. Obviously, there is a trade-off between the service level and the savings. Starting from n_{c}=1.0, improving r_{AD} by increasing n, came at the cost of reducing the savings. However, after n_{c}=5.0, increasing n_{c} no longer provided improvements in r_{AD}. Therefore, in this example, n_{c}>5.0 may not be desirable due to reduced savings.

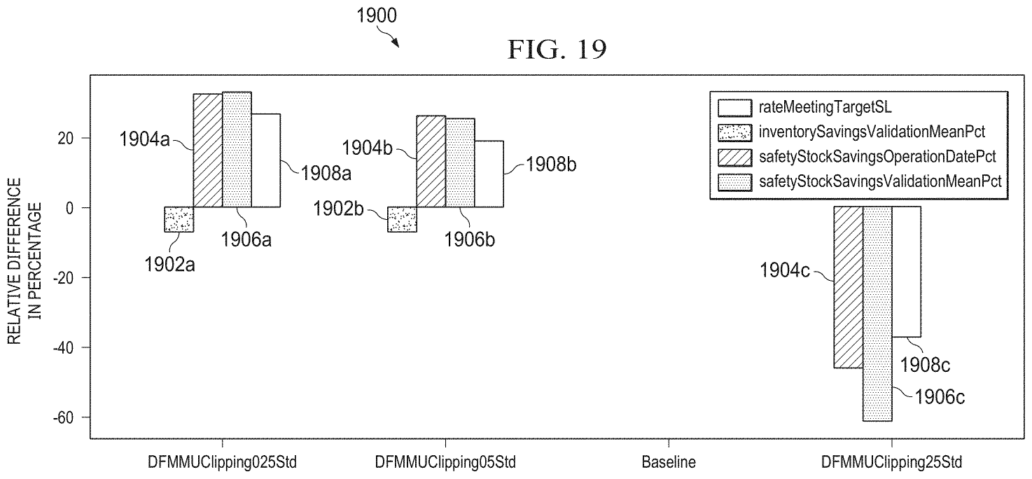

FIG. 19 illustrates example results 1900 of a sensitivity study on a clipping multiplier for demand forecast uncertainty and movement uncertainty in accordance with this disclosure. Here, the results 1900 relate to a sensitivity study for nᵤ, the multiplier for clipping the demand forecast uncertainty. FIG. 19 compares the service level adherence rate and the saving metrics for inventory optimization results with various nᵤ values. The baseline for nᵤ is 1.0, and various bars 1902a-1902b, 1904a-1904c, 1906a-1906c, 1908a-1908c map the same metrics as in FIG. 18. Here, cases with nᵤ set to 0.25, 0.5, and 2.0 were compared. As nᵤ increased, r_{AD} improved at the cost of reducing savings. As nᵤ gets larger than 1.0, the improvement in r_{AD} stopped. Therefore, in this example, nᵤ=1.0 can be a reasonable choice if improving r_{AD} is more important than increasing savings.

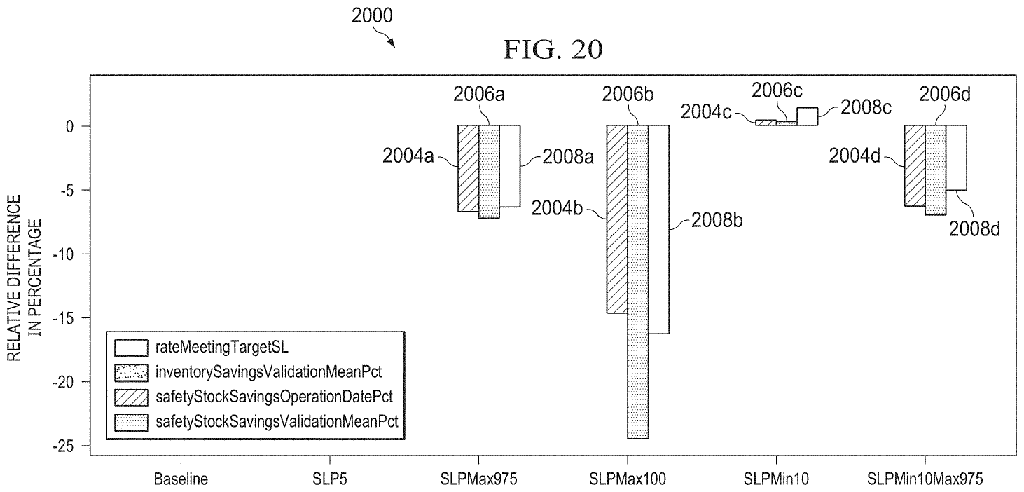

Note that the hyperparameter search results depend on the initial candidate list provided to the algorithm. For example, if the grid search of SLP starts with different candidate SLP lists, the optimized SLP can be different, and the resulting inventory or SSV savings can be affected. FIG. 20 illustrates example results 2000 of a sensitivity study on a candidate list for SLP in accordance with this disclosure. In this example, only SLP was optimized as a hyperparameter. The items on the x-axis of the results 2000 represent an SLP candidate list. The mapping between the x-axis notations in FIG. 20 and the SLP candidate list can be found in Table 1 below. For example, “Baseline” corresponds to the initial SLP candidates of 50%, 70%, 90%, 92.5%, and 95%. For experiments with “Baseline,” the best SLP can be chosen from the above five candidates.

TABLE 1
SLP Candidates in FIG. 20

| Notation | SLP candidates |
|---|---|
| Baseline | [50, 70, 90, 92.5, 95] |
| SLP5 | [50, 55, 60, 65, 70, 75, 80, 85, 90, 92.5, 95] |
| SLPMax975 | [50, 70, 90, 92.5, 95, 97.5] |
| SLPMax100 | [50, 70, 90, 92.5, 95, 97.5, 100] |
| SLPMin10 | [10, 30, 50, 70, 90, 92.5, 95] |
| SLPMin10Max975 | [10, 30, 50, 70, 90, 92.5, 95, 97.5] |

Bars 2004a-2004d, 2006a-2006d, 2008a-2008d can have similar meanings as various bars in FIGS. 18 and 19. FIG. 20 clearly indicates that the service level adherence rate is not affected as the SLP candidate list is changed for the 54 SKUs examined. In addition, as the upper bound of the candidate list is increased from 95% to 97.5% and 100%, the saving metrics drop significantly. This is expected since a high SLP value means that the recommended SSV is more likely to be affected by the outliers of the uncertainties. For example, if an outlier in the supplier quantity uncertainty (a large shortage) is present, setting SLP equal to 100% means the recommended SSV will ensure the inventory meets target service level even when this outlier is present, which will end up with a very high SSV recommendation. On the other hand, if the lower bound of the candidate list is extended, a slight increase of the savings is observed. Since selecting a very low SLP candidate involves larger risks for service level hits, the decision whether or not to extend the lower bound can be made by customers based on their risk profiles.

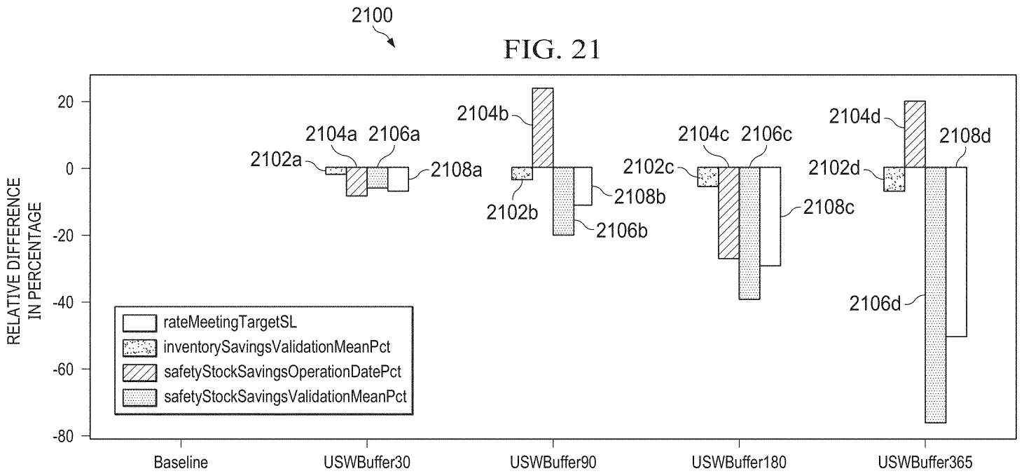

FIG. 21 illustrates example results 2100 of a sensitivity study on a buffer for USW size in accordance with this disclosure. Here, the results 2100 relate to a sensitivity study for b^{USW}, the buffer for the USW. In this example, the baseline buffer is set to fourteen days, and results with buffers of 30, 90, 180, and 365 days are plotted successively in FIG. 21. Bars 2102a-2102d, 2104a-2104d, 2106a-2106d, 2108a-2108d can have similar meanings as various bars in FIGS. 18 and 19. Despite some minor inconsistencies between the inventory savings and the SSV savings, a general downward trend is observed for both saving metrics and the service level adherence rate r_{AD}. This result is expected since, as the USW gets longer, outliers are more likely to appear in the sampling window, causing problems for both savings and service level. In some circumstances, a shorter USW can help when enough samples are collected within the window.

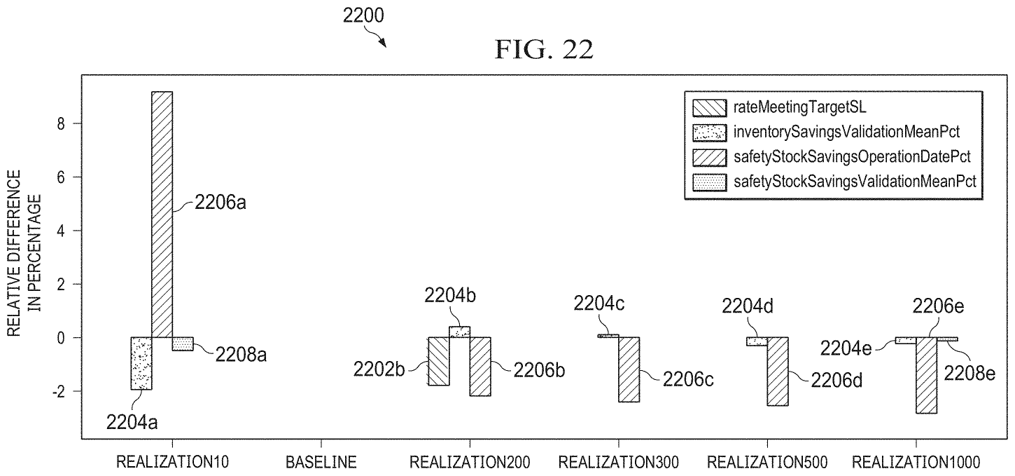

FIG. 22 illustrates example results 2200 of a convergence study on a number of uncertainty realizations in a forward-looking simulation procedure in accordance with this disclosure. Here, the results 2200 relate to a sensitivity study for Nᵣ, the number of uncertainty realizations in the forward-looking simulation. In this example, the baseline is set to 100 realizations. Bars 2202b, 2204a-2204e, 2206a-2206e, 2208a and 2208e can have similar meanings as various bars in FIGS. 18 and 19. As is observed in FIG. 22, results experience large oscillation with smaller numbers of realizations. As the number of realizations approaches 500, saving metrics and the service level adherence rate r_{AD} stabilize.

In summary, the example SIO system algorithm has been applied to customer data in a variety of verticals including building, energy, healthcare, and manufacturing. The results of the algorithm are summarized in Table 2 below. The columns in Table 2 refer to the total number of SKUs in-scope, the actual inventory cost for the customer for the validation period, the simulated inventory cost generate by the example SIO system in the validation period, the actual SSV cost for the customer, the cost of SSV recommended by the example SIO system, the percentage of savings (inventory savings or SSV savings), the actual service level maintained by the customer, and the service level for the simulated inventory (with SSV recommended by the example SIO system). Note that, for some of the customers, savings are measured by the percentage reduction on the SSV cost (defined in Equation (35)). Therefore, SSV cost reduction is distinguished from other inventory savings while interpreting the results.

TABLE 2
Inventory Optimization Results for Different Customers (k: thousand, M: million)

| Customers | #SKUs | | Invₐ | Inv_{C3} | SSVₐ | SSV_{C3} | Saving % | SLₐ | SL_{C3} |
|---|---|---|---|---|---|---|---|---|---|
| Customer 1 | 501 | | $10 M | $7.5 M | — | — | 25% | 99% | 98.0% |
| Customer 2 | 20.6 | k | $64 M | — | $11 M | $1.9 M | 14.2%* | 99.9%** | 98.7% |
| Customer 3 | 1.4 | k | $24 M | $21 M | — | — | 14% | 88.6% | 90.3% |
| Customer 4 | 1.3 | K | $7.7 M | $6.5 M | — | — | 15% | 97.6% | 91.0% |
| Customer 5 | 1 | k | $11.7 M | $9.2 M | — | — | 21.2% | 98.6% | 94.2% |

In Table 2, the “*” marker indicates that the saving percentage is calculated following Equation (35), and the “**” marker indicates that the actual SL is unreasonably high due to human intervention with extra information. Table 2 demonstrates that the example SIO system algorithm is effective for large-scale inventory optimization across a variety of verticals. The system is capable of reducing the inventory and the safety stock costs by 10-20% or more while maintaining the service level similar to its current position.

In the above examples, challenges for large-scale supply chains were discussed, and example approaches disclosed herein were evaluated. Some embodiments of these solutions are termed the example SIO system algorithm. The example SIO system algorithm works well with a variety of MRP systems or receding horizon systems, and the examples above demonstrate how embodiments work in a specific type of MRP system (such as the safety stock MRP system). The example SIO system algorithm has a training phase 302 that helps to determine or select the hyperparameters that apply to the associated risk profile. The algorithm also has a validation (live production) phase 304 that recommends the re-order parameters in real-time.

Note that the algorithm allows the objective function to be adjusted for each customer or account based on the related business situation. In an example implementation, the training phase 302 can be bypassed and enter the live production phase 304 with predefined or streamed hyperparameters. Idealized assumptions for the uncertainties frequently employed in inventory optimization often do not hold. The example SIO system algorithm illustrates a practical workflow to handle uncertainties in real-time production, where ideal conditions cannot be assumed.

Note that the performance of the example SIO system algorithm is demonstrated above in detail with data provided by clients in the energy and manufacturing industries. The performance of the example algorithm on customers' data across a variety of verticals was evaluated, and an example showed that the example SIO system algorithm is effective in reducing the inventory and the safety stock costs while maintaining a satisfying service level. However, the illustrated data and the performance obtained by the example SIO system algorithm are for illustration only. The illustrated data can vary widely based on the specific application, and the performance obtained can vary widely based on the implementation. Sensitivity studies can be conducted showing that some of the model parameters can impact the optimization results. The sensitivity studies can provide reasonable choices for model parameters as default values while deploying the algorithm in scale. Tests on a sub-sample of SKUs can assist to find the best model parameters for a dataset before live production.

### Example System Implementation

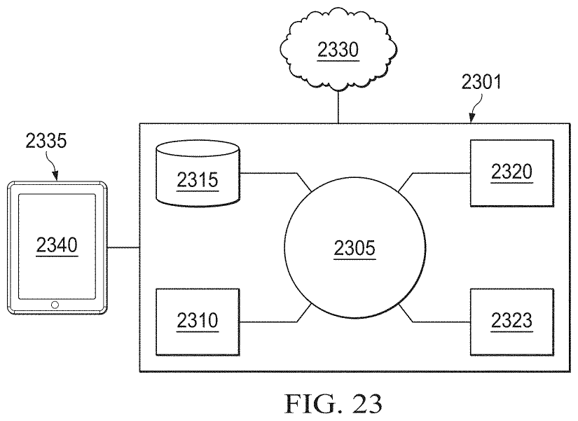

FIG. 23 illustrates an example computer system 2301 that is programmed or otherwise configured to implement various techniques for hyperparameter inventory optimization using artificial intelligence in accordance with this disclosure. The computer system 2301 can regulate various aspects of this disclosure. For example, the computer system 2301 can regulate obtaining an inventory dataset including a plurality of inventory variables, applying a trained algorithm to the inventory dataset in order to generate a prediction of the variables having future uncertainties, and applying an optimization algorithm to the inventory dataset to optimize the plurality of inventory variables. The computer system 2301 can be an electronic device of a user or a computer system that is remotely located with respect to the electronic device. In some cases, the electronic device can be a mobile electronic device.

The computer system 2301 includes a central processing unit (CPU, also “processor” and “computer processor”) 2305, which can be a single-core or multi core processor or a plurality of processors for parallel processing. The computer system 2301 also includes memory or memory location 2310 (such as random-access memory, read-only memory, Flash memory, etc.), electronic storage unit 2315 (such as a hard disk), communication interface 2320 (such as a network adapter) for communicating with one or more other systems, and one or more peripheral devices 2325, such as a cache, other memory, data storage, and/or electronic display adapters. The memory 2310, storage unit 2315, interface 2320, and peripheral devices 2325 are in communication with the CPU 2305 through a communication bus (solid lines), such as a motherboard. The storage unit 2315 can be a data storage unit or data repository for storing data. The computer system 2301 can be operatively coupled to a computer network 2330 with the aid of the communication interface 2320. The network 2330 can be the Internet, an internet and/or extranet, or an intranet and/or extranet that is in communication with the Internet.

In some cases, the network 2330 is a telecommunication and/or data network. The network 2330 can include one or more computer servers, which can enable distributed computing, such as cloud computing. For example, one or more computer servers may enable cloud computing over the network 2330 (“the cloud”) to perform various aspects of analysis, calculation, and generation of this disclosure, such as obtaining an inventory dataset including a plurality of inventory variables, applying a trained algorithm to the inventory dataset in order to generate a prediction of the variables having future uncertainties, and applying an optimization algorithm to the inventory dataset to optimize the plurality of inventory variables. Such cloud computing may be provided by various cloud computing platforms, such as AMAZON Web Services (AWS), MICROSOFT Azure, GOOGLE Cloud Platform, and IBM cloud. The network 2330, in some cases with the aid of the computer system 2301, can implement a peer-to-peer network, which may enable devices coupled to the computer system 2301 to behave as a client or a server.

The CPU 2305 can execute a sequence of machine-readable instructions, which can be embodied in a program or software. The instructions may be stored in a memory location, such as the memory 2310. The instructions can be directed to the CPU 2305, which can subsequently program or otherwise configure the CPU 2305 to implement methods of this disclosure. Examples of operations performed by the CPU 2305 can include fetch, decode, execute, and writeback. The CPU 2305 can be part of a circuit, such as an integrated circuit. One or more other components of the system 2301 can be included in the circuit. In some cases, the circuit is an application specific integrated circuit (ASIC). Note, however, that this disclosure is not limited to any specific type(s) of processing device(s). In general, any suitable type(s) of processing device(s) may be used in the computer system 2301. Example types of processing devices include one or more microprocessors, microcontrollers, reduced instruction set computers (RISCs), complex instruction set computers (CISCs), graphics processing units (GPUs), data processing units (DPUs), virtual processing units, associative process units (APUs), tensor processing units (TPUs), vision processing units (VPUs), neuromorphic chips, AI chips, quantum processing units (QPUs), cerebras wafer-scale engines (WSEs), digital signal processors (DSPs), ASICs, field programmable gate arrays (FPGAs), or discrete circuitry.

The storage unit 2315 can store files, such as drivers, libraries, and saved programs. The storage unit 2315 can store user data, such as user preferences and user programs. In some cases, the computer system 2301 can include one or more additional data storage units that are external to the computer system 2301, such as located on a remote server that is in communication with the computer system 2301 through an intranet or the Internet.

The computer system 2301 can communicate with one or more remote computer systems through the network 2330. For instance, the computer system 2301 can communicate with a remote computer system of a user. Examples of remote computer systems include personal computers (such as portable PC), slate or tablet PCs (such as an APPLE IPAD or SAMSUNG GALAXY TAB), telephones, smartphones (such as an APPLE IPHONE, ANDROID-enabled device, or BLACKBERRY), or personal digital assistants. The user can access the computer system 2301 via the network 2330.

In some embodiments, the systems and methods described above can be implemented by way of machine (such as computer processor) executable code stored on an electronic storage location of the computer system 2301, such as on the memory 2310 or electronic storage unit 2315. The machine executable or machine readable code can be provided in the form of software. During use, the code can be executed by the processor 2305. In some cases, the code can be retrieved from the storage unit 2315 and stored on the memory 2310 for ready access by the processor 2305. In some situations, the electronic storage unit 2315 can be precluded, and machine-executable instructions are stored on memory 2310. In some implementations, the code can be pre-compiled and configured for use with a machine having a processor adapted to execute the code or can be compiled during runtime. The code can be supplied in a programming language that can be selected to enable the code to execute in a pre-compiled or as-compiled fashion.

Aspects of the systems and methods provided here, such as the computer system 2301, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (like read-only memory, random-access memory, Flash memory, etc.) or a hard disk. “Storage” type media can include any or all of the tangible memory of the computers, processors, or the like or associated modules thereof, such as various semiconductor memories, tape drives, disk drives, and the like, which may provide non-transitory storage at any time for the software programming. All or portions of the software may at times be communicated through the Internet or various other telecommunication networks. Such communications, for example, may enable loading of the software from one computer or processor into another, such as from a management server or host computer into the computer platform of an application server. Thus, another type of media that may bear the software elements includes optical, electrical, and electromagnetic waves, such as those used across physical interfaces between local devices, through wired and optical landline networks, and over various air-links. The physical elements that carry such waves, such as wired or wireless links, optical links, or the like, may also be considered as media bearing the software. As used here, unless restricted to non-transitory tangible storage media, terms such as a computer or machine readable medium refer to any medium that participates in providing instructions to a processor for execution.

As a result, a machine readable medium, such as one containing computer-executable code, may take many forms, including but not limited to a tangible storage medium, a carrier wave medium, or a physical transmission medium. Non-volatile storage media include, for example, optical or magnetic disks, such as any of the storage devices in any computer(s) or the like, and may be used to implement the databases, etc. shown in the drawings. Volatile storage media include dynamic memory, such as main memory of such a computer platform. Tangible transmission media include coaxial cables, copper wire, and fiber optics, including the wires that form a bus within a computer system. Carrier-wave transmission media may take the form of electric or electromagnetic signals or acoustic or light waves, such as those generated during radio frequency (RF) and infrared (IR) data communications. Common forms of computer-readable media therefore include, for example, a floppy disk, flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM, an EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 2301 can include or be in communication with an electronic display 2335 that includes a user interface (UI) 2340. Examples of user interfaces include, without limitation, a graphical user interface (GUI) and a web-based user interface. For example, the computer system 2301 can include a web-based dashboard (such as a GUI) configured to display, for example, a BOM to a user.

The methods and systems of this disclosure can be implemented by way of one or more algorithms. An algorithm can be implemented by way of software upon execution by the central processing unit 2305. The algorithm can, for example, obtain an inventory dataset including a plurality of inventory variables, apply a trained algorithm to the inventory dataset to generate a prediction of the variables having future uncertainty, and apply an optimization algorithm to the inventory dataset to optimize the plurality of inventory variables.

In some embodiments, the processor 2305 may be configured (such as by using suitable instructions executed by the processor 2305) to provide a simulation and optimization framework, which is described above. The simulation and optimization framework can be accessed by various users in order to provide hyperparameter inventory optimization for those users. In some embodiments, the simulation and optimization framework may include the various modules described above, such as the inventory, aggregation, uncertainty, simulation, prediction, and optimization modules (or other modules described in this disclosure). These modules can be used to perform different functions of the simulation and optimization framework in order to provide the functionalities described above.

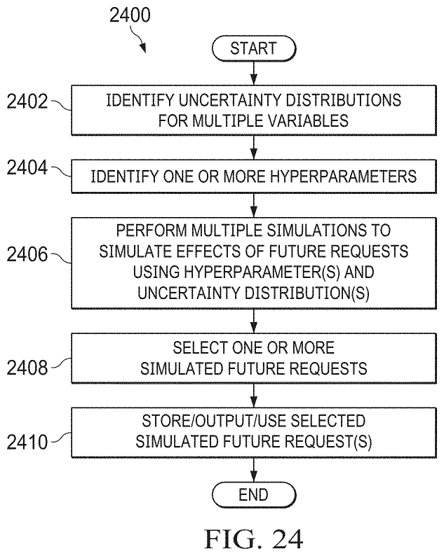

FIG. 24 illustrates an example method 2400 for AI-based hyperparameter tuning in simulation-based optimization in accordance with this disclosure. For ease of explanation, the method 2400 is described as being performed using the computer system 2301 of FIG. 23. However, the method 2400 may be performed using any other suitable device(s).

As shown in FIG. 24, uncertainty distributions for multiple variables are identified at step 2402. This may include, for example, the processor 2305 identifying historical data, current data, estimates, forecasts, or other or additional information associated with a supply chain or other system. This may also include the processor 2305 processing the data to identify an uncertainty distribution for each of multiple variables associated with the supply chain or other system. In some embodiments, one or more trained machine learning models may be used to model the uncertainties here.

One or more hyperparameters are determined or identified at step 2404. This may include, for example, the processor 2305 analyzing a set of models, model training data, and/or data sets to select one or more hyperparameters. In an example implementation, the one or more hyperparameters can be previously defined during a previous training phase. The one or more hyperparameters can provide an uncertainty model of a multiparametric optimization problem associated with the supply chain or other system. The one or more hyperparameters can vary depending on the application. In a supply chain, for example, the one or more hyperparameters can represent STP, SLP, etc.

Multiple simulations are performed to simulate the effects of future requests on the system using the one or more hyperparameters and at least one of the identified uncertainty distributions at step 2406. This may include, for example, the processor 2305 identifying one or more re-order parameters (such as SSV and ST values) to be used based on the identified hyperparameter(s) and at least one of the identified uncertainty distributions. Part of the simulations includes sampling at least one of the uncertainty distributions to simulate at least one uncertainty associated with at least one of the variables on the future request.

At least one of the future requests is selected at step 2408. This may include, for example, the processor 2305 selecting one or more of the simulated future requests that would allow an enterprise to achieve one or more specified goals. The one or more selected simulated future requests are stored, output, or used in some manner at step 2410. This may include, for example, the processor 2305 initiating the display of the one or more selected simulated future requests to a user or performing any other suitable actions.

Although FIG. 24 illustrates one example of a method 2400 for AI-based hyperparameter tuning in simulation-based optimization, various changes may be made to FIG. 24. For example, while shown as a series of steps, various steps in FIG. 24 may overlap, occur in parallel, occur in a different order, or occur any number of times.

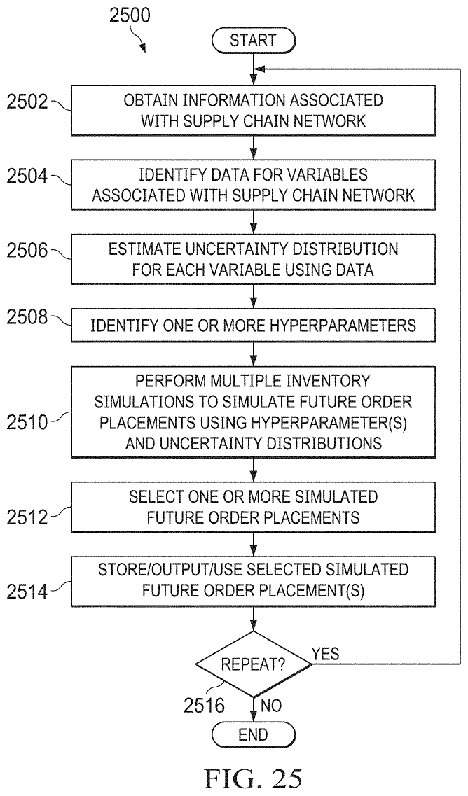

FIG. 25 illustrates an example method 2500 for hyperparameter inventory optimization using artificial intelligence in accordance with this disclosure. For ease of explanation, the method 2500 is described as being performed using the computer system 2301 of FIG. 23 while performing the process 300 of FIG. 3. However, the method 2500 may be used to perform any other suitable process(es) and using any other suitable device(s).

As shown in FIG. 25, information associated with a supply chain is obtained at step 2502. This may include, for example, the processor 2305 obtaining historical data and/or current data regarding one or more aspects of a supply chain. Any suitable historical data and/or current data may be obtained here, such as historical and/or current data related to inventory levels of an enterprise. Specific examples of data may include inventory levels, supply factors, supplier orders, demand factors, demand forecasts, material consumptions, transit times, lead times, material requirements planning (MRP), inventory holding costs, shipping costs, or any combination thereof. The data may be obtained from any suitable source(s), such as smart devices, sensors, enterprise systems, extraprise systems, Internet data sources, or any combination thereof.

Data for certain variables associated with the supply chain network is identified at step 2504, and uncertainty distributions for the variables are identified using the data at step 2506. This may include, for example, the processor 2305 identifying data related to demand forecasts, material consumptions and movements, and supplier deliveries. This may also include the processor 2305 identifying a demand forecast uncertainty, a material movement uncertainty, a supplier quantity uncertainty, and a supplier time uncertainty based on the data. The demand forecast uncertainty distribution represents a distribution of differences between demand forecasts and actual consumptions. The material movement uncertainty distribution represents a distribution of miscellaneous movements and blocked movements. The supplier quantity uncertainty distribution represents a distribution of differences between planned quantities in purchase orders and actual quantities received. The supplier time uncertainty distribution represents a distribution of time differences of planned delivery dates and actual delivery dates of orders. One or more trained machine learning models may be used to model the uncertainties used here.

One or more hyperparameters are identified at step 2508. This may include, for example, the processor 2305 identifying SLP and STP values or other hyperparameters identified during a previous training phase. Multiple inventory simulations are performed to simulate the effects of future order placements on an inventory using the one or more hyperparameters and the identified uncertainty distributions at step 2510. This may include, for example, the processor 2305 identifying one or more re-order parameters (such as SSV and ST values) to be used based on the identified hyperparameter(s) and the identified uncertainty distributions. As a particular example, this may include the processor 2305 performing multiple MRP simulations for a current sampling time t to infer the best re-order parameters or other parameters, which in some cases may be determined using the k-iteration algorithm discussed above. One or more trained machine learning models may be used here to generate the simulated future order placements.

One or more of the simulated future order placements are selected at step 2512. This may include, for example, the processor 2305 selecting one or more of the simulated future order placements that would allow the enterprise to achieve a target service level while reducing or optimizing an inventory-related cost. The one or more selected simulated future order placements are stored, output, or used in some manner at step 2514. This may include, for example, the processor 2305 initiating the display of the one or more selected simulated future order placements to a user, causing an MRP system to actually place orders, or performing any other suitable actions.

A determination is made whether to repeat the process or at least a portion thereof at step 2516. This may include, for example, the processor 2305 performing multiple MRP simulations during a subsequent sampling time and repeating subsequent steps. This may also or alternatively include the processor 2305 repeating certain steps based on an optimization frequency, such as an optimization frequency set by a schedule, file, external command stream, input interface, etc.

Although FIG. 25 illustrates one example of a method 2500 for hyperparameter inventory optimization using artificial intelligence, various changes may be made to FIG. 25. For example, while shown as a series of steps, various steps in FIG. 25 may overlap, occur in parallel, occur in a different order, or occur any number of times.

The following describes example embodiments of this disclosure that implement or relate to hyperparameter inventory optimization using artificial intelligence. However, other embodiments may be used in accordance with the teachings of this disclosure.

In a first embodiment, a method includes identifying, using at least one processor, uncertainty distributions for multiple variables. The method also includes identifying, using the at least one processor, one or more hyperparameters. The method further includes performing, using the at least one processor, multiple simulations to simulate effects of future requests using the one or more hyperparameters and at least one of the uncertainty distributions. The simulations involve sampling of the at least one uncertainty distribution to simulate at least one uncertainty associated with at least one of the variables on the future requests. In addition, the method includes selecting, using the at least one processor, one or more of the simulated future requests.

In a second embodiment, an apparatus includes at least one processor configured to identify uncertainty distributions for multiple variables and identify one or more hyperparameters. The at least one processor is also configured to perform multiple simulations to simulate effects of future requests using the one or more hyperparameters and at least one of the uncertainty distributions. The simulations involve sampling of the at least one uncertainty distribution to simulate at least one uncertainty associated with at least one of the variables on the future requests. The at least one processor is further configured to select one or more of the simulated future requests.

In a third embodiment, a non-transitory computer readable medium contains instructions that when executed cause at least one processor to identify uncertainty distributions for multiple variables and identify one or more hyperparameters. The non-transitory computer readable medium also contains instructions that when executed cause the at least one processor to perform multiple simulations to simulate effects of future requests using the one or more hyperparameters and at least one of the uncertainty distributions. The simulations involve sampling of the at least one uncertainty distribution to simulate at least one uncertainty associated with at least one of the variables on the future requests. The non-transitory computer readable medium further contains instructions that when executed cause the at least one processor to select one or more of the simulated future requests.

Any single one or any suitable combination of the following features may be used with the first, second, or third embodiment. The multiple variables may be associated with an inventory that is affected by or involved in a supply chain network, the future requests may represent future order placements, and the multiple may simulations simulate effects of the future order placements on the inventory. The multiple simulations may include identifying one or more re-order parameters for optimizing the inventory and placing orders based on the one or more re-order parameters. The uncertainty distributions for the multiple variables may include (i) a demand forecast uncertainty distribution representing a distribution of differences between demand forecasts and actual consumptions of material in the inventory, (ii) a material movement uncertainty distribution representing a distribution of movements of the material in the inventory, (iii) a supplier quantity uncertainty distribution representing a distribution of differences between planned quantities of the material in purchase orders and actual quantities of the material received, and/or (iv) a supplier time uncertainty distribution representing a distribution of time differences between planned delivery dates of the material and actual delivery dates of the material. The one or more hyperparameters may include one of (i) a service level percentile representing a percentage of inventory realizations generated by the simulations that meet a minimum target service level and a safety time percentile representing a specified percentile in a supplier time uncertainty distribution, (ii) a reorder point percentile representing the percentage of inventory realizations generated by the simulations that meet the minimum target service level and a reorder quantity percentile representing a percentage of inventory realizations generated by the simulations that minimize an overall cost of holding the inventory, or (iii) a minimum inventory level percentile representing the percentage of inventory realizations generated by the simulations that meet the minimum target service level and a maximum inventory level percentile representing the percentage of inventory realizations generated by the simulations that minimize the overall cost of holding the inventory. The multiple simulations may include identifying one or more re-order parameters based on the one or more hyperparameters and the at least one uncertainty distribution. The one or more re-order parameters may include one of (i) a safety stock value representing an additional quantity of material held in the inventory to reduce a risk that the material will be out of stock and a safety time value representing a time buffer for covering material requirements in cases of future late deliveries of the material, (ii) a reorder point value representing an inventory level of material where a new order should be placed to reduce the risk that the material will be out of stock and a reorder quantity value representing an order placement quantity at a reorder point to reduce an overall cost of holding the inventory, or (iii) a minimum inventory level representing the inventory level of material where the new order should be placed to reduce the risk that the material will be out of stock and a maximum inventory level representing an upper bound of the inventory at any order placement to reduce the overall cost of holding the inventory. The multiple simulations may include performing multiple MRP simulations to identify one or more optimal re-order parameters using a k-iteration algorithm. The MRP simulations may include at least one of: safety stock MRP simulations, reorder point MRP simulations, and min-max MRP simulations. The one or more simulated future requests may be selected by selecting at least one of the simulated future order placements that achieves a target service level while reducing an inventory-related cost. The one or more selected simulated future order placements may be displayed, and/or one or more orders based on the one or more selected simulated future order placements may be placed. The simulations may be performed using uncertainty realizations of multiple uncertainties associated with the multiple variables generated by perturbing at least one of: a demand forecast, a delay, a quantity shortage of arriving orders, and a miscellaneous order movement. The simulations may include forward-looking simulations using a receding horizon. The multiple simulations may include performing multiple MRP simulations, and the MRP simulations may be customizable for use with a specific MRP system. At least the performance of the multiple simulations and the selection of the one or more simulated future requests may be repeated at a specified optimization frequency. The one or more hyperparameters may be based on a trade-off preference associated with a prioritization of multiple objectives, and the multiple objectives may include at least one of: a risk objective, a cost objective, and a user-defined objective.

Any other aspects or features of this disclosure may be used with the first, second, or third embodiment. For example, the multiple variables may be associated with an inventory that is affected by or involved in a supply chain network, the future requests may represent potential future orders, and the one or more selected future requests may represent one or more selected future orders. In some cases, the simulations may be performed in response to predicting or detecting volatility in the supply chains network. Also, in some cases, the one or more selected future orders may be automatically placed in order to re-strategize inventory management. The results of the automatic order placement may be to reduce or minimize an amount of inventory held and/or reduce or minimize an inventory cost.

As another example, the multiple variables may be associated with an inventory that is affected by or involved in a supply chain network, the future requests may represent potential future orders, and the one or more selected future requests may represent one or more selected future orders. The one or more selected future orders may be used to control a logistical planning system, such as an MRP system. As a particular example, the one or more selected future orders may be used to control an MRP system and to instruct the MRP system to change safety stock, safety time, or other parameter(s) used by the MRP system. In some cases, the parameter(s) may be changed based on the simulations in order to (i) promote inventory cost savings and (ii) satisfying one or more contractual requirements with one or more suppliers. Also, in some cases, the parameter(s) may be changed based on the simulations in order to automatically adjust one or more resource planning, scheduling, ordering, routing, and/or restocking strategies.

The following are examples of additional embodiments or aspects of this disclosure. In an aspect, this disclosure provides systems and methods that may include one or more computers and one or more storage devices storing instructions that are operable, when executed by the one or more computers, to cause the one or more computers to perform operations of a method. The method may include receiving an inventory dataset having a plurality of inventory variables that indicate at least historical (i) inventory levels, (ii) inventory holding costs, (iii) supplier orders, or (iv) lead times over time. The inventory variables are characterized by having one or more future uncertainty levels. The method also includes predicting one or more inventory management or re-order parameters by providing information from the inventory dataset and at least one hyperparameter to an interpretation algorithm that is configured to output a probability of achieving a target service level while optimizing an inventory related cost. The method further includes processing the inventory dataset using at least the inventory management or re-order parameters to thereby generate a prediction of the inventory variables that are characterized by having one or more future uncertainty levels.

Obtaining the inventory dataset may include obtaining and aggregating datasets from a plurality of disparate sources. The datasets may include internal datasets and external datasets. The disparate sources may be selected from the group consisting of smart devices, sensors, enterprise systems, extraprise systems, and Internet sources. The datasets may be persisted in a plurality of data stores. The inventory variables may include a plurality of time series. The plurality of inventory variables may be representative of historical inventory data and/or current inventory data. The historical inventory data may include one or more types of movements selected from the group consisting of arrival movements, consumption movements, blocked movements, and inter-factory movements. In some embodiments, the variables having future uncertainty may include one or more of: inventory level, supply factor, supplier order, demand factor, demand forecast, material consumption, transit time, lead time, material requirements planning (MRP), inventory holding cost, and shipping cost.

The optimization algorithm may include a constrained optimization problem. The constrained optimization problem may minimize a cost function or maximize a reward function. The cost function or the reward function may be a function that represents the product output of an entity, the profit of such entity, or the time of delivery to customers (to name a few examples). The constrained optimization problem may include a constraint selected from the group consisting of an inventory constraint, a service level constraint, an arrival window constraint, an order size constraint, and an ordering window constraint. The service level constraint may include a confidence level that an inventory meets a demand requirement. The service level constraint may be about 90%, about 95%, about 98%, or about 99%. The minimized cost function may include a cost selected from the group consisting of an inventory holding cost, a shipping cost, a production delay cost, and a combination thereof. The constrained optimization problem may include a stochastic constrained optimization problem. The optimization algorithm may include a technique selected from the group consisting of a grid search, a random search, and a Bayesian optimization search. The stochastic constrained optimization problem may be a mixed integer linear programming (MILP) problem. The MILP problem may model the variables having future uncertainty using linear chance constraints.

The method may also include storing, by the computer, the optimized inventory dataset in a database. The storing may be performed through a cloud-based network. The method may also include generating, by the computer, one or more recommended inventory management decisions based on the optimized inventory dataset. Generating the one or more recommended inventory management decisions may include determining a difference between the optimized inventory dataset and a reference inventory dataset. The method may also include generating, by the computer, one or more alerts of disruption risks and/or delay risks based at least in part on the optimized inventory dataset. The optimized inventory dataset may be generated in real-time, substantially real-time, just-in-time, or periodically in hours, days, weeks, months, or more. In some embodiments, the method may also include traversing a bill of materials (BOM) (where the BOM may include a dynamic hierarchical graph) and displaying the BOM to a user. The BOM may be traversed and displayed to the user in real-time, substantially real-time, just-in-time, or periodically in hours, days, weeks, months, or more. The inventory dataset may include a plurality of inventory variables for a single-echelon inventory, where the single-echelon inventory may correspond to a single node or facility. The optimization algorithm may be configured to perform multi-echelon inventory optimization (MEIO), and the inventory dataset may include a plurality of inventory variables for a multi-echelon inventory, where the multi-echelon inventory may correspond to a supply chain network that includes a plurality of nodes or facilities. The optimization algorithm may be configured to model the plurality of inventory variables using a probabilistic graphical model of the supply chain network. The optimization algorithm may be configured to model the plurality of inventory variables using a Bayesian optimization model of the supply chain network.

In another aspect, this disclosure provides a computer system that includes a digital processing device having at least one processor, an operating system configured to perform executable instructions, a memory, and a computer program including instructions executable by the digital processing device to create an application for inventory management and optimization. The application includes an inventory module programmed to obtain an inventory dataset having a plurality of inventory variables, where the inventory variables include variables having future uncertainty. The application also includes a prediction module programmed to apply a trained algorithm to the inventory dataset to generate a prediction of the variables having future uncertainty. The application further includes an optimization module programmed to apply an optimization algorithm to the inventory dataset to optimize the plurality of inventory variables, to generate an optimized inventory dataset.

The application may also include an aggregation module programmed to obtain and aggregate datasets from a plurality of disparate sources. The datasets may include internal datasets and external datasets. The disparate sources may be selected from the group consisting of smart devices, sensors, enterprise systems, extraprise systems, and Internet sources. The datasets may be persisted in a plurality of data stores. The inventory variables may include a plurality of time series. The inventory variables may be representative of historical inventory data and/or current inventory data. The historical inventory data may include one or more types of movements selected from the group consisting of arrival movements, consumption movements, blocked movements, and inter-factory movements. The variables having future uncertainty may include one or more of: inventory level, supply factor, supplier order, demand factor, demand forecast, material consumption, transit time, lead time, material requirements planning (MRP), inventory holding cost, and shipping cost.

The optimization algorithm may include a constrained optimization problem. The constrained optimization problem may minimize a cost function. The constrained optimization problem may include a constraint selected from the group consisting of an inventory constraint, a service level constraint, an arrival window constraint, an order size constraint, and an ordering window constraint. The service level constraint may include a confidence level that an inventory meets a demand requirement. The service level constraint may be about 90%, about 95%, about 98%, or about 99%. The minimized cost function may include a cost selected from the group consisting of an inventory holding cost, a shipping cost, a production delay cost, and a combination thereof. The constrained optimization problem may include a stochastic constrained optimization problem. The optimization algorithm may include one or a combination of more than one technique selected from the group consisting of a grid search, a random search, Markov-Chain Monte-Carlo (MCMC) optimization, and a Bayesian optimization search or other optimization algorithms. The model may include one or more hyperparameters and one or more interpretation algorithms. The one or more hyperparameters may be calculated using one or more optimization algorithms. The system may use one or more predetermined hyperparameters. The one or more predetermined hyperparameters may be received from a digital transmission, file, external command stream, input interface, etc. The one or more hyperparameters may be determined or optimized at least in part using realized or simulated uncertainty outcomes.

The interpretation algorithm may be iterative or noniterative. The interpretation algorithm may be based on simulated uncertainty data. The interpretation algorithm may be based on realized (empirical or historical) uncertainty data. The interpretation algorithm may include an objective function and one or more constraints. The interpretation algorithm may alter one or more decision variable in order to minimize or optimize an objective function while meeting the constraints. The interpretation algorithm may be a k-iteration algorithm. The interpretation algorithm may include a mixed integer linear programming (MILP) problem by modeling demand and supply-side uncertainties as linear chance constraints and utilizing a Markov-Chain Monte-Carlo (MCMC) algorithm to sample from those uncertainties. Such MILP problems can be efficiently solved using MILP solvers.

$${argmin}_{reorder parameters} Inventory Holding cost + Shipping cost such that Prob ( Inventory > 0 ) \geq α$$

The interpretation algorithm may include a trained algorithm. The trained algorithm may include a machine learning algorithm. The machine learning algorithm may be selected from the group consisting of a support vector machine (SVM), a naïve Bayes classification, a linear regression, a quantile regression, a logistic regression, a random forest, and a neural network.

The prediction may be generated by processing the inventory dataset to fit a statistical distribution to the plurality of inventory variables. Fitting the statistical distribution may include estimating one or more statistical parameters using the historical inventory data. The statistical distribution may be a parametric distribution selected from the group consisting of a Gaussian distribution, a Gamma distribution, and a Poisson distribution. The one or more statistical parameters may be selected from the group consisting of a median, a mean, a mode, a variance, a standard deviation, a quantile, a measure of central tendency, a measure of variance, a range, a minimum, a maximum, an interquartile range, and a percentile. The statistical distribution may be used to generate the prediction of the variables having future uncertainty. The prediction may include a distribution of the variables having future uncertainty. The distribution of the variables having future uncertainty may include a distribution over a future duration of time. The future duration time may be about 1 day, about 3 days, about 5 days, about 1 week, about 2 weeks, about 3 weeks, about 1 month, about 2 months, about 3 months, about 4 months, about 5 months, about 6 months, about 7 months, about 8 months, about 9 months, about 10 months, about 11 months, about 12 months, about 14 months, about 16 months, about 18 months, about 20 months, about 22 months, about 24 months, or more than about 24 months.

The constraint optimization may be a receding horizon optimization. The receding horizon optimization may employ a sub-framework that handles the evolvement of an optimization over a period of time. The receding horizon optimization may be an MPC optimization. The optimization may use a forward-looking horizon. The optimization may employ a sliding optimization window that may extend to either the future or the past. An input interface control may be allowed to control the optimization frequency and/or otherwise specifically configure the optimization window/horizon. Interpretation of the optimization results may be either attached to or isolated from the current status, which may include inventory status, order arrival status, or other realized inventory related parameters. Where realized inventory is disconnected, a steady-state inventory may be used to predict inventory parameters.

The application may also include a storage module programmed to store the optimized inventory dataset in a database. The storing may be performed through a cloud-based network. The application may also include a decision module programmed to generate one or more recommended inventory management decisions based on the optimized inventory dataset. Generating the one or more recommended inventory management decisions may include determining a difference between the optimized inventory dataset and a reference inventory dataset. The application may also include an alert module programmed to generate one or more alerts of disruption risks and/or delay risks based at least in part on the optimized inventory dataset. The optimized inventory dataset may be generated in real-time, substantially real-time, just-in-time, or periodically in hours, days, weeks, months, or more. The application may also include a display module programmed to traverse a bill of materials (BOM) (where the BOM may include a dynamic hierarchical graph) and display the BOM to a user. The BOM may be traversed and displayed to the user in real-time, substantially real-time, just-in-time, or periodically in hours, days, weeks, months, or more. The inventory dataset may include a plurality of inventory variables for a single-echelon inventory, where the single-echelon inventory may correspond to a single node or facility. The optimization algorithm may be configured to perform multi-echelon inventory optimization (MEIO), and the inventory dataset may include a plurality of inventory variables for a multi-echelon inventory, where the multi-echelon inventory may correspond to a supply chain network having a plurality of nodes or facilities. The optimization algorithm may be configured to model the plurality of inventory variables using a probabilistic graphical model of the supply chain network. The optimization algorithm may be configured to model the plurality of inventory variables using a Bayesian optimization model of the supply chain network.

In another aspect, this disclosure provides a non-transitory computer readable medium having machine-executable code that, upon execution by one or more computer processors, implements a method for inventory management and optimization. The method includes obtaining an inventory dataset having a plurality of inventory variables, where the inventory variables include variables having future uncertainty. The method also includes applying a trained algorithm to the inventory dataset to generate a prediction of the variables having future uncertainty. The method further includes applying an optimization algorithm to the inventory dataset to optimize the plurality of inventory variables, thereby generating an optimized inventory dataset.

In another aspect, this disclosure provides a system that can receive an inventory dataset having a plurality of inventory variables that indicate at least historical (i) inventory levels, (ii) inventory holding costs, (iii) supplier orders, or (iv) lead times over time. The inventory variables can be characterized by having one or more future uncertainty levels. The system can process the inventory dataset using a trained machine learning model to generate a prediction of the plurality inventory variables that are characterized by having one or more future uncertainty levels. The system can be used for predicting one or more inventory management or re-order parameters by providing information from the inventory dataset and at least one hyperparameter to an interpretation algorithm that is configured to output a probability of achieving a target service level while optimizing an inventory related cost and/or processing the inventory dataset using at least the inventory management or re-order parameters to thereby generate a prediction of the inventory variables that are characterized by having one or more future uncertainty levels.

The system may provide a current inventory level and a quantity of current supplier orders to the optimization algorithm and may use the optimization algorithm to predict the target inventory level based at least on the current inventory level and the quantity of current supplier orders. The system may generate an inventory management recommendation based on the prediction of the target inventory level. The inventory management recommendation may include a recommendation to reduce the current inventory level. The inventory management recommendation may include a recommendation to increase the current inventory level. The inventory management recommendation may include a recommendation to maintain the current inventory level. The inventory management recommendation may be generated in real-time, substantially real-time, just-in-time, or periodically in hours, days, weeks, months, or more. The system may compute the present, incoming, or expected demand requirement using forecasted demand for finished products and a bill of materials (BOM) for the finished products. The BOM may include a dynamic hierarchical graph.

The inventory dataset may include internal data and external data. The inventory dataset may be received from a plurality of disparate sources selected from the group consisting of smart devices, sensors, enterprise systems, extraprise systems, and Internet sources. The inventory variables may further include one or more inventory movements selected from the group consisting of arrival movements, consumption movements, blocked movements, and inter-factory movements. The inventory variables may further include one or more of a demand forecast, material consumption, transit time, and shipping cost.

The optimization algorithm may include one or a combination of more than one technique selected from the group consisting of a grid search, a random search, Markov-Chain Monte-Carlo (MCMC) optimization, and a Bayesian optimization search or other optimization algorithms. The prediction of the plurality of inventory variables may include a statistical distribution of the plurality of inventory variables. The statistical distribution may include one or more statistical parameters. The one or more statistical parameters may be selected from the group consisting of a median, a mean, a mode, a variance, a standard deviation, a quantile, a measure of central tendency, a measure of variance, a range, a minimum, a maximum, an interquartile range, and a percentile. The statistical distribution may be a parametric distribution selected from the group consisting of a Gaussian distribution, a Gamma distribution, and a Poisson distribution.

The optimization algorithm may minimize a cost function. The optimization algorithm may further include a constraint condition selected from the group consisting of an inventory constraint, a service level constraint, an arrival window constraint, an order size constraint, and an ordering window constraint. The optimization algorithm may be a stochastic constrained optimization algorithm. The stochastic constrained optimization algorithm may be a mixed integer linear programming (MILP) problem. The optimization algorithm may include a technique selected from the group consisting of a grid search, a random search, and a Bayesian optimization search.

The inventory dataset may include a plurality of inventory variables for a single-echelon inventory, where the single-echelon inventory may correspond to a single node or facility. The optimization algorithm may be configured to perform multi-echelon inventory optimization (MEIO), where the inventory dataset may include a plurality of inventory variables for a multi-echelon inventory, where the multi-echelon inventory may correspond to a supply chain network having a plurality of nodes or facilities. The optimization algorithm may be configured to model the plurality of inventory variables using a probabilistic graphical model of the supply chain network. The optimization algorithm may be configured to model the plurality of inventory variables using a Bayesian optimization model of the supply chain network.

Another aspect of this disclosure provides methods corresponding to the operations performed by any of the systems described above or elsewhere here. Another aspect of this disclosure provides a non-transitory computer readable medium comprising machine executable code that, upon execution by one or more computer processors, implements any of the methods above or elsewhere here. Another aspect of this disclosure provides a system including one or more computer processors and computer memory coupled thereto. The computer memory includes machine executable code that, upon execution by the one or more computer processors, implements any of the methods above or elsewhere here.

Another example aspect of this disclosure is a new optimization workflow (referred to as “hyperparameter optimization”) to generate inventory parameter recommendations in real-time, substantially real-time, just-in-time, or periodically in hours, days, weeks, months, or more. There may be two time periods involved in this approach, namely a training period and a validation (or live production) period. The inventory parameter may be a re-order parameter. The inventory parameter may be a stock level related parameter.

The hyperparameter optimization approach may be applied to any material requirements planning (MRP) system. The MRP system may be a re-order point MRP system. The MRP system may be a min-max MRP system. The MRP system may be a Kanban MRP system. The parameters optimized using the hyperparameter may be specific to the individual MRP system. The MRP system may be a customized MRP system defined by a user or configured using a file, external command stream, input interface, etc. with at least some guidance from the inventory optimization system.

This approach may encode information in the training period (which may include planning information and uncertainty information) into two or more optimal hyperparameters, such as service level percentile (SLP) and safety time percentile (STP). The hyperparameters may be decoded to generate recommendations for re-order parameters in the validation (or live production) period with the context provided specifically in the validation period (such as planning information and realized uncertainty information). With this hyperparameter search approach, most of the computation burden may be shifted to the training period, where the optimal hyperparameters may be determined. The computation for the live production period may be significantly reduced, which may result in a faster recommendation in real-time, substantially real-time, just-in-time, or periodically in hours, days, weeks, months, or more. The hyperparameters selected may be invariant to the context of uncertainties and planning information, which means that this approach may be stable when the uncertainties during training are distributed differently from those during validation (or production). The training period may repeat the workflow of the validation period multiple times in a grid-search or other optimization approach to find the optimal hyperparameters.

In a further aspect, an optimization problem may be solved in a receding horizon fashion in both training and validation phases, where the optimal re-order parameters may be recommended based-on an optimization frequency (the corresponding timestamps may be referred to as sampling times, which may be configurable by a file, data stream, input interface, etc.). This formulation may resemble a model predictive control (MPC) setting established in the process control discipline. To make recommendations at each sampling time, inventory simulations may be carried out into the future, which may be referred to as the forward-looking simulation. The forward-looking simulation may be conducted with a steady-state initial inventory and a set of pre-specified hyperparameters, thereby reducing susceptibility to extreme fluctuations of realized inventory parameters.

In another aspect, a workflow may employ an interpretation algorithm, which may be an iterative or noniterative approach to determine one or more inventory parameters from one or more pre-specified hyperparameters. The workflow may not determine the re-order parameter directly and may convert the re-order parameters from the hyperparameters. The interpretation algorithm may determine the re-order parameters by simulating the inventory into the future (forward-looking simulations). Such simulations may be performed many times, each time with different simulated realizations of the uncertainties involved in the simulation process, thereby covering a majority of likely uncertainty outcomes.

The re-order parameters may be determined based on ensemble characteristics of many simulations performed. The process to determine the re-order parameters may be an iterative one. The re-order parameter may initially be set to zero and may gradually be updated based on pre-specified hyperparameters and the resulting ensemble characteristics of the simulations. The iteration may stop (and thus final re-order parameter may be determined) once the ensemble of simulations satisfies the constraints on the hyperparameters.

The interpretation algorithm may reduce the computation burden of a frequent forward-looking simulation, since the uncertainty realizations may be decoupled from the forward-looking simulation. Thus, the simulation of inventory may be run only once, and multiple uncertainty realizations may be run based on the result of the single simulation run. The level of coupling may be configured by a file, external command stream, input interface, etc., where a trade-off decision may be made between throughput (computational efficiency) and accuracy.

The hyperparameter uncertainty model may be advantageous in providing improved optimization results due to the ability to factor uncertainty into multiple inventory parameters. These parameters may be specific to a particular MRP system, such as SSV and ST in a safety stock MRP system or minimum and maximum inventory levels in a min-max inventory system. Forward-looking uncertainty simulations may provide an advantage over systems relying on the uncertainty information and the planning information in the recent past, which may not be as likely to be applicable to the situation in the future as would be a comprehensive model of possible outcomes. Forward-looking simulation may also incorporate future planning data (such as planned arrival, demand forecast, etc.) into the simulation and may consequently provide improved accuracy.

The hyperparameters may essentially represent a trade-off preference between multiple business objectives. An example business objective may include a tolerable risk profile of the customer, which may mean how much more of the inventory cost the customer is willing to bear to reduce the risk of the stock-out by a given amount, for example 10%. Other example business objectives may include an ideal inventory related cost, such as a tax impact profile, a holding cost, acquisition related costs, etc. The acceptable risk profile and business trade-off preferences may generally not change significantly over short periods of time. In the event that trade-off preference did suddenly change (such as due to a change in management strategy, personnel, etc.), only one re-computation of the hyperparameters may be necessary to retrain the model.

In some aspects, one task of the training period may be to extract a tolerable risk profile in an efficient way. This may be accomplished by designing an appropriate objective function so that the hyperparameters aligned with such risk profiles can maximize those objective functions. The process of maximizing the objective function may be performed via a variety of optimization algorithms (such as grid search, random search, gradient based optimization, Bayesian optimization, etc.). The optimization may be done during the training period, and the hyperparameters may be determined. There may not be any requirement to run optimization in the testing (or validation/production) period. One task of the validation period may be to interpret inventory parameters from the hyperparameters either directly or indirectly.

During the production/validation period, various actions may occur. For example, a determination may be made that a risk profile was determined in the training. Also, an uncertainty profile may be produced using data that is collected in the recent past up to a current date (such as 30, 60, or 90 days, where a user may be provided with a choice of a rolling window or a growing window). The uncertainty may be collected directly from an empirical distribution in the recent past or may be modeled using prior assumptions about the distribution followed by a fitting of the profile. This uncertainty profile may be very different from the uncertainties experienced in the training period. Data concerning orders placed during the production/validation period may be obtained and processed. The best re-order parameters based on these steps may be determined. The re-order parameters may be a final output of an algorithm that can be directly plugged into an MRP system, or the re-order parameters may be transmitted or reported through one or more interfaces.

Note that SLP and STP values are often described above as being used for hyperparameters and that SSV and ST values are often described above as being used for re-order parameters, which is suitable when used with a safety stock MRP system. The same or similar processes described above can also be used with other types of MRP systems, which may involve the usage of different hyperparameters and re-order parameters. For example, when used with a re-order point MRP system, the hyperparameters can include a reorder point percentile (which represents a percentage of inventory realizations generated by inventory simulations that meet a minimum target service level) and a reorder quantity percentile (which represents a percentage of inventory realizations generated by inventory simulations that minimize an overall cost of holding inventory). Also, when used with the re-order point MRP system, the re-order parameters can include a reorder point value (which represents an inventory level of material where a new order should be placed to reduce the risk that the material will be out of stock) and a reorder quantity value (which represents an order placement quantity at the reorder point to reduce the overall cost of holding inventory). As another example, when used with a min-max MRP system, the hyperparameters can include a minimum inventory level percentile (which represents a percentage of inventory realizations generated by inventory simulations that meet a minimum target service level) and a maximum inventory level percentile (which represents a percentage of inventory realizations generated by inventory simulations that minimize an overall cost of holding inventory). Also, when used with the min-max MRP system, the re-order parameters can include a minimum inventory level (which represents the inventory level of material where a new order should be placed to reduce the risk that the material will be out of stock) and a maximum inventory level (which represents the upper bound of inventory at any order placement to reduce the overall cost of holding inventory).

Also note that while the framework and approaches described herein are typically described as being used for supply chain optimization, the framework and approaches described herein may be used for optimizing other systems. For example, logistical systems (such as air-logistic systems) may be modeled in a similar manner as a supply chain system. As a result, the framework and approaches described herein may be used to support the optimization of other types of systems.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

Although the description has been described with respect to particular embodiments thereof, these particular embodiments are merely illustrative and not restrictive. Concepts illustrated in the examples may be applied to other examples and implementations.

While various embodiments of the present disclosure have been shown and described here, it will be obvious to those skilled in the art that such embodiments are provided by way of example only. It is not intended that the disclosure be limited by the specific examples provided within the specification. While the disclosure has been described with reference to the aforementioned specification, the descriptions and illustrations of the embodiments here are not meant to be construed in a limiting sense. Numerous variations, changes, and substitutions will now occur to those skilled in the art without departing from the disclosure. Furthermore, it shall be understood that all aspects of the disclosure are not limited to the specific depictions, configurations or relative proportions set forth here which depend upon a variety of conditions and variables. It should be understood that various alternatives to the embodiments of the disclosure described here may be employed in practicing the disclosure. It is therefore contemplated that the disclosure shall also cover any such alternatives, modifications, variations, or equivalents. It is intended that the following claims define the scope of the disclosure and that methods and structures within the scope of these claims and their equivalents be covered thereby.

What is claimed is:

1. A method comprising:
identifying, using at least one processor, uncertainty distributions for multiple variables;
identifying, using the at least one processor, one or more hyperparameters;
performing, using the at least one processor, multiple simulations to simulate effects of future requests using the one or more hyperparameters and at least one of the uncertainty distributions, the simulations involving sampling of the at least one uncertainty distribution to simulate at least one uncertainty associated with at least one of the variables on the future requests; and
selecting, using the at least one processor, one or more of the simulated future requests.

2. The method of claim 1, wherein:
the multiple variables are associated with an inventory that is affected by or involved in a supply chain network;
the future requests represent future order placements; and
performing the multiple simulations simulates effects of the future order placements on the inventory.

3. The method of claim 2, wherein performing the multiple simulations comprises:
identifying one or more re-order parameters for optimizing the inventory; and
placing orders based on the one or more re-order parameters.

4. The method of claim 2, wherein the uncertainty distributions for the multiple variables comprise:
a demand forecast uncertainty distribution representing a distribution of differences between demand forecasts and actual consumptions of material in the inventory;
a material movement uncertainty distribution representing a distribution of movements of the material in the inventory;
a supplier quantity uncertainty distribution representing a distribution of differences between planned quantities of the material in purchase orders and actual quantities of the material received; and
a supplier time uncertainty distribution representing a distribution of time differences between planned delivery dates of the material and actual delivery dates of the material.

5. The method of claim 2, wherein the one or more hyperparameters comprise one of:
a service level percentile representing a percentage of inventory realizations generated by the simulations that meet a minimum target service level and a safety time percentile representing a specified percentile in a supplier time uncertainty distribution;
a reorder point percentile representing the percentage of inventory realizations generated by the simulations that meet the minimum target service level and a reorder quantity percentile representing a percentage of inventory realizations generated by the simulations that minimize an overall cost of holding the inventory; and
a minimum inventory level percentile representing the percentage of inventory realizations generated by the simulations that meet the minimum target service level and a maximum inventory level percentile representing the percentage of inventory realizations generated by the simulations that minimize the overall cost of holding the inventory.

6. The method of claim 2, wherein performing the multiple simulations comprises:
identifying one or more re-order parameters based on the one or more hyperparameters and the at least one uncertainty distribution.

7. The method of claim 6, wherein the one or more re-order parameters comprise one of:
a safety stock value representing an additional quantity of material held in the inventory to reduce a risk that the material will be out of stock and a safety time value representing a time buffer for covering material requirements in cases of future late deliveries of the material;
a reorder point value representing an inventory level of material where a new order should be placed to reduce the risk that the material will be out of stock and a reorder quantity value representing an order placement quantity at a reorder point to reduce an overall cost of holding the inventory; and
a minimum inventory level representing the inventory level of material where the new order should be placed to reduce the risk that the material will be out of stock and a maximum inventory level representing an upper bound of the inventory at any order placement to reduce the overall cost of holding the inventory.

8. The method of claim 2, wherein performing the multiple simulations comprises:
performing multiple material requirements planning (MRP) simulations to identify one or more optimal re-order parameters using a k-iteration algorithm.

9. The method of claim 8, wherein the MRP simulations comprise at least one of:
safety stock MRP simulations, reorder point MRP simulations, and min-max MRP simulations.

10. The method of claim 2, wherein selecting the one or more simulated future requests comprises:
selecting at least one of the simulated future order placements that achieves a target service level while reducing an inventory-related cost.

11. The method of claim 2, further comprising at least one of:
displaying the one or more selected simulated future order placements; and
placing one or more orders based on the one or more selected simulated future order placements.

12. The method of claim 2, wherein the simulations are performed using uncertainty realizations of multiple uncertainties associated with the multiple variables generated by perturbing at least one of: a demand forecast, a delay, a quantity shortage of arriving orders, and a miscellaneous order movement.

13. The method of claim 1, wherein the simulations comprise forward-looking simulations using a receding horizon.

14. The method of claim 1, wherein performing the multiple simulations comprises:
performing multiple material requirements planning (MRP) simulations, the MRP simulations customizable for use with a specific MRP system.

15. The method of claim 1, wherein at least performing the multiple simulations and selecting the one or more simulated future requests are repeated at a specified optimization frequency.

16. The method of claim 1, wherein the one or more hyperparameters are based on a trade-off preference associated with a prioritization of multiple objectives, the multiple objectives including at least one of: a risk objective, a cost objective, and a user-defined objective.

17. An apparatus comprising:
at least one processor configured to:
identify uncertainty distributions for multiple variables;
identify one or more hyperparameters;
perform multiple simulations to simulate effects of future requests using the one or more hyperparameters and at least one of the uncertainty distributions, the simulations involving sampling of the at least one uncertainty distribution to simulate at least one uncertainty associated with at least one of the variables on the future requests; and
select one or more of the simulated future requests.

18. The apparatus of claim 17, wherein:
the multiple variables are associated with an inventory that is affected by or involved in a supply chain network;
the future requests represent future order placements; and
to perform the multiple simulations, the at least one processor is configured to simulate effects of the future order placements on the inventory.

19. The apparatus of claim 18, wherein, to perform the multiple simulations, the at least one processor is configured to:
identify one or more re-order parameters for optimizing the inventory; and
place orders based on the one or more re-order parameters.

20. The apparatus of claim 18, wherein the uncertainty distributions for the multiple variables comprise:
a demand forecast uncertainty distribution representing a distribution of differences between demand forecasts and actual consumptions of material in the inventory;
a material movement uncertainty distribution representing a distribution of movements of the material in the inventory;
a supplier quantity uncertainty distribution representing a distribution of differences between planned quantities of the material in purchase orders and actual quantities of the material received; and
a supplier time uncertainty distribution representing a distribution of time differences between planned delivery dates of the material and actual delivery dates of the material.

21. The apparatus of claim 18, wherein the one or more hyperparameters comprise one of:
a service level percentile representing a percentage of inventory realizations generated by the simulations that meet a minimum target service level and a safety time percentile representing a specified percentile in a supplier time uncertainty distribution;
a reorder point percentile representing the percentage of inventory realizations generated by the simulations that meet the minimum target service level and a reorder quantity percentile representing a percentage of inventory realizations generated by the simulations that minimize an overall cost of holding the inventory; and
a minimum inventory level percentile representing the percentage of inventory realizations generated by the simulations that meet the minimum target service level and a maximum inventory level percentile representing the percentage of inventory realizations generated by the simulations that minimize the overall cost of holding the inventory.

22. The apparatus of claim 18, wherein, to perform the multiple simulations, the at least one processor is configured to identify one or more re-order parameters based on the one or more hyperparameters and the at least one uncertainty distribution.

23. The apparatus of claim 22, wherein the one or more re-order parameters comprise one of:
a safety stock value representing an additional quantity of material held in the inventory to reduce a risk that the material will be out of stock and a safety time value representing a time buffer for covering material requirements in cases of future late deliveries of the material;
a reorder point value representing an inventory level of material where a new order should be placed to reduce the risk that the material will be out of stock and a reorder quantity value representing an order placement quantity at a reorder point to reduce an overall cost of holding the inventory; and
a minimum inventory level representing the inventory level of material where the new order should be placed to reduce the risk that the material will be out of stock and a maximum inventory level representing an upper bound of the inventory at any order placement to reduce the overall cost of holding the inventory.

24. The apparatus of claim 18, wherein, to perform the multiple simulations, the at least one processor is configured to perform multiple material requirements planning (MRP) simulations to identify one or more optimal re-order parameters using a k-iteration algorithm.

25. The apparatus of claim 24, wherein the MRP simulations comprise at least one of: safety stock MRP simulations, reorder point MRP simulations, and min-max MRP simulations.

26. The apparatus of claim 18, wherein, to select the one or more simulated future requests, the at least one processor is configured to select at least one of the simulated future order placements that achieves a target service level while reducing an inventory-related cost.

27. The apparatus of claim 18, wherein the at least one processor is further configured to at least one of:
display the one or more selected simulated future order placements; and
place one or more orders based on the one or more selected simulated future order placements.

28. The apparatus of claim 18, wherein the at least one processor is configured to perform the simulations using uncertainty realizations of multiple uncertainties associated with the multiple variables generated by perturbing at least one of: a demand forecast, a delay, a quantity shortage of arriving orders, and a miscellaneous order movement.

29. The apparatus of claim 17, wherein the simulations comprise forward-looking simulations using a receding horizon.

30. The apparatus of claim 17, wherein, to perform the multiple simulations, the at least one processor is configured to perform multiple material requirements planning (MRP) simulations, the MRP simulations customizable for use with a specific MRP system.

31. The apparatus of claim 17, wherein the at least one processor is configured to repeat at least the performance of the multiple simulations and the selection of the one or more simulated future requests at a specified optimization frequency.

32. The apparatus of claim 17, wherein the one or more hyperparameters are based on a trade-off preference associated with a prioritization of multiple objectives, the multiple objectives including at least one of: a risk objective, a cost objective, and a user-defined objective.

33. A non-transitory computer readable medium containing instructions that when executed cause at least one processor to:
identify uncertainty distributions for multiple variables;
identify one or more hyperparameters;
perform multiple simulations to simulate effects of future requests using the one or more hyperparameters and at least one of the uncertainty distributions, the simulations involving sampling of the at least one uncertainty distribution to simulate at least one uncertainty associated with at least one of the variables on the future requests; and
select one or more of the simulated future requests.

34. The non-transitory computer readable medium of claim 33, wherein:
the multiple variables are associated with an inventory that is affected by or involved in a supply chain network;
the future requests represent future order placements; and
the instructions that when executed cause the at least one processor to perform the multiple simulations comprise instructions that when executed cause the at least one processor to simulate effects of the future order placements on the inventory.

35. The non-transitory computer readable medium of claim 34, wherein the instructions that when executed cause the at least one processor to perform the multiple simulations comprise instructions that when executed cause the at least one processor to:
identify one or more re-order parameters for optimizing the inventory; and
place orders based on the one or more re-order parameters.

36. The non-transitory computer readable medium of claim 34, wherein the uncertainty distributions for the multiple variables comprise:
a demand forecast uncertainty distribution representing a distribution of differences between demand forecasts and actual consumptions of material in the inventory;
a material movement uncertainty distribution representing a distribution of movements of the material in the inventory;
a supplier quantity uncertainty distribution representing a distribution of differences between planned quantities of the material in purchase orders and actual quantities of the material received; and
a supplier time uncertainty distribution representing a distribution of time differences between planned delivery dates of the material and actual delivery dates of the material.

37. The non-transitory computer readable medium of claim 34, wherein the one or more hyperparameters comprise one of:
a service level percentile representing a percentage of inventory realizations generated by the simulations that meet a minimum target service level and a safety time percentile representing a specified percentile in a supplier time uncertainty distribution;
a reorder point percentile representing the percentage of inventory realizations generated by the simulations that meet the minimum target service level and a reorder quantity percentile representing a percentage of inventory realizations generated by the simulations that minimize an overall cost of holding the inventory; and
a minimum inventory level percentile representing the percentage of inventory realizations generated by the simulations that meet the minimum target service level and a maximum inventory level percentile representing the percentage of inventory realizations generated by the simulations that minimize the overall cost of holding the inventory.

38. The non-transitory computer readable medium of claim 34, wherein the instructions that when executed cause the at least one processor to perform the multiple simulations comprise instructions that when executed cause the at least one processor to identify one or more re-order parameters based on the one or more hyperparameters and the at least one uncertainty distribution.

39. The non-transitory computer readable medium of claim 38, wherein the one or more re-order parameters comprise one of:
a safety stock value representing an additional quantity of material held in the inventory to reduce a risk that the material will be out of stock and a safety time value representing a time buffer for covering material requirements in cases of future late deliveries of the material;
a reorder point value representing an inventory level of material where a new order should be placed to reduce the risk that the material will be out of stock and a reorder quantity value representing an order placement quantity at a reorder point to reduce an overall cost of holding the inventory; and
a minimum inventory level representing the inventory level of material where the new order should be placed to reduce the risk that the material will be out of stock and a maximum inventory level representing an upper bound of the inventory at any order placement to reduce the overall cost of holding the inventory.

40. The non-transitory computer readable medium of claim 34, wherein the instructions that when executed cause the at least one processor to perform the multiple simulations comprise instructions that when executed cause the at least one processor to perform multiple material requirements planning (MRP) simulations to identify one or more optimal re-order parameters using a k-iteration algorithm.

41. The non-transitory computer readable medium of claim 40, wherein the MRP simulations comprise at least one of: safety stock MRP simulations, reorder point MRP simulations, and min-max MRP simulations.

42. The non-transitory computer readable medium of claim 34, wherein the instructions that when executed cause the at least one processor to select the one or more simulated future requests comprise instructions that when executed cause the at least one processor to select at least one of the simulated future order placements that achieves a target service level while reducing an inventory-related cost.

43. The non-transitory computer readable medium of claim 34, further containing instructions that when executed cause the at least one processor to at least one of:
display the one or more selected simulated future order placements; and
place one or more orders based on the one or more selected simulated future order placements.

44. The non-transitory computer readable medium of claim 34, wherein the instructions that when executed cause the at least one processor to perform the multiple simulations comprise instructions that when executed cause the at least one processor to perform the simulations using uncertainty realizations of multiple uncertainties associated with the multiple variables generated by perturbing at least one of: a demand forecast, a delay, a quantity shortage of arriving orders, and a miscellaneous order movement.

45. The non-transitory computer readable medium of claim 33, wherein the simulations comprise forward-looking simulations using a receding horizon.

46. The non-transitory computer readable medium of claim 33, wherein the instructions that when executed cause the at least one processor to perform the multiple simulations comprise instructions that when executed cause the at least one processor to perform multiple material requirements planning (MRP) simulations, the MRP simulations customizable for use with a specific MRP system.

47. The non-transitory computer readable medium of claim 33, further containing instructions that when executed cause the at least one processor to repeat at least the performance of the multiple simulations and the selection of the one or more simulated future requests at a specified optimization frequency.

48. The non-transitory computer readable medium of claim 33, wherein the one or more hyperparameters are based on a trade-off preference associated with a prioritization of multiple objectives, the multiple objectives including at least one of: a risk objective, a cost objective, and a user-defined objective.
